(19) United States
(12) Patent Application Publication
(10) Pub. No.: US 2022/0026801 A1
(43) Pub. Date: Jan. 27, 2022

(54) CHEMICALLY AMPLIFIED POSITIVE -TYPE PHOTOSENSITIVE RESIN COMPOSITION, PHOTOSENSITIVE DRY FILM, METHOD OF MANUFACTURING PHOTOSENSITIVE DRY FILM, METHOD OF MANUFACTURING PATTERNED RESIST FILM, METHOD OF MANUFACTURING SUBSTRATE WITH TEMPLATE, AND METHOD OF MANUFACTURING PLATED ARTICLE

(71) Applicant: TOKYO OHKA KOGYO CO., LTD., Kawasaki-shi (JP)

(72) Inventors: Shota KATAYAMA, Kawasaki-shi (JP); Kazuaki EBISAWA, Kawasaki-shi (JP)

(21) Appl. No.: 17/309,729

(22) PCT Filed: Dec. 25, 2019
(86) PCT No.: PCT/JP2019/051011

§ 371 Date: Jun. 16, 2021

(30) Foreign Application Priority Data
Dec. 26, 2018 (JP) 2018-243233
Nov. 5, 2019 (JP) 2019-201064

(51) Int. Cl. G03F 7/004; G03F 7/039; G03F 7/32; G03F 7/20

(52) U.S. Cl. CPC G03F 7/0045; G03F 7/20; G03F 7/322; G03F 7/0392

(57) ABSTRACT

A chemically amplified positive-type photosensitive resin composition that can be used for exposure to h line and that has excellent plating solution resistance and crack resistance; a photosensitive dry film provided with a photosensitive resin layer comprising the chemically amplified positive type photosensitive resin composition; a photosensitive dry film manufacturing method; a patterned resist film manufacturing method using the chemically amplified positive-type photosensitive resin composition; a method for manufacturing a substrate with a template by using the chemically amplified positive-type photosensitive resin composition; and a plated article manufacturing method using the substrate with a template. The chemically amplified positive-type photosensitive resin composition includes an acid generator and a resin whose solubility in alkali increases under action of an acid, the acid generator including an acid generator having a specific naphthalimide skeleton, and the proportion of an acrylic resin with respect to the sum of the resin and resins other than the resin is not less than 70 mass %.

### TECHNICAL FIELD

The present invention relates to a chemically amplified positive-type photosensitive resin composition, a photosensitive dry film having a photosensitive resin layer formed from the chemically amplified positive-type photosensitive resin composition, a method of manufacturing the photosensitive dry film, a method of manufacturing a patterned resist film using the chemically amplified positive-type photosensitive resin composition, a method of manufacturing a substrate with a template using the chemically amplified positive-type photosensitive resin composition, and a method of manufacturing a plated article using the substrate with a template.

### BACKGROUND ART

Photofabrication is now the mainstream of a microfabrication technique. The manufacturing is carried out by applying a photoresist composition to the surface of a processing target to form a photoresist layer, patterning this photoresist layer using photolithographic techniques, and then conducting chemical etching, electrolytic etching, or electroforming based mainly on electroplating, using the patterned photoresist layer (photoresist pattern) as a mask.

In recent years, high density packaging technologies have progressed in semiconductor packages along with downsizing electronics devices, and the increase in package density has been developed on the basis of mounting multi-pin thin film in packages, miniaturizing of package size, two-dimensional packaging technologies in flip-tip systems or three-dimensional packaging technologies. In these types of high density packaging techniques, connection terminals, for example, protruding electrodes (mounting terminals) known as bumps that protrude above the package or metal posts that extend from peripheral terminals on the wafer and connect rewiring (RDL) with the mounting terminals, are disposed on the surface of the substrate with high precision.

In the photofabrication as described above, a photoresist composition is used, and chemically amplified photoresist compositions containing an acid generator have been known as such a photoresist composition. According to the chemically amplified photoresist composition, an acid is generated from the acid generator upon irradiation with radiation (exposure) and diffusion of the acid is promoted through heat treatment, to cause an acid catalytic reaction with a base resin and the like in the composition resulting in a change to the alkali-solubility of the same.

Such chemically amplified positive-type photoresist compositions are often utilized for the fabrication of etching masks to be used when a substrate is processed by etching (Patent Documents 1 and 2). Specifically, a photoresist layer having a desired film thickness is formed on a substrate using a chemically amplified photoresist composition, then only a portion corresponding to an etching target portion of the photoresist layer is exposed via a predetermined mask pattern, and then the exposed photoresist layer is developed to form a photoresist pattern to be used as an etching mask.

Moreover, the chemically amplified positive-type photoresist compositions are also used, for example, in formation of templates to be used for production of plated articles such as bumps, metal posts, and Cu-rewiring. Specifically, a photoresist layer having a desired film thickness is formed on a support such as a metal substrate using a chemically amplified photoresist composition, and the photoresist layer is exposed through a predetermined mask pattern and is developed, thereby forming a photoresist pattern to be used as a template in which portions for forming plated articles have been selectively removed (stripped). Then, bumps, metal posts, and Cu rewiring can be formed by embedding a conductor such as copper into the removed portions (nonresist portions) using plating, and then removing the surrounding photoresist pattern.
Patent Document 1: Japanese Unexamined Patent Application, Publication No. 2018-169543
Patent Document 2: PCT International Publication No. WO2018/179641
Patent Document 3: Japanese Unexamined Patent Application (Translation of PCT Application), Publication No. 2017-535595
Patent Document 4: Japanese Unexamined Patent Application (Translation of PCT Application), Publication No. 2018-513113
Patent Document 5: Japanese Unexamined Patent Application (Translation of PCT Application), Publication No. 2018-523640
Patent Document 6: Japanese Unexamined Patent Application, Publication No. 2018-087970
Patent Document 7: Japanese Unexamined Patent Application, Publication No. 2015-087759
Patent Document 8: Japanese Unexamined Patent Application, Publication No. 2017-107211
Patent Document 9: Japanese Unexamined Patent Application, Publication No. 2018-018087

### DISCLOSURE OF THE INVENTION

### Problems to be Solved by the Invention

It is considered that h-line may be used as exposure light for a panel level package having a larger area than a wafer level. Therefore, it is desirable that a photoresist composition is applicable to exposure to h-line.

For example, Patent Documents 3 to 5 disclose chemically amplified negative-type or positive-type photoresist compositions used for exposure to g-line, h-line, and an i-line. However, when the photosensitive resin compositions described in Patent Documents 3 to 5 are used, plating solution resistance was bad, and therefore, shape of resist patterns may be changed due to the plating process.

Patent Documents 4 to 9 disclose chemically amplified positive-type photoresist compositions to be used for producing templates for forming plated articles. However, when the chemically amplified positive-type photoresist compositions described in these documents were used, during the plating treatment in which a conductor such as copper is embedded by plating, shapes of resist patterns were often changed due to contact with the plating treatment solution, and it was difficult to form plated articles such as a bump, a metal post, and Cu rewiring, etc. having desired shapes.

Therefore, the chemically amplified positive-type photoresist compositions to be used for producing templates for forming plated articles are required to be able to suppress shapes of resist patterns from changing due to a plating treatment, that is, to have excellent plating solution resistance.

Further, when there are cracks in the resist pattern serving as a template for forming a plated article, it is difficult to form a plated article of a desired shape. Therefore, chemically amplified positive-type photoresist compositions to be used for producing templates for forming plated articles are also required to be able to suppress occurrence of cracks, that is, to have excellent crack resistance.

The present invention has been made in view of the above-mentioned problem. An object of the present invention is to provide a chemically amplified positive-type photosensitive resin composition which is applicable to exposure to h-line and with which a resist pattern having excellent plating solution resistance and crack resistance is easily formed, a photosensitive dry film having a photosensitive resin layer formed from the chemically amplified positive-type photosensitive resin composition, a method of manufacturing the photosensitive dry film, a method of manufacturing a patterned resist film using the chemically amplified positive-type photosensitive resin composition, a method of manufacturing a substrate with a template using the chemically amplified positive-type photosensitive resin composition, and a method of manufacturing a plated article using the substrate with a template.

### Means for Solving the Problems

As a result of extensive research to achieve the above object, the present inventors have found that the problem of the present invention can be solved by a chemically amplified positive-type photosensitive resin composition, including an acid generator (A) which generates acid upon exposure to an irradiated active ray or radiation and a resin (B) whose solubility in alkali increases under an action of acid, provided that the acid generator (A) is at least one compound selected from a compound represented by the following formula (a1-i) or the following formula (a1-ii), a compound represented by the following formula (a2-i) or the following formula (a2-ii), and a compound represented by the following formula (a3-i) or the following formula (a3-ii); and an acrylic resin which is a resin containing an acrylic constituent unit derived from a (meth)acrylic acid or a (meth)acrylic acid derivative in a content of 70 mol % or more is formulated in a content of 70% by mass or more with respect to a total of the resin (B) and a resin other than the resin (B). Thereby, the present inventors have completed the present invention. Specifically, the present invention provides the followings.

A first aspect of the present invention is a chemically amplified positive-type photosensitive resin composition, which is used for manufacturing a template for forming a plated article by embedding a metal by a plating treatment on a substrate having a metal surface and which contains an acid generator (A) which generates acid upon exposure to an irradiated active ray or radiation, and a resin (B) whose solubility in alkali increases under an action of acid. The acid generator (A) includes at least one compound selected from: a compound represented by the following formula (a1-i) or (a1-ii):

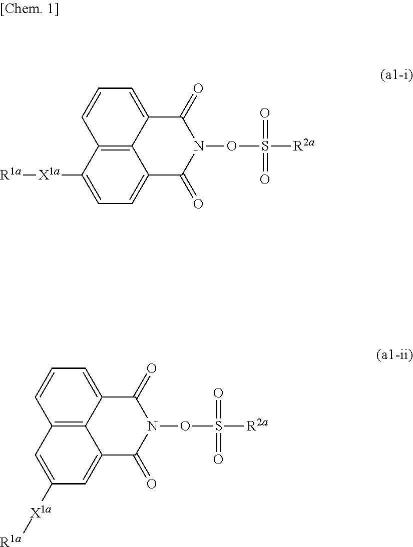

(in the formulae (a1-i) and (a1-ii), X^{1a} is an oxygen atom or a sulfur atom;
R^{1a} is selected from the group consisting of an aliphatic group having 1 or more and 18 or less carbon atoms, optionally substituted with one or more halogen atoms;
an aliphatic group having 2 or more and 18 or less carbon atoms, including at least one moiety selected from the group consisting of —S—, —C(═O)—S—, —O—S(═O)₂—, —O—C(═O)—O—, —C(═O)—NH—, —C(═O)—NR^{10a}—, and —C(═O)—NR^{10a}R^{11a}, and optionally substituted with one or more halogen atoms;
a group represented by the following formula (a11):

[Chem. 2]

—R^{3a}—Ar (a11)

a group represented by the following formula (a12):

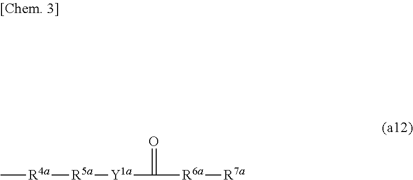

and
a group represented by the following formula (a13):

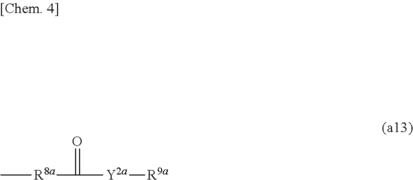

wherein in the formula (a11), R^{3a} is a single bond, or an aliphatic group having 1 or more and 20 or less carbon atoms, optionally including at least one moiety selected from the group consisting of —O—, —S—, —C(═O)—O—, —C(═O)—S—, —O—S(═O)₂—, —O—C(═O)—O—, —C(═O)—NH—, —O—C(═O)—NH—, —C(═O)—NR^{10a}—, and —C(═O)—NR^{10a}—,
Ar is an aromatic group which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group,
in the formula (a12), R^{4a} and R^{5a} are each independently an aliphatic group having 1 or more and 5 or less carbon atoms;
Y^{1a} is an oxygen atom;
R^{6a} is an aliphatic group having 1 or more and 10 or less carbon atoms, and
R^{7a} is an aliphatic group having 1 or more and 18 or less carbon atoms, including at least one moiety selected from the group consisting of —O—, —S—, —C(═O)—S—, —O—S(═O)₂—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a},
in the formula (a13), R^{8a} is an aliphatic group having 2 or more and 18 or less carbon atoms, optionally including at least one moiety selected from the group consisting of —O—, —S—, —C(═O)—S—, —O—S(═O)₂—, —O—C(═O)—O—, —C(═O)—NH—, —O—C(═O)—NH—, —C(═O)—NR^{10a}—, and —O—C(═O)—NR^{10a}—,
Y^{2a} is an oxygen atom;
R^{9a} is an aliphatic group having 1 or more and 18 or less carbon atoms, including at least one moiety selected from the group consisting of —O—, —S—, —C(═O)—O—, —C(═O)—S—, —O—S(═O)₂—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a},
R^{10a} and R^{11a} are each an aliphatic group having 1 or more and 10 or less carbon atoms, and in —C(═O)—NR^{10a}R^{11a}, R^{10a} and R^{11a} may be the same as or different from each other, and bonded to each other to form an alicyclic group, and
R^{2a} is selected from the group consisting of an aliphatic group having 1 or more and 18 or less carbon atoms, optionally substituted with one or more halogen atoms;
an aliphatic group having 3 or more and 18 or less carbon atoms, including at least one moiety selected from the group consisting of —O—, —S—, —C(═O)—O—, —C(═O)—S—, —O—S(═O)₂—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms;
an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxy carbonyl group, an alkylsulfonyl group, an alkylsulfinyl group, an aryl group, an alkyl aryl group, a cyano group, and a nitro group;
and an alkyl group substituted with an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxy carbonyl group, an alkylsulfonyl group, an alkylsulfinyl group, an aryl group, an alkyl aryl group, a cyano group, and a nitro group),
a compound represented by the following formula (a2-i) or (a2-ii):

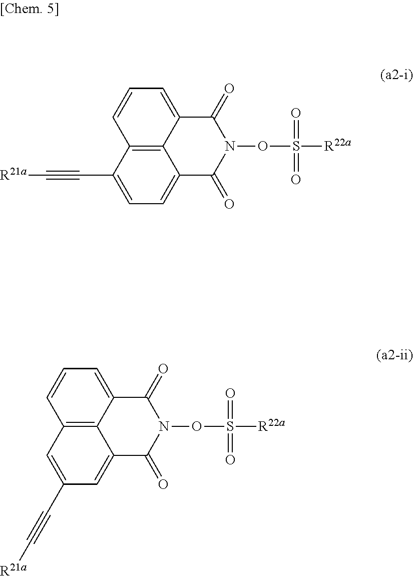

(in the formulae (a2-i) to (a2-ii), R^{21a} is a hydrogen atom;
an aliphatic group having 1 or more and 18 or less carbon atoms, optionally substituted with one or more halogen atoms;
or
an aliphatic group having 2 or more and 18 or less carbon atoms, optionally including at least one moiety selected from the group consisting of —O—, —S—, —C(═O)—, —C(═O)—O—, —C(═O)—S—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms,
R^{22a} is selected from the group consisting of —CH₃, —CH₂F, —CHF₂, —CF₃, or an aliphatic group having 2 or more and 18 or less carbon atoms, optionally substituted with one or more halogen atoms;
an aliphatic group having 2 or more and 18 or less carbon atoms, including at least one moiety selected from the group consisting of —O—, —S—, —C(═O)—, —C(═O)—O—, —C(═O)—S—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms;
an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group; and
an alkyl group substituted with an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group,
wherein when R^{22a} is —CF₃, R^{21a} is a group selected from the group consisting of a hydrogen atom;
an aliphatic group having 2 or more and 18 or less carbon atoms, optionally including at least one moiety selected from the group consisting of —O—, —S—, —C(═O)—, —C(═O)—O—, —C(═O)—S—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms;
—CH₂CH(CH₃)₂, —CH₂CH═CHCH₃, or —CH₂CH₂CH═CH₂;
a group represented by the following formula (a21):

[Chem. 6]

—CH₂—R^{23a} (a21)

and
a group represented by the following formula (a22):

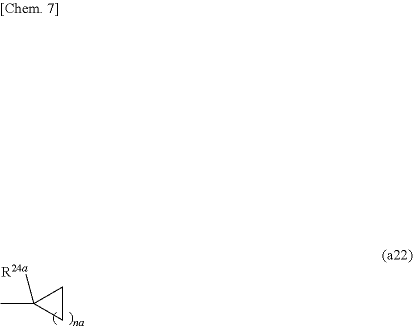

R^{10a} and R^{11a} are each an aliphatic group having 1 or more and 10 or less carbon atoms, and in —C(═O)—NR^{10a}R^{11a}, R^{10a} and R^{11a} may be the same as or different from each other, and bonded to each other to form an alicyclic group,
in the formula (a21), R^{23a} is an aliphatic group having 4 or more and 18 or less carbon atoms,
in the formula (a22), R^{24a} is a hydrogen atom, or an alkyl group having 1 or more and 10 or less carbon atoms, and na is an integer of 1 to 5)
and
a compound represented by the following formulae (a3-i) or (a3-ii):

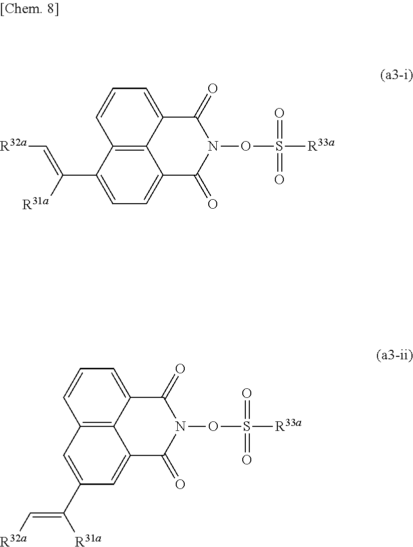

(in the formulae (a3-i) to (a3-ii), R^{31a}, and R^{32a} are each independently a group selected from the group consisting of a hydrogen atom;
a cyano group;
an aliphatic group having 1 or more and 18 or less carbon atoms, optionally substituted with one or more halogen atoms;
an aliphatic group having 1 or more and 18 or less carbon atoms, including at least one moiety selected from the group consisting of —O—, —S—, —C(═O)—, —C(═O)—O—, —C(═O)—S—, —OC(═O)—O—, —CN, —C(═O)—NH—, —C(═O)—NR^{10a}—, and —C(═O)—NR^{10a}R^{11a}, and optionally substituted with one or more halogen atoms; and
an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group;
R^{31a} and R^{32a} may be the same as or different from each other, and bonded to each other to form an alicyclic group or a heterocyclic group,
R^{33a} is selected from the group consisting of an aliphatic group having 1 or more and 18 or less carbon atoms, optionally substituted with one or more halogen atoms;
an aliphatic group having 1 or more and 18 or less carbon atoms, including at least one moiety selected from the group consisting of —O—, —S—, —C(═O)—, —C(═O)—O—, —C(═O)—S—, —O—C(═O)—O—, —CN, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms; and
an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group, R^{10a} and R^{11a} are each an aliphatic group having 1 or more and 10 or less carbon atoms, and in —C(═O)—NR^{10a}R^{11a}, R^{10a} and R^{11a} may be the same as or different from each other, and bonded to each other to form an alicyclic group).
Additionally, the chemically amplified positive-type photosensitive resin composition includes an acrylic resin that is a resin including an acrylic constituent unit that is a constituent unit derived from (meth)acrylic acid or (meth)acrylic acid derivative in a content of 70 mol % or more,
and
a ratio of the acrylic resin to a total of the resin (B) and a resin other than the resin (B) is 70% by mass or more.

A second aspect of the present invention is a photosensitive dry film including a substrate film, and a photosensitive resin layer formed on a surface of the substrate film, in which the photosensitive resin layer includes the chemically amplified positive-type photosensitive resin composition as described in the first aspect.

A third aspect of the present invention is a method of manufacturing a photosensitive dry film, the method including applying the chemically amplified positive-type photosensitive resin composition as described in the first aspect to a substrate film to form a photosensitive resin layer.

A fourth aspect of the present invention is a method of manufacturing a patterned resist film, the method including: laminating a photosensitive resin layer on a substrate, the layer including the chemically amplified positive-type photosensitive resin composition as described in the first aspect;

exposing the photosensitive resin layer through irradiation with an active ray or radiation in a position-selective manner; and
developing the exposed photosensitive resin layer.

A fifth aspect of the present invention is a method of manufacturing a substrate with a template, the method including:

laminating a photosensitive resin layer on a substrate having a metal surface, the layer including the chemically amplified positive-type photosensitive resin composition as described in the first aspect;
exposing the photosensitive resin layer through irradiation with an active ray or radiation in a position-selective manner; and
developing the exposed photosensitive resin layer to form a template for forming a plated article.

A sixth aspect of the present invention is a method of manufacturing a plated article, the method including plating a substrate with a template to form the plated article in the template, the substrate with a template being manufactured by the method of manufacturing a substrate with a template as described in the fifth aspect.

### Effects of the Invention

The present invention can provide a chemically amplified positive-type photosensitive resin composition which is applicable to exposure to h-line and with which a resist pattern having excellent plating solution resistance and crack resistance is easily formed, a photosensitive dry film having a photosensitive resin layer formed of the chemically amplified positive-type photosensitive resin composition, a method of manufacturing the photosensitive dry film, a method of manufacturing a patterned resist film using the chemically amplified positive-type photosensitive resin composition, a method of manufacturing a substrate with a template using the chemically amplified positive-type photosensitive resin composition, and a method of manufacturing a plated article using the substrate with a template.

### PREFERRED MODE FOR CARRYING OUT THE INVENTION

### <<Chemically Amplified Positive-Type Photosensitive Resin Composition>>

The chemically amplified positive-type photosensitive resin composition (hereinafter, also referred to as a “photosensitive resin composition”) is used for manufacturing a template for forming a plated article by embedding metal on a substrate having a metal surface by plating treatment. The photosensitive resin composition includes an acid generator (A) which generates acid upon exposure to an irradiated active ray or radiation (hereinafter also referred to as the acid generator (A)), and a resin (B) whose solubility in alkali increases under an action of acid (hereinafter also referred to as the resin (B)). Furthermore, in the present invention, the acid generator (A) includes at least one selected from compounds represented by the following formula (a1-i) or the following formula (a1-ii), compounds represented by the following formula (a2-i) or the following formula (a2-ii), and compounds represented by the following formula (a3-i) or the following formula (a3-ii). The photosensitive resin composition includes an acrylic resin that is a resin including an acrylic constituent unit derived from (meth)acrylic acid or a (meth)acrylic acid derivative in a content of 70 mol % or more. A ratio of the acrylic resin with respect to a total of the resin (B) and a resin other than the resin (B) is 70% by mass or more.

In the photosensitive resin composition including an acid generator (A) which generates acid upon exposure to an irradiated active ray or radiation, and a resin (B) whose solubility in alkali increases under an action of acid, when a specific acid generator is blended, and a ratio of a content of the acrylic resin to a total of the resin (B) and a resin other than the resin (B) is set to a specific range, the photosensitive resin composition is applicable to exposure to h-line, and a resist pattern having excellent plating solution resistance and crack resistance is easily formed using the photosensitive resin composition, as shown in the Examples described below.

The photosensitive resin composition may include components such as a phenolic hydroxyl group-containing low molecular weight compound (C), an alkali-soluble resin (D), a sulfur-containing compound (E), an acid diffusion suppressing agent (F), an organic solvent (S), and the like, as necessary.

Hereinafter, described are essential or optional components in the photosensitive resin composition, and a method for manufacturing the photosensitive resin composition.

### <Acid Generator (A)>

The acid generator (A) is a compound which is capable of generating an acid when irradiated with an active ray or radiation, and which directly or indirectly generates an acid under the action of light. The acid generator (A) includes at least one compound selected from compounds represented by the following formula (a1-i) or the following formula (a1-ii), compounds represented by the following formula (a2-i) or the following formula (a2-ii), and the compounds represented by the following formula (a3-i) or the following formula (a3-ii).

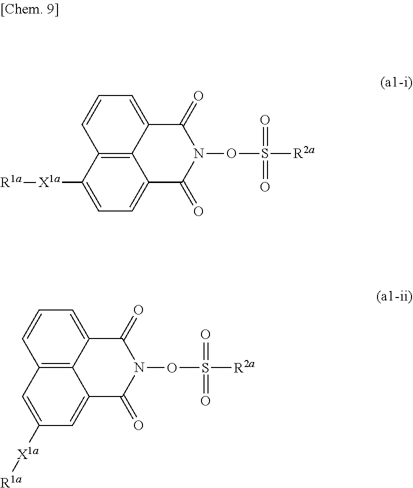

(In the formulae (a1-i) and (a1-ii), X^{1a} is an oxygen atom or a sulfur atom;
R^{1a} is selected from the group consisting of an aliphatic group having 1 or more and 18 or less carbon atoms, optionally substituted with one or more halogen atoms;
an aliphatic group having 2 or more and 18 or less carbon atoms, including at least one moiety selected from the group consisting of —S—, —C(═O)—S—, —O—S(═O)₂—, —O—C(═O)—O—, —C(═O)—NH—, —C(═O)—NR^{10a}—, and —C(═O)—NR^{10a}R^{11a}, and optionally substituted with one or more halogen atoms;
a group represented by the following formula (a11):

[Chem. 10]

—R^{3a}—Ar (a11)

a group represented by the following formula (a12):

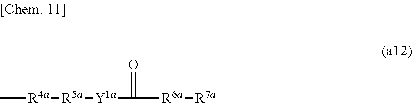

and
a group represented by the following formula (a13):

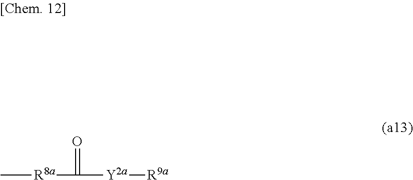

wherein in the formula (a11), R^{3a} is a single bond, or an aliphatic group having 1 or more and 20 or less carbon atoms, optionally including at least one moiety selected from the group consisting of —O—, —S—, —C(═O)—O—, —C(═O)—S—, —O—S(═O)₂—, —O—C(═O)—O—, —C(═O)—NH—, —O—C(═O)—NH—, —C(═O)—NR^{10a}—, and —C(═O)—NR^{10a}—,
Ar is an aromatic group which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group,
in the formula (a12), R^{4a}, and R^{5a} are each independently an aliphatic group having 1 or more and 5 or less carbon atoms,
Y^{1a} is an oxygen atom,
R^{6a} is an aliphatic group having 1 or more and 10 or less carbon atoms, and
R^{7a} is an aliphatic group having 1 or more and 18 or less carbon atoms, including at least one moiety selected from the group consisting of —O—, —S—, —C(═O)—S—, —O—S(═O)₂—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a},
in the formula (a13), R^{8a} is an aliphatic group having 2 or more and 18 or less carbon atoms, optionally including at least one moiety selected from the group consisting of —O—, —S—, —C(═O)—S—, —O—S(═O)₂—, —O—C(═O)—O—, —C(═O)—NH—, —O—C(═O)—NH—, —C(═O)—NR^{10a}—, and —O—C(═O)—NR^{10a}—,
Y^{2a} is an oxygen atom,
R^{9a} is an aliphatic group having 1 or more and 18 or less carbon atoms, including at least one moiety selected from the group consisting of —O—, —S—, —C(═O)—O—, —C(═O)—S—, —O—S(═O)₂—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a},
R^{10a} and R^{11a} are each an aliphatic group having 1 or more and 10 or less carbon atoms, and in —C(═O)—NR^{10a}R^{11a}, R^{10a} and R^{11a} may be the same as or different from each other, and bonded to each other to form an alicyclic group, and
R^{2a} is selected from the group consisting of an aliphatic group having 1 or more and 18 or less carbon atoms, optionally substituted with one or more halogen atoms;
an aliphatic group having 3 or more and 18 or less carbon atoms, including at least one moiety selected from the group consisting of —O—, —S—, —C(═O)—O—, —C(═O)—S—, —O—S(═O)₂—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms;
an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxy carbonyl group, an alkylsulfonyl group, an alkylsulfinyl group, an aryl group, an alkyl aryl group, a cyano group, and a nitro group; and
an alkyl group substituted with an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxy carbonyl group, an alkylsulfonyl group, an alkylsulfinyl group, an aryl group, an alkyl aryl group, a cyano group, and a nitro group.)

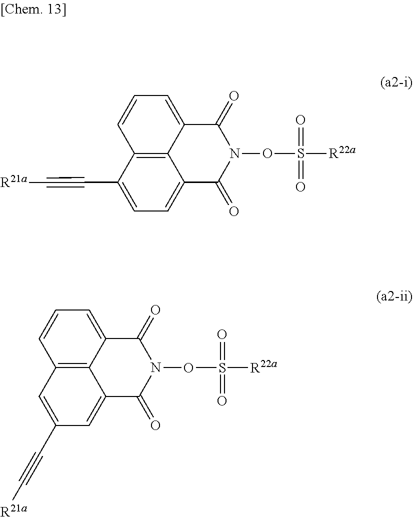

(In the formulae (a2-i) to (a2-ii), R^{21a} is a hydrogen atom;
an aliphatic group having 1 or more and 18 or less carbon atoms, optionally substituted with one or more halogen atoms;
or
an aliphatic group having 2 or more and 18 or less carbon atoms, optionally including at least one moiety selected from the group consisting of —O—, —S—, —C(═O)—, —C(═O)—O—, —C(═O)—S—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms,
R^{22a} is selected from the group consisting of —CH₃, —CH₂F, —CHF₂, —CF₃, or an aliphatic group having 2 or more and 18 or less carbon atoms, optionally substituted with one or more halogen atoms;
an aliphatic group having 2 or more and 18 or less carbon atoms, including at least one moiety selected from the group consisting of —O—, —S—, —C(═O)—, —C(═O)—O—, —C(═O)—S—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms;
an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group; and
an alkyl group substituted with an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group,
wherein when R^{22a} is —CF₃, R^{21a} is a group selected from the group consisting of a hydrogen atom;
an aliphatic group having 2 or more and 18 or less carbon atoms, optionally including at least one moiety selected from the group consisting of —O—, —S—, —C(═O)—, —C(═O)—O—, —C(═O)—S—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms;
—CH₂CH(CH₃)₂, —CH₂CH═CHCH₃, or —CH₂CH₂CH═CH₂;
a group represented by the following formula (a21):

[Chem. 14]

—CH₂—R^{23a} (a21)

and
a group represented by the following formula (a22):

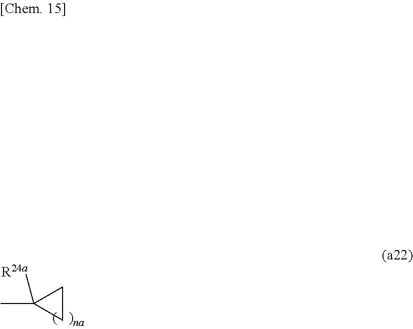

R^{10a} and R^{11a} are each an aliphatic group having 1 or more and 10 or less carbon atoms, and in —C(═O)—NR^{10a}R^{11a}, R^{10a} and R^{11a} may be the same as or different from each other, and bonded to each other to form an alicyclic group,
in the formula (a21), R^{23a} is an aliphatic group having 4 or more and 18 or less carbon atoms,
in the formula (a22), R^{24a} is a hydrogen atom, or an alkyl group having 1 or more and 10 or less carbon atoms, and na is an integer of 1 to 5.)

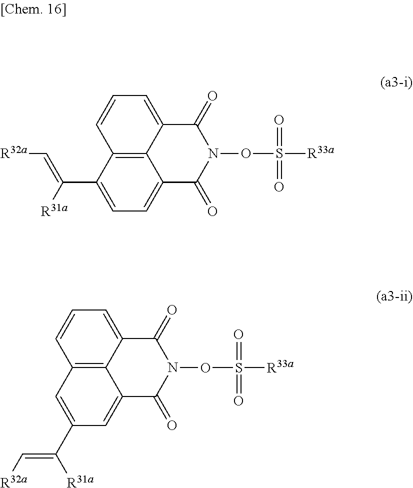

wherein in the formulae (a3-i) to (a3-ii), R^{31a} and R^{32a} are each independently a group selected from the group consisting of a hydrogen atom;
a cyano group;
an aliphatic group having 1 or more and 18 or less carbon atoms, optionally substituted with one or more halogen atoms;
an aliphatic group having 1 or more and 18 or less carbon atoms, including at least one moiety selected from the group consisting of —O—, —S—, —C(═O)—, —C(═O)—O—, —C(═O)—S—, —OC(═O)—O—, —CN, —C(═O)—NH—, —C(═O)—NR^{10a}—, and —C(═O)—NR^{10a}R^{11a}, and optionally substituted with one or more halogen atoms; and
an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group;
R^{31a} and R^{32a} may be the same as or different from each other, and bonded to each other to form an alicyclic group or a heterocyclic group,
R^{33a} is selected from the group consisting of an aliphatic group having 1 or more and 18 or less carbon atoms, optionally substituted with one or more halogen atoms;
an aliphatic group having 1 or more and 18 or less carbon atoms, including at least one moiety selected from the group consisting of —O—, —S—, —C(═O)—, —C(═O)—O—, —C(═O)—S—, —O—C(═O)—O—, —CN, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms; and
an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group, R^{10a} and R^{11a} are each an aliphatic group having 1 or more and 10 or less carbon atoms, and in —C(═O)—NR^{10a}R^{11a}, R^{10a} and R^{11a} may be the same as or different from each other, and bonded to each other to form an alicyclic group.)

The aliphatic groups in the formulae (a1-i), (a1-ii), (a2-i), (a2-ii), (a3-i), (a3-ii), (a11) to (a13), (a21), and (a22) each may be a chain, cyclic, or a structure including a chain structure and a cyclic structure. Furthermore, the aliphatic group may include a hetero atom, and may be a chain aliphatic group including a hetero atom such as a nitrogen atom, and a sulfur atom, or a heterocyclic aliphatic group. The chain aliphatic group may be linear or branched. Examples of the chain aliphatic group include an alkyl group, an alkenyl group, and an alkynyl group. Examples of the alkyl group include linear alkyl groups such as a methyl group, an ethyl group, an n-propyl group, an n-butyl group, an n-pentyl group, an n-hexyl group, an n-octyl group, an n-nonyl group, an n-decyl group, an n-undecyl group, and an n-dodecyl group; branched alkyl groups such as an isopropyl group, an isobutyl group, a sec-butyl group, a tert-butyl group, an isopentyl group, a neopentyl group, a tert-pentyl group, an isohexyl group, a 2-ethyl hexyl group, and a 1,1,3,3-tetramethyl butyl group. Examples of the alkenyl group include a 3-butenyl group, a pentenyl group, a hexenyl group, a heptenyl group, an octenyl group, a nonenyl group, and a decenyl group. Examples of the alkynyl groups include a pentynyl group, a hexynyl group, a heptynyl group, an octynyl group, a nonynyl group, and a decynyl group. In the alkyl group, the alkenyl group, and the alkynyl group, hydrogen atoms bonded to these groups may be substituted with one or more substituents. Examples of the substituents include a halogen atom, a cyano group, an oxoalkoxy group, a hydroxy group, an amino group, a nitro group, an aryl group, and an alkyl group substituted with a halogen atom. Examples of the cyclic aliphatic group include cycloalkyl group such as a cyclopropyl group, a cyclobutyl group, a cyclopentyl group, a cyclohexyl group, a cycloheptyl group, an adamantyl group, a norbornyl group, a cubyl group, an octahydro-indenyl group, a decahydro-naphthyl group, bicyclo[3.2.1]octyl group, a bicyclo[2.2.2]octyl group, a bicyclo[3.3.1]nonyl group, a bicyclo[3.3.2]decyl group, a bicyclo[2.2.2]octyl group, an azacycloalkyl group, an ((aminocarbonyl)cycloalkyl)cycloalkyl group.

The aromatic groups in the above formula each may be an aromatic hydrocarbon group, or an aromatic heterocyclic group including a hetero atom such as a nitrogen atom, an oxygen atom, and a sulfur atom. Examples of the aromatic hydrocarbon group include aryl groups such as monocyclic groups (phenyl group, and the like), bicyclic groups (a naphthyl group, a biphenyl group, and the like), and tricyclic groups (a fluorenyl, and the like), aralkyl groups such as a benzyl group, and a phenethyl group. Examples of the aromatic heterocyclic group include heteroaryl groups such as a furyl group and a thienyl group. These aromatic hydrocarbon groups and aromatic heterocyclic groups may have an alkyl group as the substituent. The alkyl group are the same as mentioned above.

In the above, as the aliphatic group and the aromatic group, a monovalent group is exemplified. A divalent group is a group in which one hydrogen atom is removed from the above-mentioned monovalent group.

Halogen atoms as the above formula include a fluorine atom, a chlorine atom, a bromine atom, an iodine atom and the like.

The alkyl group and aryl group in the alkoxy group (alkyl group-O—), alkylthio group (alkyl group-S—), dialkylamino group ((alkyl group)₂N—), acyloxy group (alkyl group-carbonyl group —O—), acylthio group (alkyl group-carbonyl group —S—), acylamino group (alkyl group-carbonyl group —NH—), alkoxy carbonyl group, alkylsulfonyl group, alkylsulfinyl group, aryl group, alkyl aryl group in the above formula are the same as those mentioned above. The haloalkyl group is an alkyl group substituted with one or more and the maximum possible number or less of halogen atoms. The alkyl group and the halogen atom are the same as those mentioned above. The haloalkoxy group in the above formula is an alkoxy group substituted with one or more and the maximum possible number or less of halogen atoms. The alkyl group or the halogen atom is the same as those mentioned above.

Specific examples of the compound represented by the formula (a1-i) or (a1-ii) includes the compounds having, for example, the following structures.

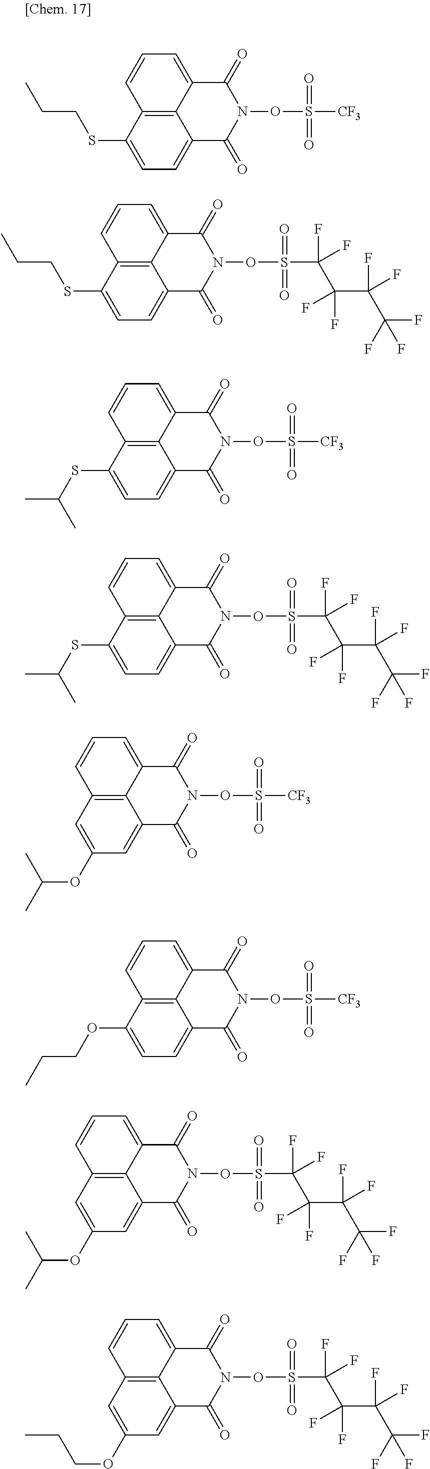

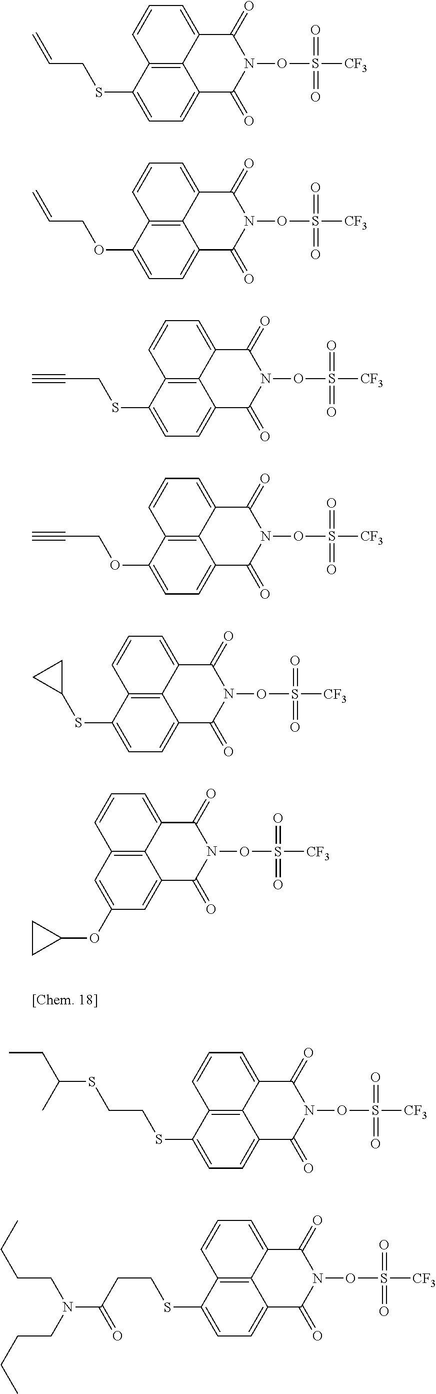

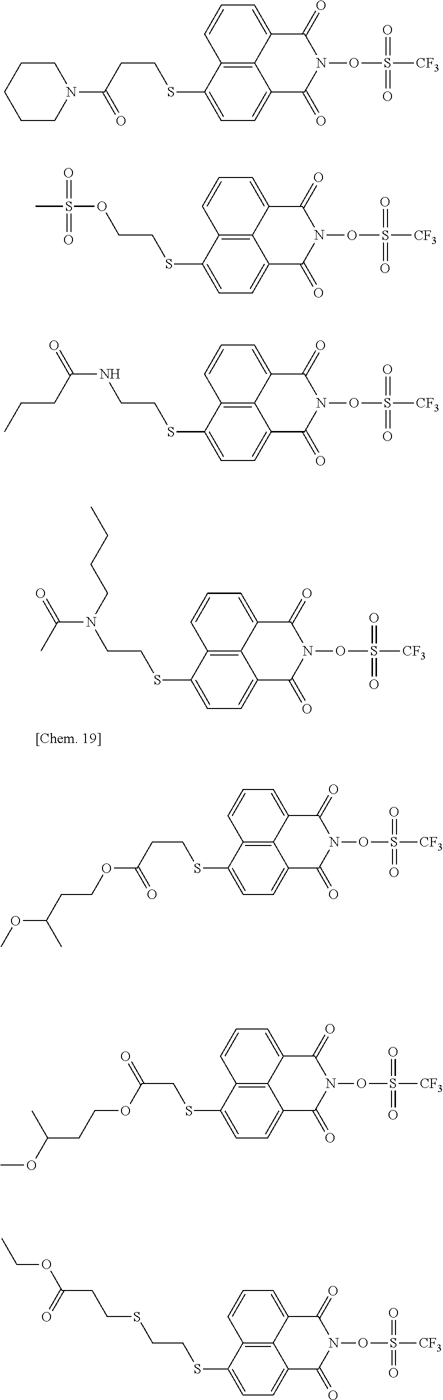

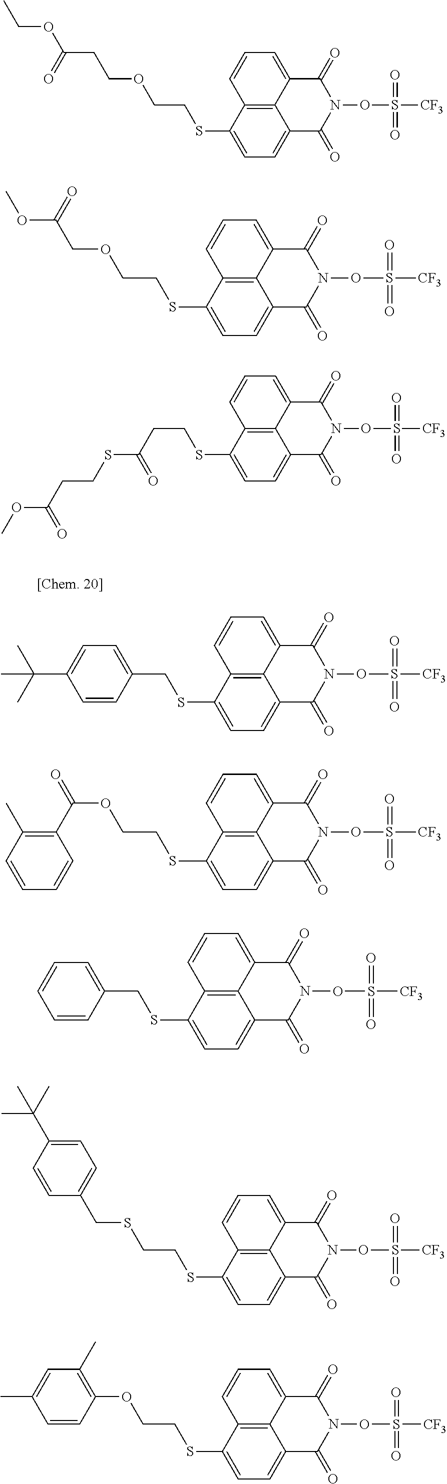

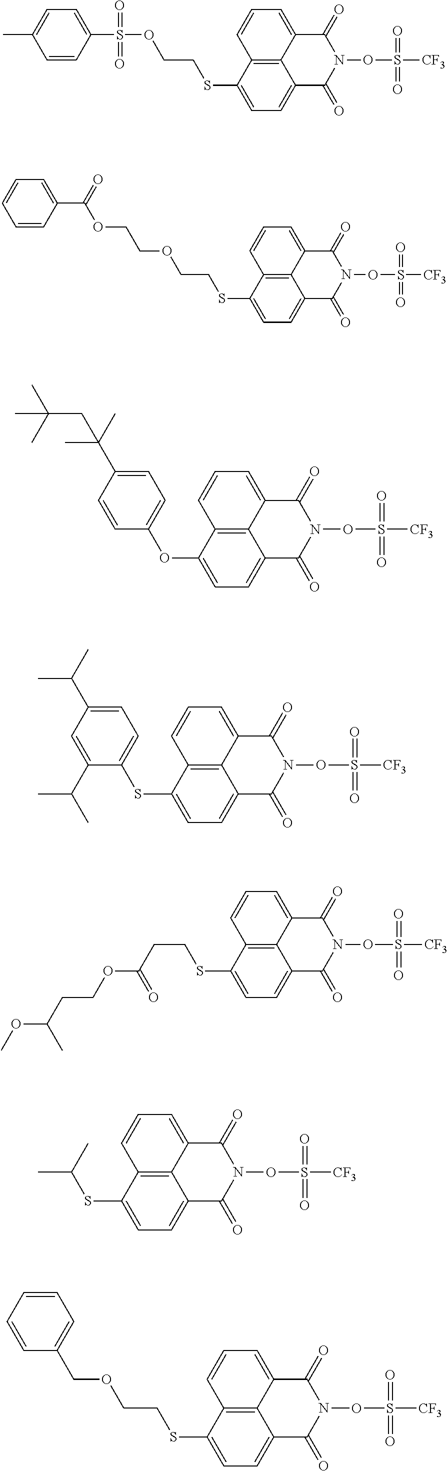

It is preferable in the compounds represented by the formula (a1-i) or (a1-ii) that X^{1a} is a sulfur atom, R^{1a} is linear or branched alkyl group having 1 or more and 3 or less carbon atoms, R^{2a} is a chain aliphatic group having 1 or more and 18 or less carbon atoms substituted with one or more fluorine atoms.

Specific examples of the compounds represented by the formula (a2-i) or (a2-ii) include compounds having the following structures.

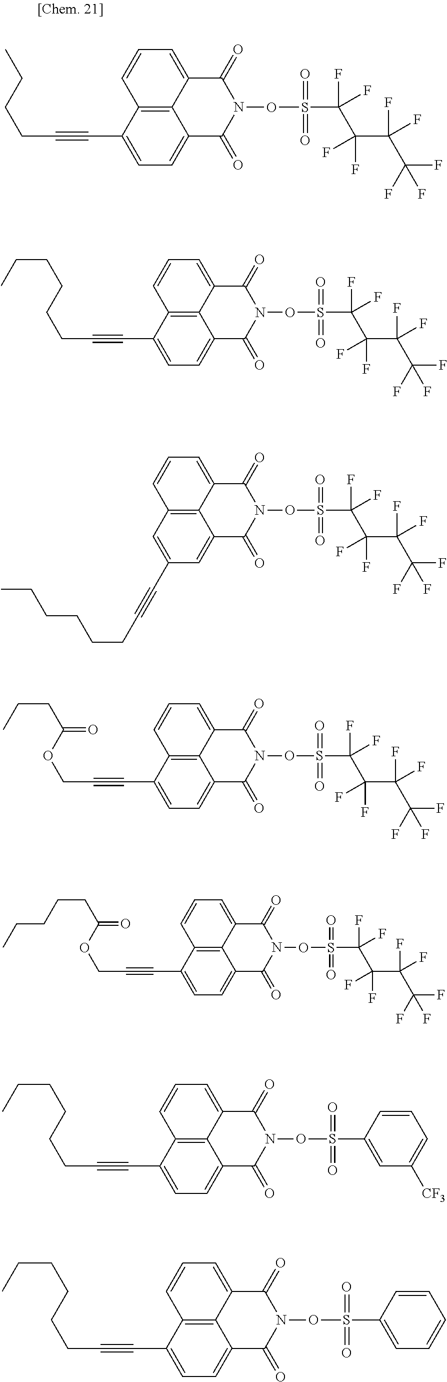

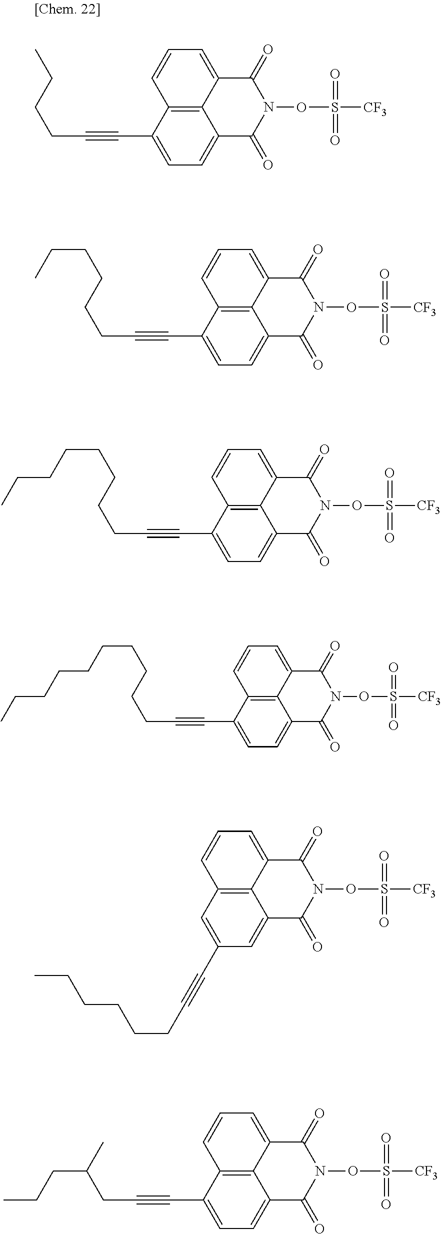 [SMILES: CCCCC#Cc1ccc2c3c(cccc13)C(=O)N(OS(=O)(=O)C(F)(F)F)C2=O ; CCCCCCC#Cc1ccc2c3c(cccc13)C(=O)N(OS(=O)(=O)C(F)(F)F)C2=O ; CCCCCCCCC#Cc1ccc2c3c(cccc13)C(=O)N(OS(=O)(=O)C(F)(F)F)C2=O ; CCCCCCCCCCC#Cc1ccc2c3c(cccc13)C(=O)N(OS(=O)(=O)C(F)(F)F)C2=O ; CCCCCCC#Cc1cc2c3c(cccc3c1)C(=O)N(OS(=O)(=O)C(F)(F)F)C2=O ; CCCC(C)CC#Cc1ccc2c3c(cccc13)C(=O)N(OS(=O)(=O)C(F)(F)F)C2=O]

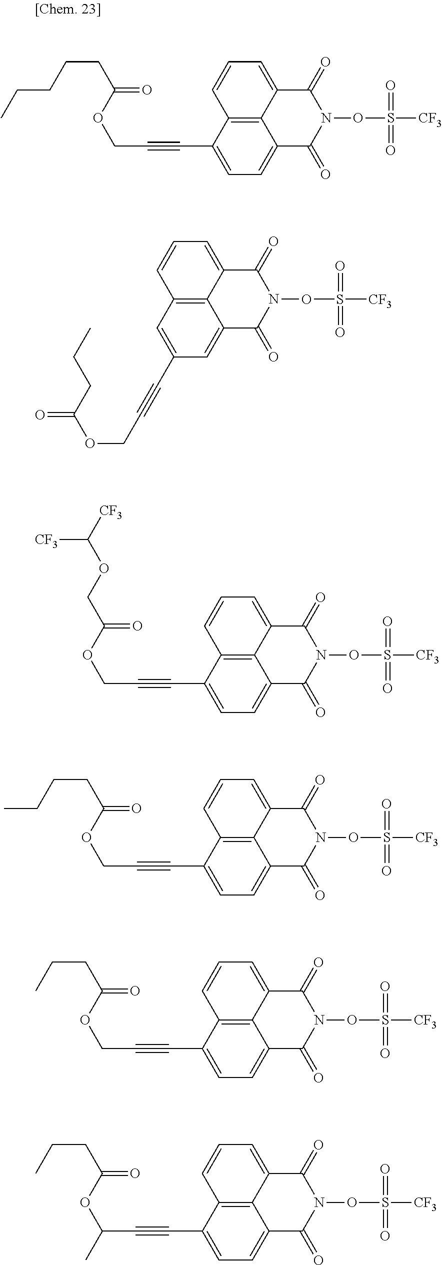 [SMILES: CCCCCC(=O)OCC#Cc1ccc2c3c(cccc13)C(=O)N(OS(=O)(=O)C(F)(F)F)C2=O ; CCCC(=O)OCC#Cc1cc2c3c(cccc3c1)C(=O)N(OS(=O)(=O)C(F)(F)F)C2=O ; O=C(COC(C(F)(F)F)C(F)(F)F)OCC#Cc1ccc2c3c(cccc13)C(=O)N(OS(=O)(=O)C(F)(F)F)C2=O ; CCCCC(=O)OCC#Cc1ccc2c3c(cccc13)C(=O)N(OS(=O)(=O)C(F)(F)F)C2=O ; CCCC(=O)OCC#Cc1ccc2c3c(cccc13)C(=O)N(OS(=O)(=O)C(F)(F)F)C2=O ; CCCC(=O)OC(C)C#Cc1ccc2c3c(cccc13)C(=O)N(OS(=O)(=O)C(F)(F)F)C2=O]

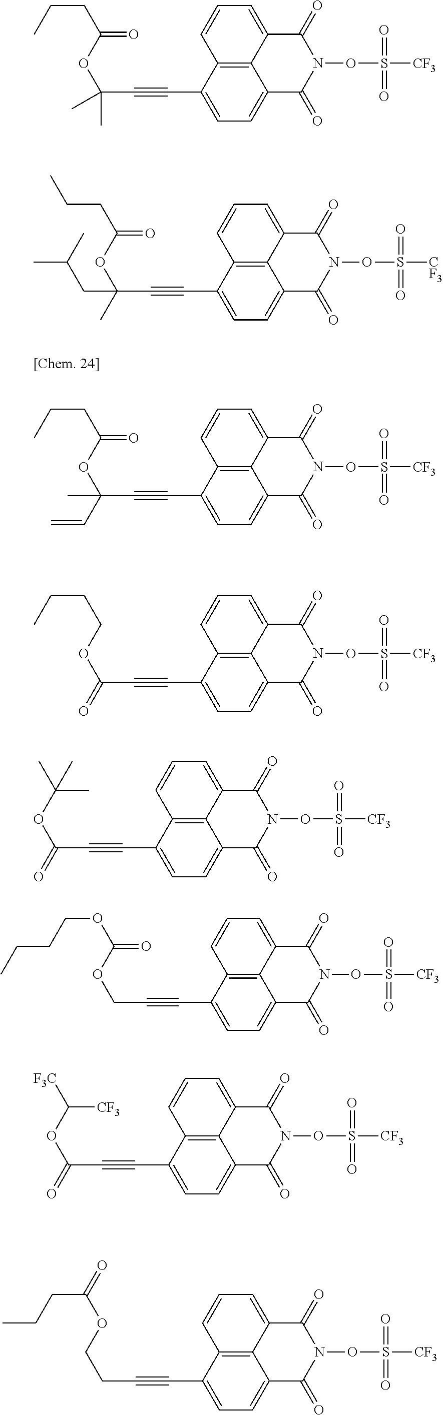

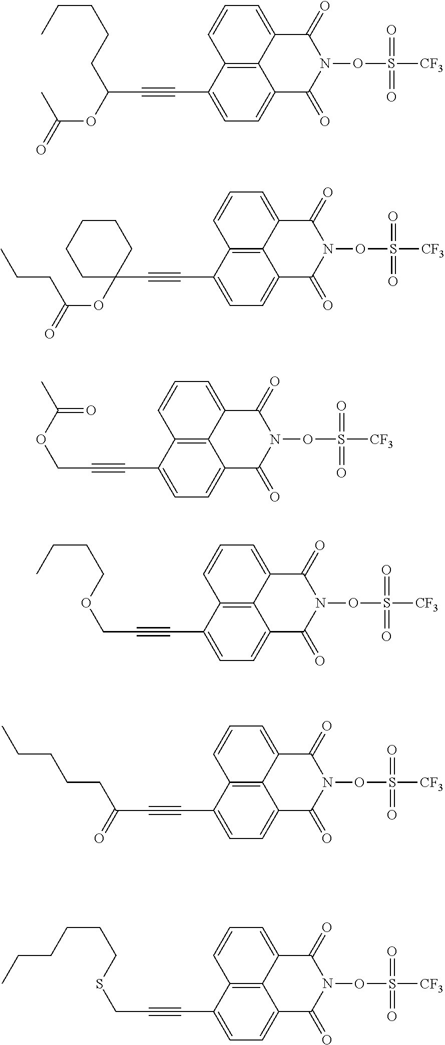 [SMILES: CCCCCC(C#Cc1ccc2c3c(cccc13)C(=O)N(OS(=O)(=O)C(F)(F)F)C2=O)OC(C)=O ; CCCC(=O)OC1(C#Cc2ccc3c4c(cccc24)C(=O)N(OS(=O)(=O)C(F)(F)F)C3=O)CCCCC1 ; CC(=O)OCC#Cc1ccc2c3c(cccc13)C(=O)N(OS(=O)(=O)C(F)(F)F)C2=O ; CCCCOCC#Cc1ccc2c3c(cccc13)C(=O)N(OS(=O)(=O)C(F)(F)F)C2=O ; CCCCCC(=O)C#Cc1ccc2c3c(cccc13)C(=O)N(OS(=O)(=O)C(F)(F)F)C2=O ; CCCCCCSCC#Cc1ccc2c3c(cccc13)C(=O)N(OS(=O)(=O)C(F)(F)F)C2=O]

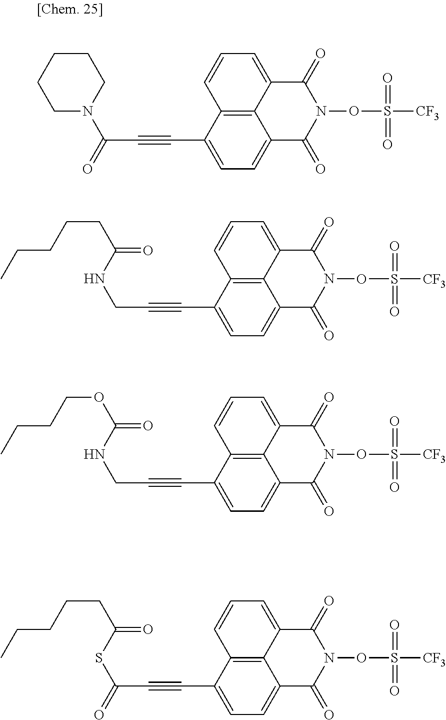 [SMILES: O=C(C#Cc1ccc2c3c(cccc13)C(=O)N(OS(=O)(=O)C(F)(F)F)C2=O)N1CCCCC1 ; CCCCCC(=O)NCC#Cc1ccc2c3c(cccc13)C(=O)N(OS(=O)(=O)C(F)(F)F)C2=O ; CCCCOC(=O)NCC#Cc1ccc2c3c(cccc13)C(=O)N(OS(=O)(=O)C(F)(F)F)C2=O ; CCCCCC(=O)SC(=O)C#Cc1ccc2c3c(cccc13)C(=O)N(OS(=O)(=O)C(F)(F)F)C2=O]

It is preferable in the compounds represented by the formula (a2-i) or (a2-ii) that R^{21a} is a chain aliphatic group having 1 or more and 18 or less carbon atoms, and R^{22a} is a chain aliphatic group having 1 or more and 18 or less carbon atoms, substituted with one or more fluorine atoms.

Specific examples of the compounds represented by the formula (a3-i) or formula (a3-ii) include compounds having the following structures.

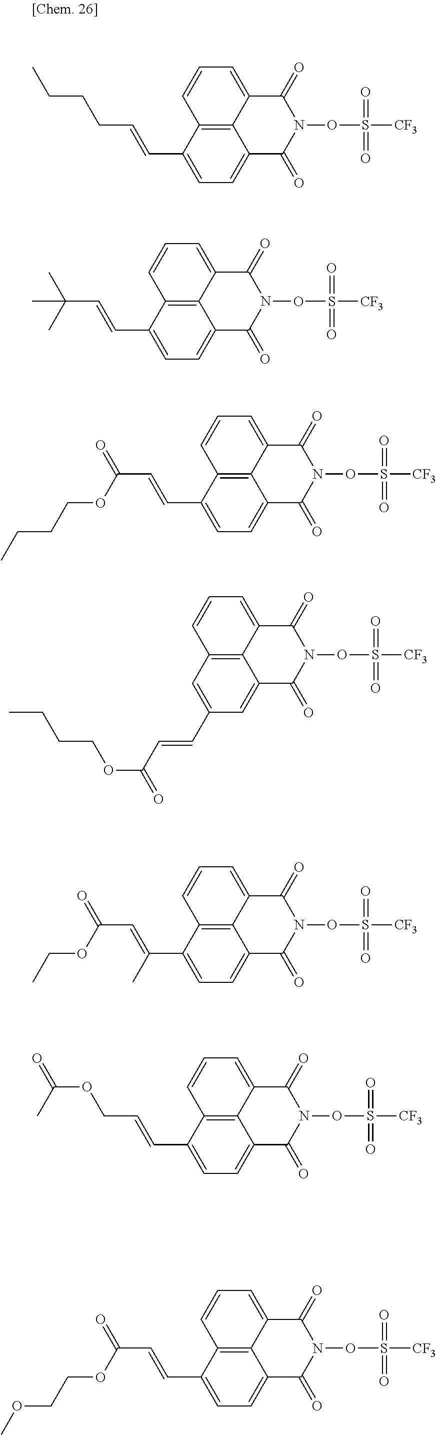

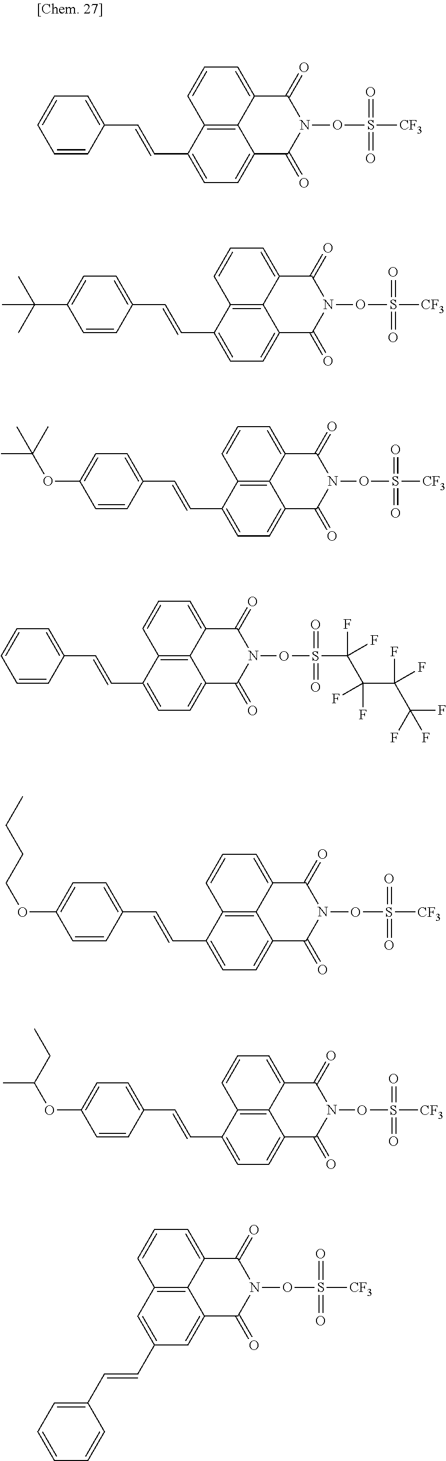

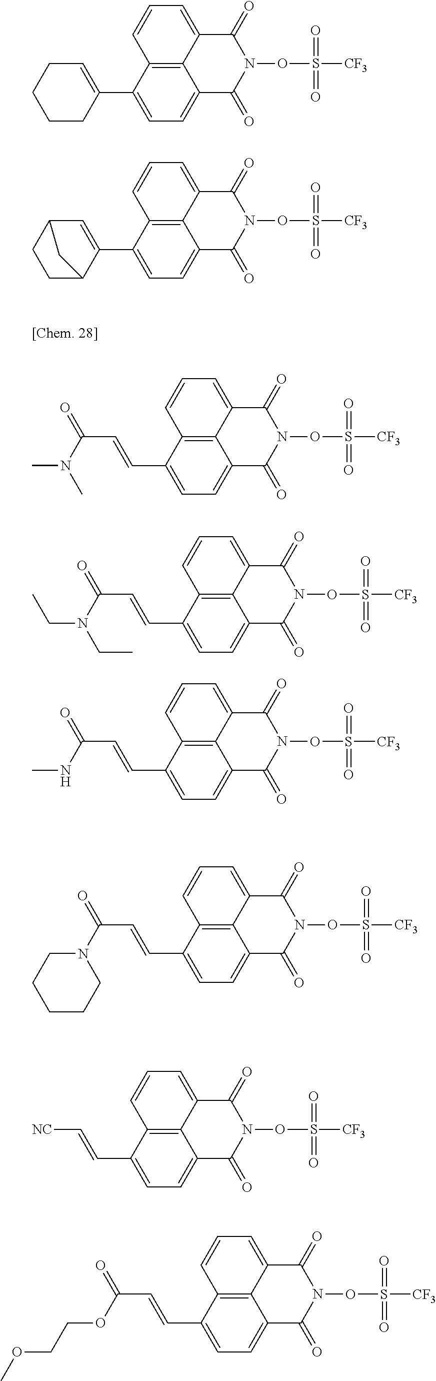

It is preferable in the compounds represented by the formula (a3-i) or (a3-ii) that R^{31a} is a hydrogen atom, R^{32a} is a chain aliphatic group having 1 or more and 18 or less carbon atoms, and R^{33a} is a chain aliphatic group having 1 or more and 18 or less carbon atoms, substituted with one or more fluorine atoms.

The method of manufacturing the compound represented by the formula (a1-i) or (a1-ii), the compound represented by the formula (a2-i) or (a2-ii), and the compound represented by the formula (a3-i) or (a3-ii) is not particularly limited. For example, these compounds can be manufactured by the manufacturing methods described in Patent Documents 3 to 5.

The acid generator (A) may include other acid generator (hereinafter, also referred to as the other acid generator) other than the compound represented by the above formula (a1-i) or (a1-ii), the compound represented by the formula (a2-i) or (a2-ii), and the compound represented by the formula (a3-i) or (a3-ii). The other acid generator is a compound which generates acid upon exposure to an irradiated active ray or radiation, and which generates acid by the light directly or indirectly. As the other acid generator which the acid generator (A) may include, the acid generator of the first to fifth aspect mentioned below is preferable.

The first aspect of the other acid generator in the acid generator (A) may be a compound represented by the following formula (a101).

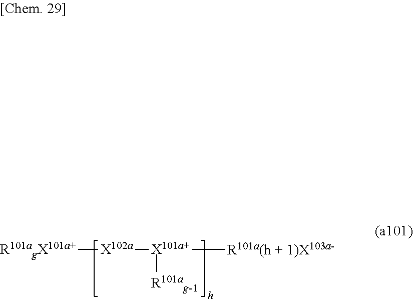

In the formula (a101), X^{101a}s represents a sulfur atom or iodine atom respectively having a valence of g; g represents 1 or 2. h represents the number of repeating units in the structure within parentheses. R^{101a} represents an organic group that is bonded to X^{101a}, and represents an aryl group having 6 or more and 30 or less carbon atoms, a heterocyclic group having 4 or more and 30 or less carbon atoms, an alkyl group having 1 or more and 30 or less carbon atoms, an alkenyl group having 2 or more and 30 or less carbon atoms, or an alkynyl group having 2 or more and 30 or less carbon atoms, and R^{101a} may be substituted with at least one selected from the group consisting of an alkyl group, a hydroxyl group, an alkoxy group, an alkylcarbonyl group, an arylcarbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, an alkyleneoxy group, an amino group, a cyano group, a nitro group, and halogen atoms. The number of R^{101a}s is g+h(g−1)+1, and the R^{101a}s may be respectively identical to or different from each other. Furthermore, two or more R^{101a}s may be bonded to each other directly or via —O—, —S—, —SO—, —SO₂—, —NH—, —NR^{102a}—, —CO—, —COO—, —CONH—, an alkylene group having 1 or more and 3 or less carbon atoms, or a phenylene group, and may form a ring structure including X^{101a}. R^{102a} represents an alkyl group having 1 or more and 5 or less carbon atoms, or an aryl group having 6 or more and 10 or less carbon atoms.

X^{102a} represents a structure represented by the following formula (a102).

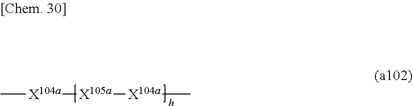

In the above formula (a102), X^{104a} represents an alkylene group having 1 or more and 8 or less carbon atoms, an arylene group having 6 or more and 20 or less carbon atoms, or a divalent group of a heterocyclic compound having 8 or more and 20 or less carbon atoms, and X^{104a} may be substituted with at least one selected from the group consisting of an alkyl group having 1 or more and 8 or less carbon atoms, an alkoxy group having 1 or more and 8 or less carbon atoms, an aryl group having 6 or more and 10 or less carbon atoms, a hydroxyl group, a cyano group, a nitro group, and halogen atoms. X^{105a} represents —O—, —S—, —SO—, —SO₂—, —NH—, —NR^{102a}—, —CO—, —COO—, —CONH—, an alkylene group having 1 or more and 3 or less carbon atoms, or a phenylene group. h represents the number of repeating units of the structure in parentheses. X^{104a}s in the number of h+1 and X^{105a}s in the number of h may be identical to or different from each other. R^{102a} has the same definition as described above.

X^{103a} represents a counter ion of an onium, and examples thereof include a fluorinated alkylfluorophosphoric acid anion represented by the following formula (a117) or a borate anion represented by the following formula (a118).

[Chem. 31]

[(R^{103a})ⱼPF₆₋ⱼ]⁻ (a117)

In the formula (a117), R^{103a} represents an alkyl group having 80% or more of the hydrogen atoms substituted with fluorine atoms. j represents the number of R^{103a}s and is an integer of 1 or more and 5 or less. R^{103a}s in the number of j may be respectively identical to or different from each other.

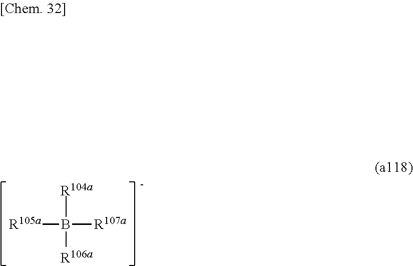

In the formula (a118) R^{104a} to R^{107a} each independently represents a fluorine atom or a phenyl group, and a part or all of the hydrogen atoms of the phenyl group may be substituted with at least one selected from the group consisting of a fluorine atom and a trifluoromethyl group.

Examples of the onium ion in the compound represented by the above formula (a101) include triphenylsulfonium, tri-p-tolylsulfonium, 4-(phenylthio)phenyldiphenylsulfonium, bis[4-(diphenylsulfonio)phenyl] sulfide, bis[4-{bis[4-(2-hydroxyethoxy)phenyl]sulfonio}phenyl] sulfide, bis{4-[bis(4-fluorophenyl)sulfonio]phenyl} sulfide, 4-(4-benzoyl-2-chlorophenylthio)phenylbis(4-fluorophenyl)sulfonium, 7-isopropyl-9-oxo-10-thia-9,10-dihydroanthracen-2-yldi-p-tolylsulfonium, 7-isopropyl-9-oxo-10-thia-9,10-dihydroanthracen-2-yldiphenylsulfonium, 2-[(diphenyl)sulfonio]thioxanthone, 4-[4-(4-tert-butylbenzoyl)phenylthio]phenyldi-p-tolylsulfonium, 4-(4-benzoylphenylthio)phenyldiphenylsulfonium, diphenylphenacylsulfonium, 4-hydroxyphenylmethylbenzylsulfonium, 2-naphthylmethyl(1-ethoxycarbonyl)ethylsulfonium, 4-hydroxyphenylmethylphenacylsulfonium, phenyl[4-(4-biphenylthio)phenyl]4-biphenylsulfonium, phenyl[4-(4-biphenylthio)phenyl]3-biphenylsulfonium, [4-(4-acetophenylthio)phenyl]diphenylsulfonium, octadecylmethylphenacylsulfonium, diphenyliodonium, di-p-tolyliodonium, bis(4-dodecylphenyl)iodonium, bis(4-methoxyphenyl)iodonium, (4-octyloxyphenyl)phenyliodonium, bis(4-decyloxy)phenyliodonium, 4-(2-hydroxytetradecyloxy)phenylphenyliodonium, 4-isopropylphenyl(p-tolyl)iodonium, 4-isobutylphenyl(p-tolyl)iodonium, or the like.

Among the onium ions in the compound represented by the above formula (a101), a preferred onium ion may be a sulfonium ion represented by the following formula (a119).

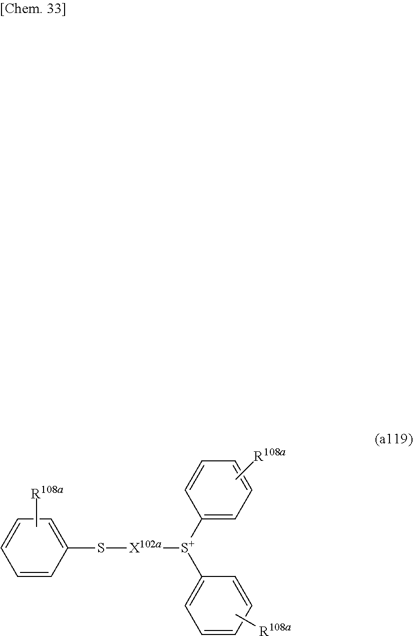

In the above formula (a119), R^{108a}s each independently represents a hydrogen atom or a group selected from the group consisting of alkyl, hydroxyl, alkoxy, alkylcarbonyl, alkylcarbonyloxy, alkyloxycarbonyl, a halogen atom, an aryl which may have a substituent, and arylcarbonyl. X^{102a} has the same definition as X^{102a} in the above formula (a101).

Specific examples of the sulfonium ion represented by the above formula (a119) include 4-(phenylthio)phenyldiphenylsulfonium, 4-(4-benzoyl-2-chlorophenylthio)phenylbis(4-fluorophenyl)sulfonium, 4-(4-benzoylphenylthio)phenyldiphenylsulfonium, phenyl[4-(4-biphenylthio)phenyl]4-biphenylsulfonium, phenyl[4-(4-biphenylthio)phenyl]3-biphenylsulfonium, [4-(4-acetophenylthio)phenyl]diphenylsulfonium, and diphenyl[4-(p-terphenylthio)phenyl]diphenylsulfonium.

In regard to the fluorinated alkylfluorophosphoric acid anion represented by the above formula (a117), R^{103a} represents an alkyl group substituted with a fluorine atom, and a preferred number of carbon atoms is 1 or more and 8 or less, while a more preferred number of carbon atoms is 1 or more and 4 or less. Specific examples of the alkyl group include linear alkyl groups such as methyl, ethyl, propyl, butyl, pentyl and octyl; branched alkyl groups such as isopropyl, isobutyl, sec-butyl and tert-butyl; and cycloalkyl groups such as cyclopropyl, cyclobutyl, cyclopentyl, and cyclohexyl. The proportion of hydrogen atoms substituted with fluorine atoms in the alkyl groups is usually 80% or more, preferably 90% or more, and even more preferably 100%. If the substitution ratio of fluorine atoms is less than 80%, the acid strength of the onium fluorinated alkylfluorophosphate represented by the above formula (a101) decreases.

A particularly preferred example of R^{103a} is a linear or branched perfluoroalkyl group having 1 or more and 4 or less carbon atoms and a substitution ratio of fluorine atoms of 100%. Specific examples thereof include CF₃, CF₃CF₂, (CF₃)₂CF, CF₃CF₂CF₂, CF₃CF₂CF₂CF₂, (CF₃)₂CFCF₂, CF₃CF₂(CF₃)CF, and (CF₃)₃C. j which is the number of R^{103a}s represents an integer of 1 or more and 5 or less, and is preferably 2 or more and 4 or less, and particularly preferably 2 or 3.

Preferred specific examples of the fluorinated alkylfluorophosphoric acid anion include [(CF₃CF₂)₂PF₄]⁻, [(CF₃CF₂)₃PF₃]⁻, [((CF₃)₂CF)₂PF₄]⁻, [((CF₃)₂CF)₃PF₃]⁻, [(CF₃CF₂CF₂)₂PF₄]⁻, [(CF₃CF₂CF₂)₃PF₃]⁻, [((CF₃)₂CFCF₂)₂PF₄]⁻, [((CF₃)₂CFCF₂)₃PF₃]⁻, [(CF₃CF₂CF₂CF₂)₂PF₄]⁻, or [(CF₃CF₂CF₂)₃PF₃]⁻. Among these, [(CF₃CF₂)₃PF₃]⁻, [(CF₃CF₂CF₂)₃PF₃]⁻, [((CF₃)₂CF)₃PF₃]⁻, [((CF₃)₂CF)₂PF₄]⁻, [((CF₃)₂CFCF₂)₃PF₃]⁻, or [((CF₃)₂CFCF₂)₂PF₄]⁻ are particularly preferred.

Preferred specific examples of the borate anion represented by the above formula (a118) include tetrakis(pentafluorophenyl)borate ([B(C₆F₅)₄]⁻), tetrakis[(trifluoromethyl)phenyl]borate ([B(C₆H₄CF₃)₄]⁻), difluorobis(pentafluorophenyl)borate ([(C₆F₅)₂BF₂]⁻), trifluoro(pentafluorophenyl)borate ([(C₆F₅)BF₃]⁻), and tetrakis(difluorophenyl)borate ([B(C₆H₃F₂)₄]⁻). Among these, tetrakis(pentafluorophenyl)borate ([B(C₆F₅)₄]⁻) is particularly preferred.

The second aspect of the other acid generator in the acid generator (A) include halogen-containing triazine compounds such as 2,4-bis(trichloromethyl)-6-piperonyl-1,3,5-triazine, 2,4-bis(trichloromethyl)-6-[2-(2-furyl)ethenyl]-s-triazine, 2,4-bis(trichloromethyl)-6-[2-(5-methyl-2-furyl)ethenyl]-s-triazine, 2,4-bis(trichloromethyl)-6-[2-(5-ethyl-2-furyl)ethenyl]-s-triazine, 2,4-bis(trichloromethyl)-6-[2-(5-propyl-2-furyl)ethenyl]-s-triazine, 2,4-bis(trichloromethyl)-6-[2-(3,5-dimethoxyphenyl)ethenyl]-s-triazine, 2,4-bis(trichloromethyl)-6-[2-(3,5-diethoxyphenyl)ethenyl]-s-triazine, 2,4-bis(trichloromethyl)-6-[2-(3,5-dipropoxyphenyl)ethenyl]-s-triazine, 2,4-bis(trichloromethyl)-6-[2-(3-methoxy-5-ethoxyphenyl)ethenyl]-s-triazine, 2,4-bis(trichloromethyl)-6-[2-(3-methoxy-5-propoxyphenyl)ethenyl]-s-triazine, 2,4-bis(trichloromethyl)-6-[2-(3,4-methylenedioxyphenyl)ethenyl]-s-triazine, 2,4-bis(trichloromethyl)-6-(3,4-methylenedioxyphenyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(2-bromo-4-methoxy)styrylphenyl-s-triazine, 2,4-bis-trichloromethyl-6-(3-bromo-4-methoxy)styrylphenyl-s-triazine, 2-(4-methoxyphenyl)-4,6-bis(trichloromethyl)-1,3,5-triazine, 2-(4-methoxynaphthyl)-4,6-bis(trichloromethyl)-1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethyl)-1,3,5-triazine, 2-[2-(3,5-dimethoxyphenyl)ethenyl]-4,6-bis(trichloromethyl)-1,3,5-triazine, 2-[2-(3,4-dimethoxyphenyl)ethenyl]-4,6-bis(trichloromethyl)-1,3,5-triazine, 2-(3,4-methylenedioxyphenyl)-4,6-bis(trichloromethyl)-1,3,5-triazine, tris(1,3-dibromopropyl)-1,3,5-triazine and tris(2,3-dibromopropyl)-1,3,5-triazine, and halogen-containing triazine compounds represented by the following formula (a103) such as tris(2,3-dibromopropyl)isocyanurate.

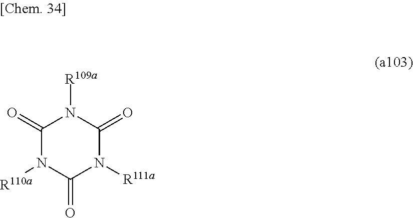

In the above formula (a103), R^{109a}, R^{110a} and R^{111a} each independently represent a halogenated alkyl group.

Further, the third aspect of the other acid generator of the acid generator (A) include α-(p-toluenesulfonyloxyimino)-phenylacetonitrile, α-(benzenesulfonyloxyimino)-2,4-dichlorophenylacetonitrile, α-(benzenesulfonyloxyimino)-2,6-dichlorophenylacetonitrile, α-(2-chlorobenzenesulfonyloxyimino)-4-methoxyphenylacetonitrile and α-(ethylsulfonyloxyimino)-1-cyclopentenylacetonitrile, and compounds represented by the following formula (a104) having an oximesulfonate group.

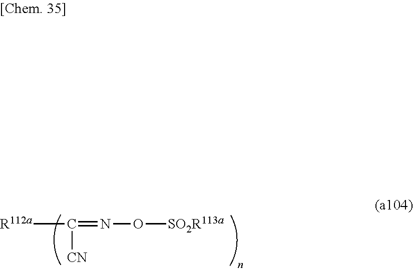

In the above formula (a104), R^{112a} represents a monovalent, bivalent or trivalent organic group, R^{113a} represents a substituted or unsubstituted saturated hydrocarbon group, an unsaturated hydrocarbon group, or an aromatic group, and n represents the number of repeating units of the structure in the parentheses.

In the formula (a104), examples of the aromatic group include aryl groups such as a phenyl group and a naphthyl group, and heteroaryl groups such as a furyl group and a thienyl group. These may have one or more appropriate substituents such as halogen atoms, alkyl groups, alkoxy groups and nitro groups on the rings. It is particularly preferable that R^{113a} is an alkyl group having 1 or more and 6 or less carbon atoms such as a methyl group, an ethyl group, a propyl group, and a butyl group. In particular, compounds in which R^{112a} represents an aromatic group, and R^{113a} represents an alkyl group having 1 or more and 4 or less carbon atoms are preferred.

Examples of the acid generator represented by the above formula (a104) include compounds in which R^{112a} is any one of a phenyl group, a methylphenyl group and a methoxyphenyl group, and R^{113a} is a methyl group, provided that n is 1, and specific examples thereof include α-(methylsulfonyloxyimino)-1-phenylacetonitrile, α-(methylsulfonyloxyimino)-1-(p-methylphenyl)acetonitrile, α-(methylsulfonyloxyimino)-1-(p-methoxyphenyl)acetonitrile, [2-(propylsulfonyloxyimino)-2,3-dihydroxythiophene-3-ylidene](o-tolyl)acetonitrile and the like. Provided that n is 2, the acid generator represented by the above formula (a104) is specifically an acid generator represented by the following formulae.

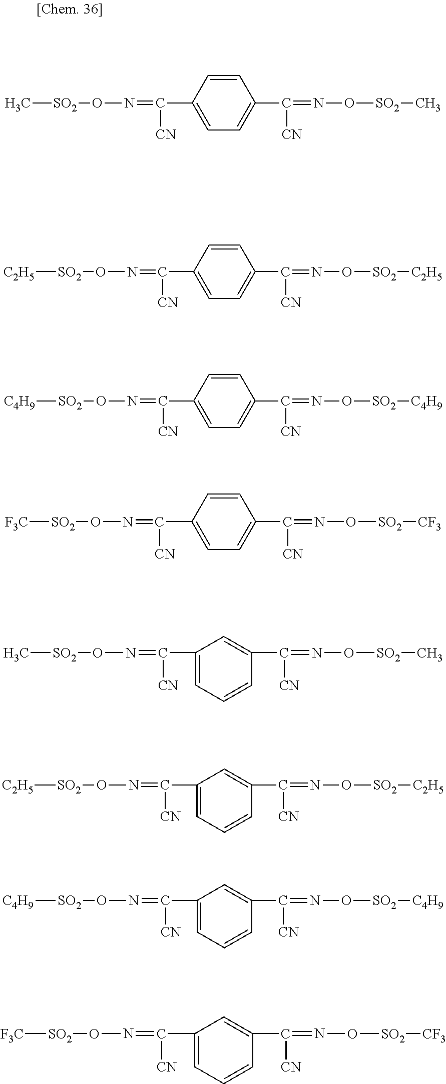

In addition, the other acid generators of the fourth aspect of the acid generator (A) include onium salts that have a naphthalene ring at their cation moiety. The expression “have a naphthalene ring” indicates having a structure derived from naphthalene and also indicates at least two ring structures and their aromatic properties are maintained. The naphthalene ring may have a substituent such as a linear or branched alkyl group having 1 or more and 6 or less carbon atoms, a hydroxyl group, a linear or branched alkoxy group having 1 or more and 6 or less carbon atoms or the like. The structure derived from the naphthalene ring, which may be of a monovalent group (one free valance) or of a bivalent group (two free valences), is desirably of a monovalent group (in this regard, the number of free valence is counted except for the portions connecting with the substituents described above). The number of naphthalene rings is preferably 1 or more and 3 or less.

Preferably, the cation moiety of the onium salt having a naphthalene ring at the cation moiety is of the structure represented by the following formula (a105).

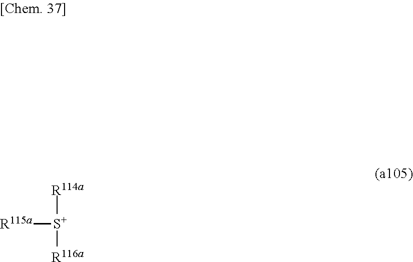

In the above formula (a105), at least one of R^{114a}, R^{115a} and R^{116a} represents a group represented by the following formula (a106), and the remaining represents a linear or branched alkyl group having 1 or more and 6 or less carbon atoms, a phenyl group which may have a substituent, a hydroxyl group, or a linear or branched alkoxy group having 1 or more and 6 or less carbon atoms. Alternatively, one of R^{114a}, R^{115a} and R^{116a} is a group represented by the following formula (a106), and the remaining two are each independently a linear or branched alkylene group having 1 or more and 6 or less carbon atoms, and these terminals may bond to form a ring structure.

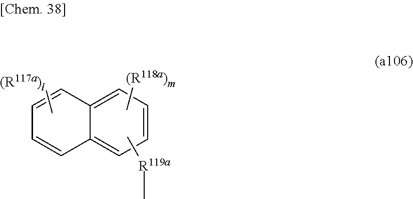

In the formula (a106), R^{117a} and R^{118a} each independently represent a hydroxyl group, a linear or branched alkoxy group having 1 or more and 6 or less carbon atoms, or a linear or branched alkyl group having 1 or more and 6 or less carbon atoms, and R^{119a} represents a single bond or a linear or branched alkylene group having 1 or more and 6 or less carbon atoms that may have a substituent. l and m each independently represent an integer of 0 or more and 2 or less, and l+m is 3 or less. Herein, when there exists a plurality of R^{117a}, they may be identical to or different from each other. Furthermore, when there exists a plurality of R^{118a}, they may be identical to or different from each other.

Preferably, among R^{114a}, R^{115a} and R^{116a} as above, the number of groups represented by the above formula (a106) is one in view of the stability of the compound, and the remaining are linear or branched alkylene groups having 1 or more and 6 or less carbon atoms of which the terminals may bond to form a ring. In this case, the two alkylene groups described above form a 3 to 9 membered ring including sulfur atom(s). Preferably, the number of atoms to form the ring (including sulfur atom(s)) is 5 or more and 6 or less.

Examples of the substituent, which the alkylene group may have, include an oxygen atom (in this case, a carbonyl group is formed together with a carbon atom that constitutes the alkylene group), a hydroxyl group or the like.

Furthermore, examples of the substituent, which the phenyl group may have, include a hydroxyl group, a linear or branched alkoxy group having 1 or more and 6 or less carbon atoms, a linear or branched alkyl group having 1 or more and 6 or less carbon atoms, or the like.

Examples of cations for the suitable cation moiety include cations represented by the following formulae (a107) and (a108), and the structure represented by the following formula (a108) is particularly preferable.

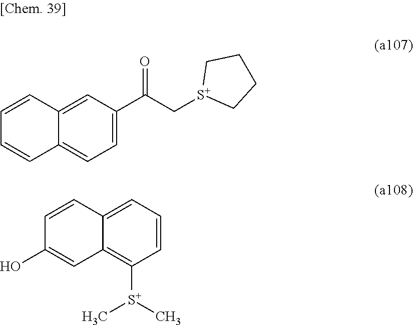 [SMILES: O=C(C[S+]1CCCC1)c1ccc2ccccc2c1 ; C[S+](C)c1cccc2ccc(O)cc12]

The cation moieties, which may be of an iodonium salt or a sulfonium salt, are desirably of a sulfonium salt in view of acid-producing efficiency.

It is, therefore, desirable that the suitable anions for the anion moiety of the onium salt having a naphthalene ring at the cation moiety is an anion capable of forming a sulfonium salt.

The anion moiety of the acid generator is exemplified by fluoroalkylsulfonic acid ions or aryl sulfonic acid ions, of which hydrogen atom(s) being partially or entirely fluorinated.

The alkyl group of the fluoroalkylsulfonic acid ions may be linear, branched or cyclic and have 1 or more and 20 or less carbon atoms. Preferably, the carbon number is 1 or more and 10 or less in view of bulkiness and diffusion distance of the generated acid. In particular, branched or cyclic alkyl groups are preferable due to shorter diffusion length. Also, methyl, ethyl, propyl, butyl, octyl groups and the like are preferable due to being inexpensively synthesizable.

The aryl group of the aryl sulfonic acid ions may be an aryl group having 6 or more and 20 or less carbon atoms, and is exemplified by a phenol group or a naphthyl group that may be unsubstituted or substituted with an alkyl group or a halogen atom. In particular, aryl groups having 6 or more and 10 or less carbon atoms are preferable due to being inexpensively synthesizable. Specific examples of preferable aryl group include phenyl, toluenesulfonyl, ethylphenyl, naphthyl, methylnaphthyl groups and the like.

When hydrogen atoms in the above fluoroalkylsulfonic acid ion or the aryl sulfonic acid ion are partially or entirely substituted with a fluorine atom, the fluorination rate is preferably 10% or more and 100% or less, and more preferably 50% or more and 100% or less; it is particularly preferable that all hydrogen atoms are each substituted with a fluorine atom in view of higher acid strength. Specific examples thereof include trifluoromethane sulfonate, perfluorobutane sulfonate, perfluorooctane sulfonate, perfluorobenzene sulfonate, and the like.

Among these, the preferable anion moiety is exemplified by those represented by the following formula (a109).

[Chem. 40]

R^{120a}SO₃⁻ (a109)

In the above formula (a109), R^{120a} represents groups represented by the following formulae (a110), (a111), and (a112).

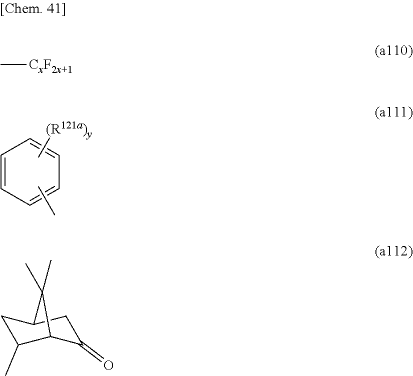

In the above formula (a110), x represents an integer of 1 or more and 4 or less. Also, in the above formula (a111), R^{121a} represents a hydrogen atom, a hydroxyl group, a linear or branched alkyl group having 1 or more and 6 or less carbon atoms, or a linear or branched alkoxy group having 1 or more and 6 or less carbon atoms, and y represents an integer of 1 or more and 3 or less. Of these, trifluoromethane sulfonate, and perfluorobutane sulfonate are preferable in view of safety.

In addition, a nitrogen-containing moiety represented by the following formulae (a113) and (a114) may also be used for the anion moiety.

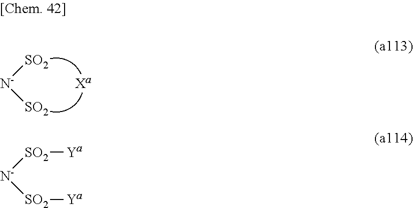

In the formulae (a113) and (a114), X^{a} represents a linear or branched alkylene group in which at least one hydrogen atom is substituted with a fluorine atom, the carbon number of the alkylene group is 2 or more and 6 or less, preferably 3 or more and 5 or less, and most preferably the carbon number is 3. In addition, Y^{a} and Z^{a} each independently represent a linear or branched alkyl group of which at least one hydrogen atom is substituted with a fluorine atom, the number of carbon atoms of the alkyl group is 1 or more and 10 or less, preferably 1 or more and 7 or less, and more preferably 1 or more and 3 or less.

The smaller number of carbon atoms in the alkylene group of X^{a}, or in the alkyl group of Y^{a} or Z^{a} is preferred since the solubility into organic solvent is favorable.

In addition, a larger number of hydrogen atoms each substituted with a fluorine atom in the alkylene group of X^{a}, or in the alkyl group of Y^{a} or Z^{a} is preferred since the acid strength becomes greater. The percentage of fluorine atoms in the alkylene group or alkyl group, i.e., the fluorination rate is preferably 70% or more and 100% or less and more preferably 90% or more and 100% or less, and most preferable are perfluoroalkylene or perfluoroalkyl groups in which all of the hydrogen atoms are each substituted with a fluorine atom.

Examples of preferable compounds for onium salts having a naphthalene ring at their cation moieties include compounds represented by the following formulae (a115) and (a116).

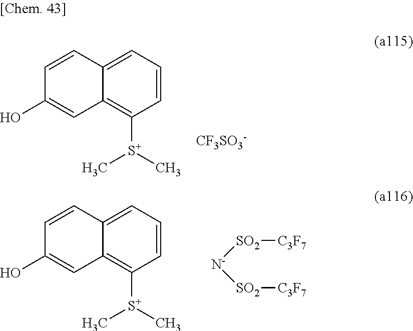

Also, the other acid generators of the fifth aspect of the acid generator (A) include bissulfonyldiazomethanes such as bis(p-toluenesulfonyl)diazomethane, bis(1,1-dimethyl ethylsulfonyl)diazomethane, bis(cyclohexylsulfonyl)diazomethane and bis(2,4-dimethylphenylsulfonyl)diazomethane; nitrobenzyl derivatives such as 2-nitrobenzyl p-toluenesulfonate, 2,6-dinitrobenzyl p-toluenesulfonate, nitrobenzyl tosylate, dinitrobenzyl tosylate, nitrobenzyl sulfonate, nitrobenzyl carbonate and dinitrobenzyl carbonate; sulfonates such as pyrogalloltrimesylate, pyrogalloltritosylate, benzyltosylate, benzylsulfonate, N-methylsulfonyloxysuccinimide, N-trichloromethylsulfonyloxysuccinimide, N-phenylsulfonyloxymaleimide and N-methylsulfonyloxyphthalimide; trifluoromethane sulfonates such as N-(trifluoromethylsulfonyloxy)phthalimide, N-(trifluoromethylsulfonyloxy)-1,8-naphthalimide and N-(trifluoromethylsulfonyloxy)-4-butyl-1,8-naphthalimide (excluding the compounds represented by the formula (a1-i) or (a1-ii), the compounds represented by the formula (a2-i) or (a2-ii), and the compounds represented by the formula (a3-i) or (a3-ii)); onium salts such as diphenyliodonium hexafluorophosphate, (4-methoxyphenyl)phenyliodonium trifluoromethanesulfonate, bis(p-tert-butylphenyl)iodonium trifluoromethanesulfonate, triphenylsulfonium hexafluorophosphate, (4-methoxyphenyl)diphenylsulfonium trifluoromethanesulfonate and (p-tert-butylphenyl)diphenylsulfonium trifluoromethanesulfonate; benzointosylates such as benzointosylate and α-methylbenzointosylate; other diphenyliodonium salts, triphenylsulfonium salts, phenyldiazonium salts, benzylcarbonates and the like.

The total content of the acid generator (A) is preferably 0.01% by mass or more and 10% by mass or less, more preferably 0.03% by mass or more and 8% by mass or less, and particularly preferably 0.05% by mass or more and 5% by mass or less with respect to the total solid content of the photosensitive resin composition. Furthermore, the total of the compounds represented by the formula (a1-i) or (a1-ii), the compounds represented by the formula (a2-i) or (a2-ii), and the compounds represented by the formula (a3-i) or (a3-ii) is preferably 0.01% by mass or more and 10% by mass or less, more preferably 0.03% by mass or more and 8% by mass or less, and particularly preferably 0.05% by mass or more and 5% by mass or less with respect to the total solid content of the photosensitive resin composition. When the use amount of the acid generator (A) is within the above range, photosensitive resin composition including a uniform solution having more excellent sensitivity, and having excellent preservation stability can be easily prepared.

### <Resin (B)>

The resin (B) whose solubility in alkali increases under an action of acid is not particularly limited, and any resin whose solubility under an action of acid increases can be used. Examples of the resin whose solubility in alkali increases under an action of acid include various resins such as a novolac resin (B1), a polyhydroxystyrene resin (B2), and an acrylic resin (B3). The resin (B) preferably includes an acrylic resin (B3). A ratio of the acrylic resin contained in the resin (B) with respect to the resin (B), that is, a ratio of the acrylic resin (B3) with respect to the resin (B), is preferably 70% by mass or more.

### [Novolac Resin (B1)]

A novolac resin (B1) is a novolac resin having an acid-dissociable dissolution-inhibiting group. As the novolak resin (B1), a resin including the constituent unit represented by the following formula (b1) may be used.

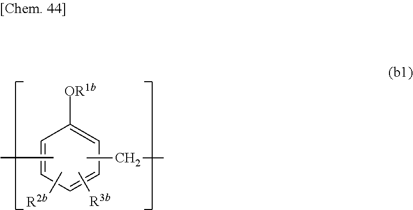

In the formula (b1), R^{1b} represents an acid-dissociable dissolution-inhibiting group, and R^{2b} and R^{3b} each independently represent a hydrogen atom or an alkyl group having 1 or more and 6 or less carbon atoms.

The acid-dissociable dissolution-inhibiting group represented by the above R^{1b} is preferably a group represented by the following formula (b2) or (b3), a linear, branched or cyclic alkyl group having 1 or more and 6 or less carbon atoms, a vinyloxyethyl group, a tetrahydropyranyl group, a tetrahydrofuranyl group, or a trialkylsilyl group.

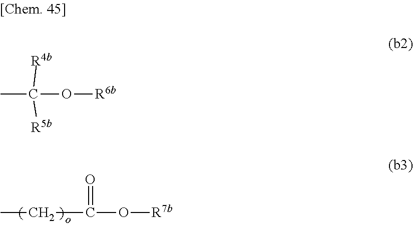

In the above formulae (b2) and (b3), R^{4b} and R^{5b} each independently represent a hydrogen atom, or a linear or branched alkyl group having 1 or more and 6 or less carbon atoms, R^{6b} represents a linear, branched or cyclic alkyl group having 1 or more and 10 or less carbon atoms, R^{7b} represents a linear, branched or cyclic alkyl group having 1 or more and 6 or less carbon atoms, and o represents 0 or 1.

Examples of the above linear or branched alkyl group include a methyl group, an ethyl group, a propyl group, an isopropyl group, an n-butyl group, an isobutyl group, a tert-butyl group, a pentyl group, an isopentyl group, a neopentyl group, and the like. Also, examples of the above cyclic alkyl group include a cyclopentyl group, a cyclohexyl group, and the like.

Specific examples of the acid-dissociable dissolution-inhibiting group represented by the above formula (b2) include a methoxyethyl group, ethoxyethyl group, n-propoxyethyl group, isopropoxyethyl group, n-butoxyethyl group, isobutoxyethyl group, tert-butoxyethyl group, cyclohexyloxyethyl group, methoxypropyl group, ethoxypropyl group, 1-methoxy-1-methylethyl group, 1-ethoxy-1-methylethyl group, and the like. Furthermore, specific examples of the acid-dissociable dissolution-inhibiting group represented by the above formula (b3) include a tert-butoxycarbonyl group, a tert-butoxycarbonylmethyl group, and the like. Examples of the above trialkylsilyl group include a trimethylsilyl group and tri-tert-butyldimethylsilyl group in which each alkyl group has 1 or more and 6 or less carbon atoms.

### [Polyhydroxystyrene Resin (B2)]

The polyhydroxystyrene resin (B2) is a polyhydroxystyrene resin having an acid-dissociable dissolution-inhibiting group. In this specification, the term “polyhydroxystyrene resin” is not particularly limited as long as it is a resin recognized by a person skilled in the art to be a polyhydroxystyrene resin in the technical field relating to a photosensitive resin composition. Typically, the polyhydroxystyrene resin is a resin in which a total of a hydroxystyrene constituent unit which is derived from hydroxystyrene or a hydroxystyrene derivative, and a constituent unit derived from styrene is 70 mol % or more, and a total of the hydroxystyrene constituent unit is 50 mol % or more. The “hydroxystyrene derivative” is a compound in which a hydrogen atom of a hydroxy group of hydroxystyrene or a hydrogen atom bonded to a carbon atom at an α-position of the hydroxystyrene is substituted with a hydrocarbon group which may have an oxygen atom. Examples of the acid-dissociable dissolution-inhibiting group include the same acid dissociable dissolution inhibiting groups as those exemplified for the above formulas (b2) and (b3).

As the polyhydroxystyrene resin (B2), a resin including a constituent unit represented by the following formula (b4) may be used.

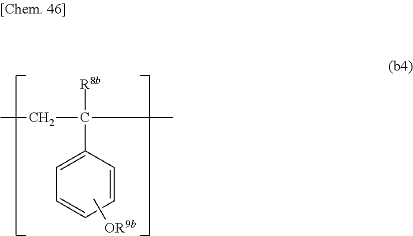

In the above formula (b4), R^{8b} represents a hydrogen atom or an alkyl group having 1 or more and 6 or less carbon atoms, and R^{9b} represents an acid-dissociable dissolution-inhibiting group.

The above alkyl group having 1 or more and 6 or less carbon atoms may include, for example, linear, branched or cyclic alkyl groups having 1 or more and 6 or less carbon atoms. Examples of the linear or branched alkyl group include a methyl group, ethyl group, propyl group, isopropyl group, n-butyl group, isobutyl group, tert-butyl group, pentyl group, isopentyl group, neopentyl group, and the like. Examples of the cyclic alkyl group include a cyclopentyl group and cyclohexyl group.

The acid-dissociable dissolution-inhibiting group represented by the above R^{9b} may be similar to the acid-dissociable dissolution-inhibiting groups exemplified in terms of the above formulae (b2) and (b3).

Furthermore, a resin including a constituent unit represented by the above formula (b4) as the polyhydroxystyrene resin (B2) may include another polymerizable compound as a constituent unit in order to moderately control physical or chemical properties. The polymerizable compound is exemplified by conventional radical polymerizable compounds and anion polymerizable compounds. Examples of the polymerizable compound include monocarboxylic acids such as acrylic acid, methacrylic acid and crotonic acid; dicarboxylic acids such as maleic acid, fumaric acid and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid and 2-methacryloyloxyethyl hexahydrophthalic acid; (meth)acrylic acid alkyl esters such as methyl (meth)acrylate, ethyl (meth)acrylate and butyl (meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide. Note that, in a case in which the polyhydroxystyrene resin (B2) includes a different polymerizable compound other than the constituent unit represented by the above formula (b4) as the constituent unit, the constituent unit derived from the different polymerizable compound may have the acid-dissociable dissolution-inhibiting group.

### [Acrylic Resin (B3)]

An acrylic resin (B3) is an acrylic resin having an acid-dissociable dissolution-inhibiting group. An acrylic resin (B3) is not particularly limited as long as it is an acrylic resin the solubility of which in alkali increases under the action of acid, and has conventionally blended in various photosensitive resin compositions.

In this specification, the “acrylic resin” is a resin containing an acrylic constituent unit which is a constituent unit derived from (meth)acrylic acid or a (meth)acrylic acid derivative, in a content of 70 mol %. In addition, in this specification, the “(meth)acrylic acid derivative” is a (meth)acrylate ester, an optionally N-substituted (meth)acrylamide, or a (meth)acrylnitrile. In this specification, “(meth)acrylic” means both “acryl” and “methacryl”. “(Meth)acrylate” refers to both “acrylate” and “methacrylate”. The “acrylic resin” may contain a constituent unit derived from a monomer other than (meth)acrylic acid or (meth)acrylic acid derivatives in a content of 30 mol % or less.

Preferably, the acrylic resin (B3) contains a constituent unit (b-3) derived from, for example, an acrylic ester including an —SO₂-containing cyclic group or a lactone-containing cyclic group. In such a case, when a resist pattern is formed, a resist pattern having a preferable cross-sectional shape can be easily formed.

### (—SO₂-Containing Cyclic Group)

Herein, the “—SO₂-containing cyclic group” refers to a cyclic group having a cyclic group containing a ring including —SO₂— in the ring skeleton thereof, specifically a cyclic group in which the sulfur atom (S) in —SO₂— forms a part of the ring skeleton of the cyclic group. Considering a ring including —SO₂— in the ring skeleton thereof as the first ring, a group having that ring alone is called a monocyclic group, and a group further having another ring structure is called a polycyclic group regardless of its structure. The —SO₂— containing cyclic group may be monocyclic or polycyclic.

In particular, the —SO₂-containing cyclic group is preferably a cyclic group containing —O—SO₂— in the ring skeleton thereof, i.e., a cyclic group containing a sultone ring in which —O—S— in —O—SO₂— forms a part of the ring skeleton.

The number of carbon atoms in an —SO₂-containing cyclic group is preferably 3 or more and 30 or less, more preferably 4 or more and 20 or less, even more preferably 4 or more and 15 or less, and in particular preferably 4 or more and 12 or less. The above number of carbon atoms is the number of carbon atoms constituting a ring skeleton, and shall not include the number of carbon atoms in a substituent.

The —SO₂-containing cyclic group may be an —SO₂-containing aliphatic cyclic group or an —SO₂-containing aromatic cyclic group. It is preferably an —SO₂-containing aliphatic cyclic group.

—SO₂-containing aliphatic cyclic groups include a group in which at least one hydrogen atom is removed from an aliphatic hydrocarbon ring where a part of the carbon atoms constituting the ring skeleton thereof is(are) substituted with —SO₂— or —O—SO₂—. More specifically, they include a group in which at least one hydrogen atom is removed from an aliphatic hydrocarbon ring where —CH₂— constituting the ring skeleton thereof is substituted with —SO₂— and a group in which at least one hydrogen atom is removed from an aliphatic hydrocarbon ring where —CH₂—CH₂— constituting the ring thereof is substituted with —O—SO₂—.

The number of carbon atoms in the above alicyclic hydrocarbon ring is preferably 3 or more and 20 or less, more preferably 3 or more and 12 or less. The above alicyclic hydrocarbon ring may be polycyclic, or may be monocyclic. As the monocyclic alicyclic hydrocarbon group, preferred is a group in which two hydrogen atoms are removed from monocycloalkane having 3 or more and 6 or less carbon atoms. Examples of the above monocycloalkane can include cyclopentane, cyclohexane and the like. As the polycyclic alicyclic hydrocarbon ring, preferred is a group in which two hydrogen atoms are removed from polycycloalkane having 7 or more and 12 or less carbon atoms, and specific examples of the above polycycloalkane include adamantane, norbornane, isobornane, tricyclodecane, tetracyclododecane and the like.

The —SO₂-containing cyclic group may have a substituent. Examples of the above substituent include, for example, an alkyl group, an alkoxy group, a halogen atom, a halogenated alkyl group, a hydroxy group, an oxygen atom (═O), —COOR″, —OC(═O)R″, a hydroxyalkyl group, a cyano group and the like.

For an alkyl group as the above substituent, preferred is an alkyl group having 1 or more and 6 or less carbon atoms. The above alkyl group is preferably linear or branched. Specific examples include a methyl group, an ethyl group, an n-propyl group, an isopropyl group, an n-butyl group, an isobutyl group, a tert-butyl group, an n-pentyl group, an isopentyl group, a neopentyl group, an n-hexyl group and the like. Among these, a methyl group or an ethyl group is preferred, and a methyl group is particularly preferred.

For an alkoxy group as the above substituent, preferred is an alkoxy group having 1 or more and 6 or less carbon atoms. The above alkoxy group is preferably linear or branched. Specific examples include a group in which an alkyl groups recited as an alkyl group for the above substituent is attached to the oxygen atom (—O—).

Halogen atoms as the above substituent include a fluorine atom, a chlorine atom, a bromine atom, an iodine atom and the like, and a fluorine atom is preferred.

Halogenated alkyl groups for the above substituent include a group in which a part or all of the hydrogen atoms in the above alkyl group is(are) substituted with the above halogen atom(s).

Halogenated alkyl groups as the above substituent include a group in which a part or all of the hydrogen atoms in the alkyl groups recited as an alkyl group for the above substituent is(are) substituted with the above halogen atom(s). As the above halogenated alkyl group, a fluorinated alkyl group is preferred, and a perfluoroalkyl group is particularly preferred.

R″s in the aforementioned —COOR″ and —OC(═O)R″ are either a hydrogen atom or a linear, branched or cyclic alkyl group having 1 or more and 15 or less carbon atoms.

In a case where R″ is a linear or branched alkyl group, the number of carbon atoms in the above chain alkyl group is preferably 1 or more and 10 or less, more preferably 1 or more and 5 or less, and in particular preferably 1 or 2.

In a case where R″ is a cyclic alkyl group, the number of carbon atoms in the above cyclic alkyl group is preferably 3 or more and 15 or less, more preferably 4 or more and 12 or less, and in particular preferably 5 or more and 10 or less. Specific examples can include a group in which one or more hydrogen atoms are removed from monocycloalkane, and polycycloalkane such as bicycloalkane, tricycloalkane, tetracycloalkane, and the like, which may be or not may be substituted with a fluorine atom or a fluorinated alkyl group. More specific examples include a group in which one or more hydrogen atoms are removed from monocycloalkane such as cyclopentane and cyclohexane; and polycycloalkane such as adamantane, norbornane, isobornane, tricyclodecane and tetracyclododecane.

For a hydroxyalkyl group as the above substituent, preferred is a hydroxyalkyl group having 1 or more and 6 or less carbon atoms. Specific examples include a group in which at least one of the hydrogen atoms in the alkyl groups recited as an alkyl group for the above substituent is substituted with a hydroxy group.

More specific examples of the —SO₂-containing cyclic group include the groups represented by the following formulae (3-1) to (3-4).

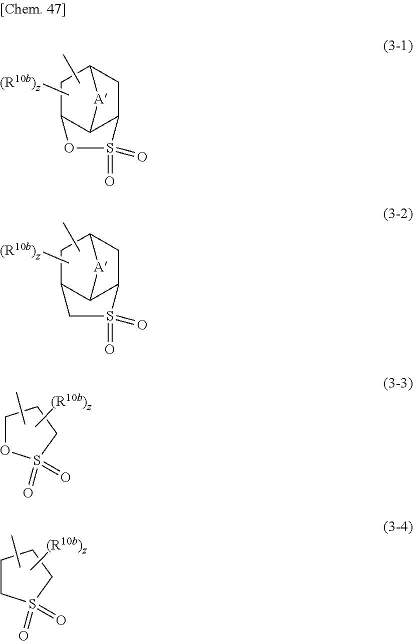

(In the formulae, A′ represents an alkylene group having 1 or more and 5 or less carbon atoms optionally including an oxygen atom or a sulfur atom, an oxygen atom or a sulfur atom; z represents an integer of 0 or more and 2 or less; R^{10b} represents an alkyl group, an alkoxy group, a halogenated alkyl group, a hydroxy group, —COOR″, —OC(═O)R″, a hydroxyalkyl group, or a cyano group; and R″ represents a hydrogen atom or an alkyl group.)

In the above formulae (3-1) to (3-4), A′ represents an alkylene group having 1 or more and 5 or less carbon atoms optionally including an oxygen atom (—O—) or a sulfur atom (—S—), an oxygen atom or a sulfur atom. As an alkylene group having 1 or more and 5 or less carbon atoms in A′, a linear or branched alkylene group is preferred, and examples thereof include a methylene group, an ethylene group, an n-propylene group, an isopropylene group and the like.

In a case where the above alkylene group includes an oxygen atom or a sulfur atom, specific examples thereof include a group in which —O— or —S— is present at a terminal or between carbon atoms of the above alkylene group, for example, —O—CH₂—, —CH₂—O—CH₂—, —S—CH₂—, —CH₂—S—CH₂—, and the like. As A′, an alkylene group having 1 or more and 5 or less carbon atoms or —O— is preferred, and an alkylene group having 1 or more and 5 or less carbon atoms is more preferred, and a methylene group is most preferred.

z may be any of 0, 1, and 2, and is most preferably 0. In a case where z is 2, a plurality of R^{10b} may be the same, or may differ from each other.

An alkyl group, an alkoxy group, a halogenated alkyl group, —COOR″, —OC(═O)R″ and a hydroxyalkyl group in R^{10b} include those similar to the groups described above for the alkyl group, the alkoxy group, the halogenated alkyl group, —COOR″, —OC(═O)R″ and the hydroxyalkyl group, respectively, which are recited as those optionally contained in the —SO₂-containing cyclic group.

Below, specific cyclic groups represented by the above formulae (3-1) to (3-4) will be illustrated. Note here that “Ac” in the formulae represents an acetyl group.

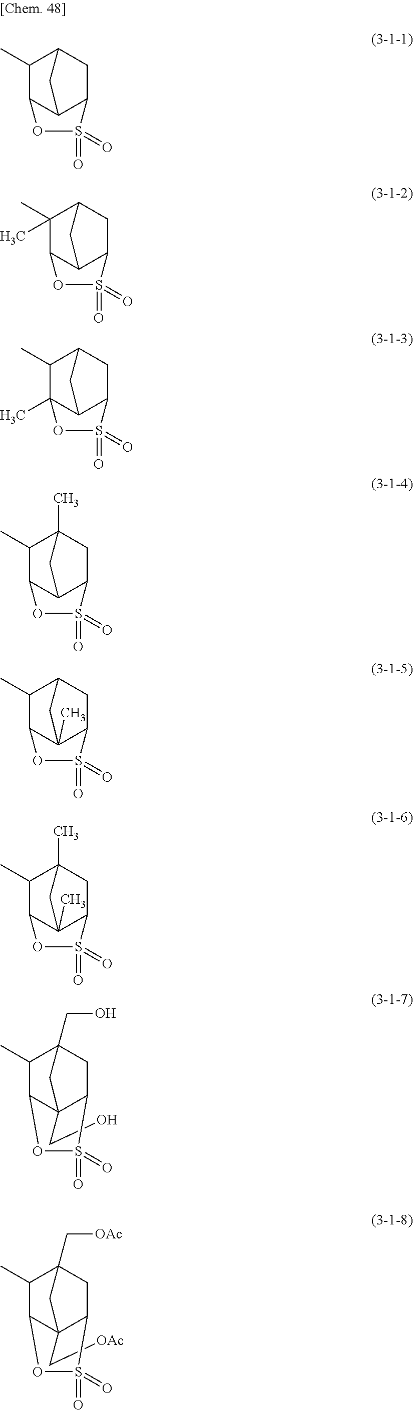

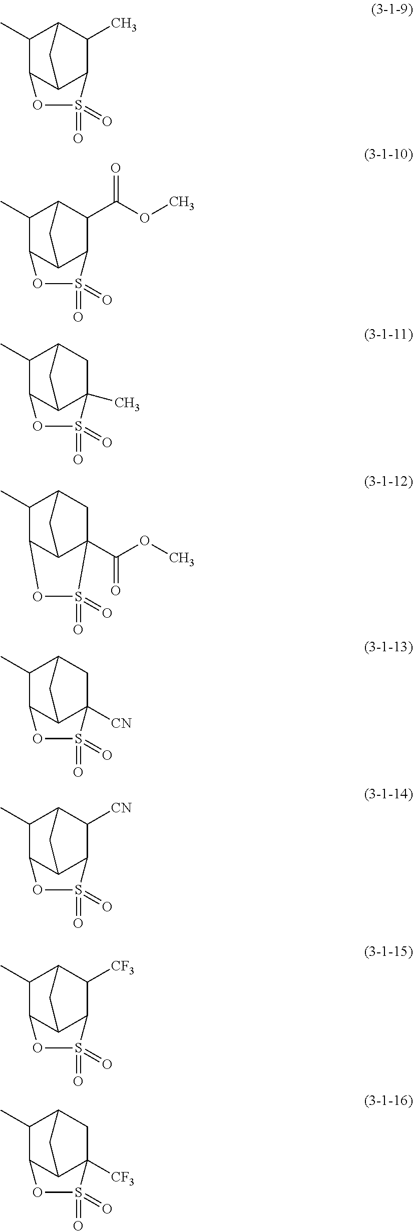

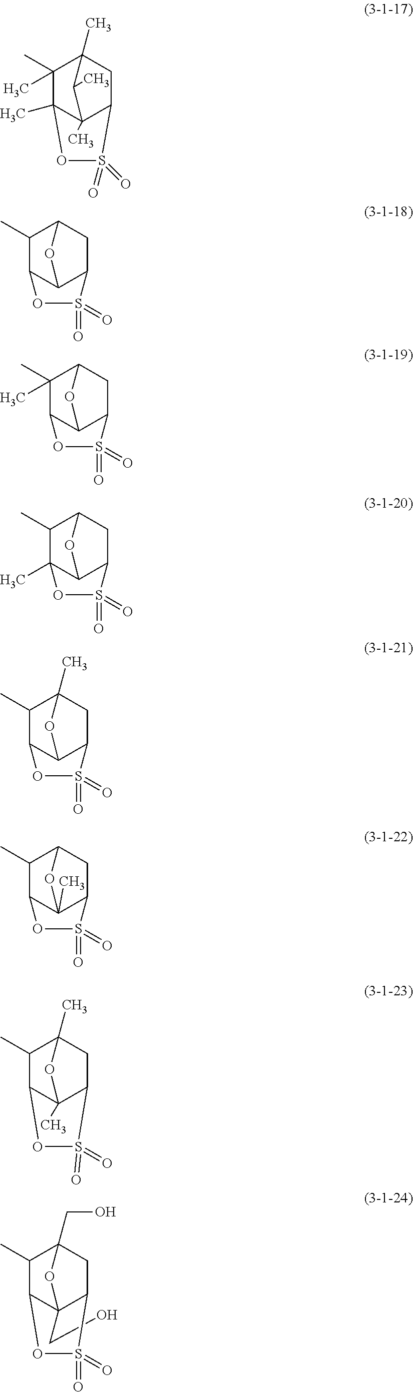

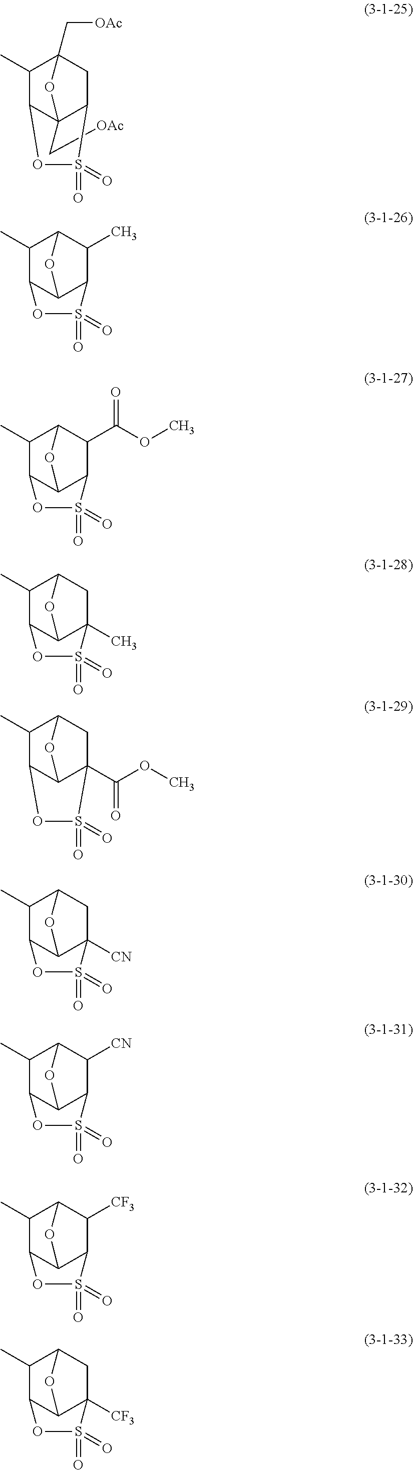

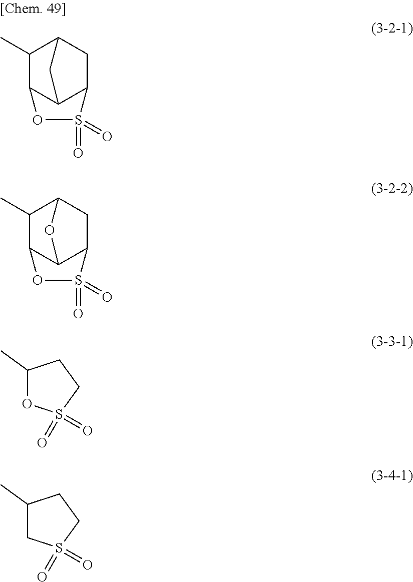

As the —SO₂-containing cyclic group, among those shown above, a group represented by the above formula (3-1) is preferred, and at least one selected from the group consisting of the groups represented by any of the aforementioned formulae (3-1-1), (3-1-18), (3-3-1) and (3-4-1) is more preferred, and a group represented by the aforementioned formula (3-1-1) is most preferred.

### (Lactone-Containing Cyclic Group)

The “lactone-containing cyclic group” refers to a cyclic group containing a ring (lactone ring) including —O—C(═O)— in the ring skeleton thereof. Considering the lactone ring as the first ring, a group having that lactone ring alone is called a monocyclic group, and a group further having another ring structure is called a polycyclic group regardless of its structure. The lactone-containing cyclic group may be a monocyclic group, or may be a polycyclic group.

There is no particular limitation on the lactone cyclic group in the constituent unit (b-3), and any cyclic group containing lactone can be used. Specifically, examples of the lactone-containing monocyclic groups include a group in which one hydrogen atom is removed from 4 to 6 membered ring lactone, for example, a group in which one hydrogen atom is removed from β-propiono lactone, a group in which one hydrogen atom is removed from γ-butyrolactone, a group in which one hydrogen atom is removed from δ-valerolactone and the like. Further, lactone-containing polycyclic groups include a group in which one hydrogen atom is removed from bicycloalkane, tricycloalkane and tetracycloalkane having a lactone ring.

As to the constituent unit (b-3), as long as the constituent unit (b-3) has an —SO₂-containing cyclic group or a lactone-containing cyclic group, the structures of other parts are not particularly limited. A preferred constituent unit (b-3) is at least one constituent unit selected from the group consisting of a constituent unit (b-3-S) derived from an acrylic acid ester including an —SO₂-containing cyclic group in which a hydrogen atom attached to the carbon atom in the α position may be substituted with a substituent; and a constituent unit (b-3-L) derived from an acrylic acid ester including a lactone-containing cyclic group in which the hydrogen atom attached to the carbon atom in the α position may be substituted with a substituent.

[Constituent Unit (b-3-S)]

More specifically, examples of the constituent unit (b-3-S) include one represented by the following formula (b-S1).

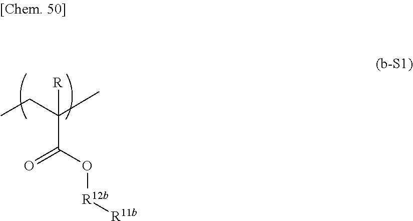

(In the formula, R represents a hydrogen atom, an alkyl group having 1 or more 5 or less carbon atoms or a halogenated alkyl group having 1 or more 5 or less carbon atoms; and R^{11b} represents an —SO₂-containing cyclic group; and R^{12b} represents a single-bond or divalent linking group.)

In the formula (b-S1), R is similarly defined as above. R^{11b} is similarly defined as in the —SO₂-containing cyclic group described above. R^{12b} may be either a single-bond linking group or a divalent linking group.

There is no particular limitation on the divalent linking group in R^{12b}, and suitable examples include an optionally substituted divalent hydrocarbon group, a divalent linking group including a heteroatom, and the like.

### Optionally Substituted Divalent Hydrocarbon Group

The hydrocarbon group as a divalent linking group may be an aliphatic hydrocarbon group, or may be an aromatic hydrocarbon group. The aliphatic hydrocarbon group means a hydrocarbon group without aromaticity. The above aliphatic hydrocarbon group may be saturated or may be unsaturated. Usually, a saturated hydrocarbon group is preferred. More specifically, examples of the above aliphatic hydrocarbon group include a linear or branched aliphatic hydrocarbon group, an aliphatic hydrocarbon group including a ring in the structure thereof and the like.

The number of carbon atoms in the linear or branched aliphatic hydrocarbon group is preferably 1 or more and 10 or less, more preferably 1 or more and 8 or less, and even more preferably 1 or more and 5 or less.

As the linear aliphatic hydrocarbon group, a linear alkylene group is preferred. Specific examples include a methylene group [—CH₂—], an ethylene group [—(CH₂)₂—], a trimethylene group [—(CH₂)₃—], a tetramethylene group [—(CH₂)₄—], a pentamethylene group [—(CH₂)₅-] and the like.

As the branched aliphatic hydrocarbon group, a branched alkylene group is preferred. Specific examples include alkyl alkylene groups such as alkyl methylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; alkyl ethylene groups such as —CH(CH₃)CH₂—, —CH(CH₃)CH(CH₃)—, —C(CH₃)₂CH₂—, —CH(CH₂CH₃)CH₂— and —C(CH₂CH₃)₂—CH₂—; alkyl trimethylene groups such as —CH(CH₃)CH₂CH₂— and —CH₂CH(CH₃)CH₂—; alkyl tetramethylene groups such as —CH(CH₃)CH₂CH₂CH₂— and —CH₂CH(CH₃)CH₂CH₂—; and the like. As an alkyl group in the alkyl alkylene group, a linear alkyl group having 1 or more and 5 or less carbon atoms is preferred.

The above linear or branched aliphatic hydrocarbon group may or may not have a substituent (a group or atom other than a hydrogen atom) which substitutes a hydrogen atom. Examples of the substituent include a fluorine atom, a fluorinated alkyl group having 1 or more and 5 or less carbon atoms substituted with a fluorine atom, an oxo group (═O) and the like.

Examples of the above aliphatic hydrocarbon group including a ring in the structure thereof include a cyclic aliphatic hydrocarbon group optionally including a hetero atom in the ring structure (a group in which two hydrogen atoms are removed from an aliphatic hydrocarbon ring); a group in which the above cyclic aliphatic hydrocarbon group is attached to an end of a linear or branched aliphatic hydrocarbon group; a group in which the above cyclic aliphatic hydrocarbon group is present in a linear or branched aliphatic hydrocarbon group along the chain; and the like. Examples of the above linear or branched aliphatic hydrocarbon group include groups similar to the above.

The number of carbon atoms in the cyclic aliphatic hydrocarbon group is preferably 3 or more and 20 or less, and more preferably 3 or more and 12 or less.

The cyclic aliphatic hydrocarbon group may be polycyclic, or may be monocyclic. As the monocyclic aliphatic hydrocarbon group, a group in which two hydrogen atoms are removed from monocycloalkane is preferred. The number of carbon atoms in the above monocycloalkane is preferably 3 or more and 6 or less. Specific examples include cyclopentane, cyclohexane and the like. As the polycyclic aliphatic hydrocarbon group, a group in which two hydrogen atoms are removed from polycycloalkane is preferred. The number of carbon atoms in the above polycycloalkane is preferably 7 or more and 12 or less. Specific examples include adamantane, norbornane, isobornane, tricyclodecane, tetracyclododecane and the like.

The cyclic aliphatic hydrocarbon group may or may not have a substituent which substitutes a hydrogen atom (a group or atom other than a hydrogen atom). Examples of the above substituent include an alkyl group, an alkoxy group, a halogen atom, a halogenated alkyl group, a hydroxy group, an oxo group (═O) and the like.

For an alkyl group as the above substituent, an alkyl group having 1 or more and 5 or less carbon atoms is preferred, and a methyl group, an ethyl group, a propyl group, an n-butyl group and a tert-butyl group are more preferred.

For an alkoxy group as the above substituent, an alkoxy group having 1 or more and 5 or less carbon atoms is preferred, and a methoxy group, an ethoxy group, an n-propoxy group, an iso-propoxy group, an n-butoxy group and a tert-butoxy group are more preferred, and a methoxy group and an ethoxy group are particularly preferred.

Halogen atoms as the above substituent include a fluorine atom, a chlorine atom, a bromine atom, an iodine atom and the like, and a fluorine atom is preferred.

Halogenated alkyl groups as the above substituent include a group in which a part or all of hydrogen atoms in the aforementioned alkyl group is(are) substituted with the above halogen atom(s).

In the cyclic aliphatic hydrocarbon group, a part of carbon atoms constituting the ring structure thereof may be substituted with —O—, or —S—. As the substituent including the above hetero atom, preferred are —O—, —C(═O)—O—, —S—, —S(═O)₂— and —S(═O)₂—O—.

The aromatic hydrocarbon group as the divalent hydrocarbon group is a divalent hydrocarbon group having at least one aromatic ring, and may have a substituent. There is no particular limitation on the aromatic ring as long as it is a cyclic conjugated system having a 4n+2 n electrons, and it may be monocyclic or may be polycyclic. The number of carbon atoms in the aromatic ring is preferably 5 or more and 30 or less, more preferably 5 or more and 20 or less, further more preferably 6 or more and 15 or less, and particularly preferably 6 or more and 12 or less. However, the number of carbon atoms in a substituent shall not be included in the above number of carbon atoms.

Specifically, aromatic rings include aromatic hydrocarbon rings such as benzene, naphthalene, anthracene and phenanthrene; aromatic heterocycles in which a part of the carbon atoms constituting the above aromatic hydrocarbon ring is(are) substituted with hetero atom(s). Hetero atoms in the aromatic heterocycle include an oxygen atom, a sulfur atom, a nitrogen atom and the like. Specifically, aromatic heterocycles include a pyridine ring, a thiophene ring, and the like.

Specific examples of the aromatic hydrocarbon group as a divalent hydrocarbon group include a group in which two hydrogen atoms are removed from the above aromatic hydrocarbon ring or the above aromatic heterocycle (an arylene group or a heteroarylene group); a group in which two hydrogen atoms are removed from an aromatic compound including two or more aromatic rings (for example, biphenyl, fluorene and the like); a group in which one hydrogen atom from a group where one hydrogen atom is removed from the above aromatic hydrocarbon ring or the above aromatic heterocycle (an aryl group or a heteroaryl group) is substituted with an alkylene group (for example, a group in which one hydrogen atom is further removed from an aryl group in an arylalkyl group such as a benzyl group, a phenethyl group, a 1-naphthylmethyl group, a 2-naphthylmethyl group, a 1-naphthylethyl group and a 2-naphthylethyl group); and the like.

The number of carbon atoms in the above alkylene group bonded to an aryl group or a heteroaryl group is preferably 1 or more and 4 or less, more preferably 1 or more and 2 or less, and particularly preferably 1.

In the above aromatic hydrocarbon group, a hydrogen atom of the above aromatic hydrocarbon group may be substituted with a substituent. For example, a hydrogen atom attached to an aromatic ring in the above aromatic hydrocarbon group may be substituted with a substituent. Examples of the substituent include an alkyl group, an alkoxy group, a halogen atom, a halogenated alkyl group, a hydroxy group, an oxo group (═O) and the like.

For an alkyl group as the above substituent, an alkyl group having 1 or more and 5 or less carbon atoms is preferred, and a methyl group, an ethyl group, an n-propyl group, an n-butyl group and a tert-butyl group are more preferred.

For an alkoxy group as the above substituent, an alkoxy group having 1 or more and 5 or less carbon atoms is preferred, and a methoxy group, an ethoxy group, an n-propoxy group, an iso-propoxy group, an n-butoxy group and a tert-butoxy group are preferred, and a methoxy group and an ethoxy group are more preferred.

Halogen atoms as the above substituent include a fluorine atom, a chlorine atom, a bromine atom, an iodine atom and the like, and a fluorine atom is preferred.

Halogenated alkyl groups as the above substituent include a group in which a part or all of hydrogen atoms in the aforementioned alkyl group is(are) substituted with the above halogen atom(s).

### Divalent Linking Group Including Hetero Atom

A hetero atom in the divalent linking group including a hetero atom is an atom other than a carbon atom and a hydrogen atom, and examples thereof include an oxygen atom, a nitrogen atom, a sulfur atom, a halogen atom and the like.

Specific examples of the divalent linking group including a hetero atom include non-hydrocarbon based linking groups such as —O—, —C(═O)—, —C(═O)—O—, —O—C(═O)—O—, —S—, —S(═O)₂—, —S(═O)₂—O—, —NH—, —NH—C(═O)—, —NH—C(═NH)—, ═N—, and combinations of at least one of these non-hydrocarbon based linking groups and a divalent hydrocarbon group and the like. Examples of the above divalent hydrocarbon group include those similar to the aforementioned divalent hydrocarbon groups optionally having a substituent, and linear or branched aliphatic hydrocarbon groups are preferred.

Among those described above, H in —NH— in —C(═O)—NH—, —NH— and —NH—C(═NH)— may be substituted with a substituent such as an alkyl group or an acyl group, respectively. The number of carbon atoms in the above substituent is preferably 1 or more and 10 or less, more preferably 1 or more and 8 or less, and in particular preferably 1 or more and 5 or less.

As a divalent linking group in R^{12b}, a linear or branched alkylene group, a cyclic aliphatic hydrocarbon group, or a divalent linking group including a hetero atom is preferred.

In a case where the divalent linking group in R^{12b} is a linear or branched alkylene group, the number of carbon atoms in the above alkylene group is preferably 1 or more and 10 or less, more preferably 1 or more and 6 or less, in particular preferably 1 or more and 4 or less, and most preferably 1 or more and 3 or less. Specific examples include groups similar to the linear alkylene groups or branched alkylene groups recited as a linear and branched aliphatic hydrocarbon group in the description of the “divalent hydrocarbon group optionally having a substituent” as the aforementioned divalent linking group.

In a case where the divalent linking group in R^{12b} is a cyclic aliphatic hydrocarbon group, examples of the above cyclic aliphatic hydrocarbon group include groups similar to the cyclic aliphatic hydrocarbon groups recited as the “aliphatic hydrocarbon group including a ring in the structure” in the description of the “divalent hydrocarbon group optionally having a substituent” as the aforementioned divalent linking group.

As the above cyclic aliphatic hydrocarbon group, particularly preferred is a group in which two or more hydrogen atoms are removed from cyclopentane, cyclohexane, norbornane, isobornane, adamantane, tricyclodecane or tetracyclododecane.

In a case where the divalent linking group in R^{12b} is a divalent linking group including a hetero atom, groups preferred as the above linking groups include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O— and a group represented by the general formula —Y^{1b}—O—Y^{2b}—, —[Y^{1b}—C(═O)—O]_{m′}—Y^{2b}— or —Y^{1b}—O—C(═O)—Y^{2b}— [wherein in the formula, Y^{1b} and Y^{2b} are divalent hydrocarbon groups each independently, optionally having a substituent, and O represents an oxygen atom, and m′ is an integer of 0 or more and 3 or less], or the like.

In a case where the divalent linking group in R^{12b} is —NH—, the hydrogen atom in —NH— may be substituted with a substituent such as an alkyl group or an acyl group. The number of carbon atoms in the above substituent (an alkyl group, an acyl group and the like) is preferably 1 or more and 10 or less, more preferably 1 or more and 8 or less, and in particular preferably 1 or more and 5 or less.

Y^{1b} and Y^{2b} in the formula —Y^{1b}—O—Y^{2b}—, —[Y^{1b}—C(═O)—O]_{m′}—Y^{2b}— or —Y^{1b}—O—C(═O)—Y^{2b}— are divalent hydrocarbon groups each independently, optionally having a substituent. Examples of the above divalent hydrocarbon group include groups similar to the “divalent hydrocarbon group optionally having a substituent” recited in the description of the above divalent linking group.

As Y^{1b}, a linear aliphatic hydrocarbon group is preferred, and a linear alkylene group is more preferred, and a linear alkylene group having 1 or more and 5 or less carbon atoms is more preferred, and a methylene group and an ethylene group are particularly preferred.

As Y^{2b}, a linear or branched aliphatic hydrocarbon group is preferred, and a methylene group, an ethylene group and an alkylmethylene group are more preferred. The alkyl group in the above alkylmethylene group is preferably a linear alkyl group having 1 or more and 5 or less carbon atoms, more preferably a linear alkyl group having 1 or more and 3 or less carbon atoms, and particularly preferably a methyl group.

In a group represented by the formula —[Y^{1b}—C(═O)—O]_{m′}—Y^{2b}—, m′ is an integer of 0 or more and 3 or less, preferably an integer of 0 or more and 2 or less, more preferably 0 or 1, and particularly preferably 1. In other words, as a group represented by the formula —[Y^{1b}—C(═O)—O]_{m′}—Y^{2b}—, a group represented by the formula —Y^{1b}—C(═O)—O—Y^{2b}— is particularly preferred. Among these, a group represented by the formula —(CH₂)_{a′}—C(═O)—O—(CH₂)_{b′}— is preferred. In the above formula, a′ is an integer of 1 or more and 10 or less, preferably an integer of 1 or more and 8 or less, more preferably an integer of 1 or more and 5 or less, even more preferably 1 or 2, and most preferably 1. b′ is an integer of 1 or more and 10 or less, preferably an integer of 1 or more and 8 or less, more preferably an integer of 1 or more and 5 or less, even more preferably 1 or 2, and most preferably 1.

With regard to the divalent linking group in R^{12b}, an organic group including a combination of at least one non-hydrocarbon group and a divalent hydrocarbon group is preferred as the divalent linking group including a hetero atom. Among these, a linear chain group having an oxygen atom as a hetero atom, for example, a group including an ether bond or an ester bond is preferred, and a group represented by the aforementioned formula —Y^{1b}—O—Y^{2b}—, —[Y^{1b}—C(═O)—O]_{m′}—Y^{2b}— or —Y^{1b}—O—C(═O)—Y^{2b}— is more preferred, and a group represented by the aforementioned formula —[Y^{1b}—C(═O)—O]_{m′}—Y^{2b}— or —Y^{1b}—O—C(═O)—Y^{2b}— is particularly preferred.

As the divalent linking group in R^{12b}, a group including an alkylene group or an ester bond (—C(═O)—O—) is preferred.

The above alkylene group is preferably a linear or branched alkylene group. Suitable examples of the above linear aliphatic hydrocarbon group include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—] and the like. Suitable examples of the above branched alkylene group include alkyl alkylene groups such as alkyl methylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; alkyl ethylene groups such as —CH(CH₃)CH₂—, —CH(CH₃)CH(CH₃)—, —C(CH₃)₂CH₂—, —CH(CH₂CH₃)CH₂— and —C(CH₂CH₃)₂—CH₂—; alkyl trimethylene groups such as —CH(CH₃)CH₂CH₂— and —CH₂CH(CH₃)CH₂—; alkyl tetramethylene groups such as —CH(CH₃)CH₂CH₂CH₂— and —CH₂CH(CH₃)CH₂CH₂—.

As the divalent linking group including an ester bond, particularly preferred is a group represented by the formula: —R^{13b}—C(═O)—O— [wherein R^{13b} represents a divalent linking group.]. In other words, the constituent unit (b-3-S) is preferably a constituent unit represented by the following formula (b-S1-1).

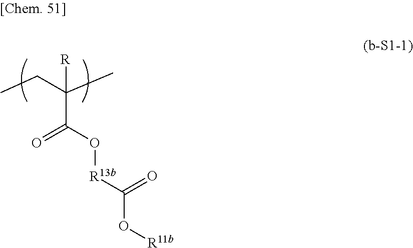

(In the formula, R and R^{11b} are each similar to the above, and R^{13b} represents a divalent linking group.)

There is no particular limitation for R^{13b}, examples thereof include those similar to the aforementioned divalent linking group in R^{12b}. As the divalent linking group in R^{13b}, a linear or branched alkylene group, an aliphatic hydrocarbon group including a ring in the structure, or a divalent linking group including a hetero atom is preferred, and a linear or branched alkylene group or a divalent linking group including an oxygen atom as a hetero atom is preferred.

As the linear alkylene group, a methylene group or an ethylene group is preferred, and a methylene group is particularly preferred. As the branched alkylene group, an alkylmethylene group or an alkylethylene group is preferred, and —CH(CH₃)—, —C(CH₃)₂— or —C(CH₃)₂CH₂— is particularly preferred.

As the divalent linking group including an oxygen atom, a divalent linking group including an ether bond or an ester bond is preferred, and the aforementioned —Y^{1b}—O—Y^{2b}—, —[Y^{1b}—C(═O)—O]_{m′}—Y^{2b}— or —Y^{1b}—O—C(═O)—Y^{2b}— is more preferred. Y^{1b} and Y^{2b} are each independently divalent hydrocarbon groups optionally having a substituent, and m′ is an integer of 0 or more and 3 or less. Among these, —Y^{1b}—O—C(═O)—Y^{2b}— is preferred, and a group represented by —(CH₂)_{c}—O—C(═O)—(CH₂)_{d}— is particularly preferred. c is an integer of 1 or more and 5 or less, and 1 or 2 is preferred. d is an integer of 1 or more and 5 or less, and 1 or 2 is preferred.

As the constituent unit (b-3-S), in particular, one represented by the following formula (b-S1-11) or (b-S1-12) is preferred, and one represented by the formula (b-S1-12) is more preferred.

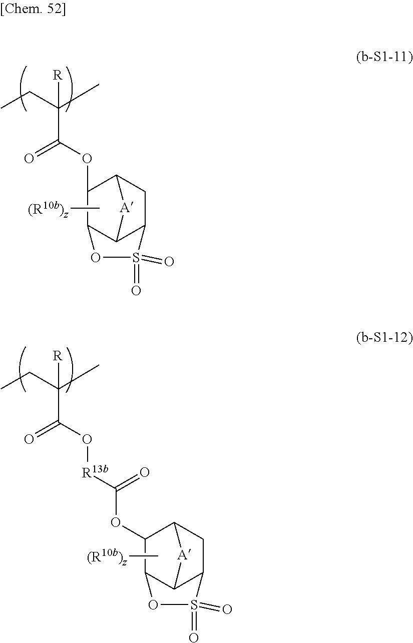

(In the formulae, R, A′, R^{10b}, z and R^{13b} are each the same as the above.)

In the formula (b-S1-11), A′ is preferably a methylene group, an oxygen atom (—O—) or a sulfur atom (—S—).

As R^{13b}, preferred is a linear or branched alkylene group or a divalent linking group including an oxygen atom. Examples of the linear or branched alkylene group and the divalent linking group including an oxygen atom in R^{13b} include those similar to the aforementioned linear or branched alkylene group and the aforementioned divalent linking group including an oxygen atom, respectively.

As the constituent unit represented by the formula (b-S1-12), particularly preferred is one represented by the following formula (b-S1-12a) or (b-S1-12b).

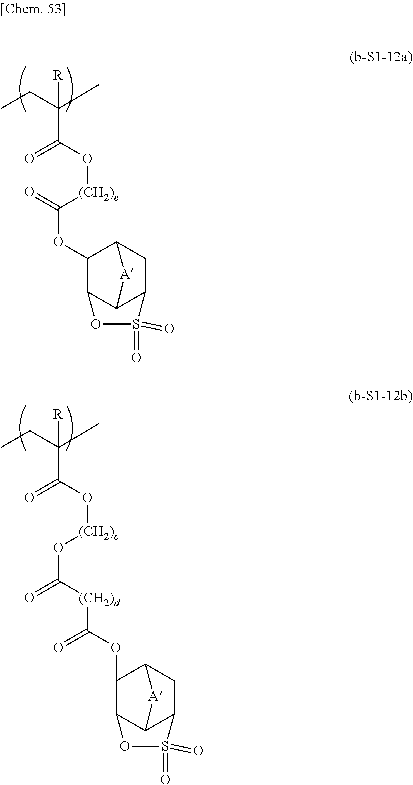

(In the formulae, R and A′ are each the same as the above, and c to e are each independently an integer of 1 or more and 3 or less.)
[Constituent Unit (b-3-L)]

Examples of the constituent unit (b-3-L) include, for example, a constituent unit in which R^{11b} in the aforementioned formula (b-S1) is substituted with a lactone-containing cyclic group. More specifically they include those represented by the following formulae (b-L1) to (b-L5).

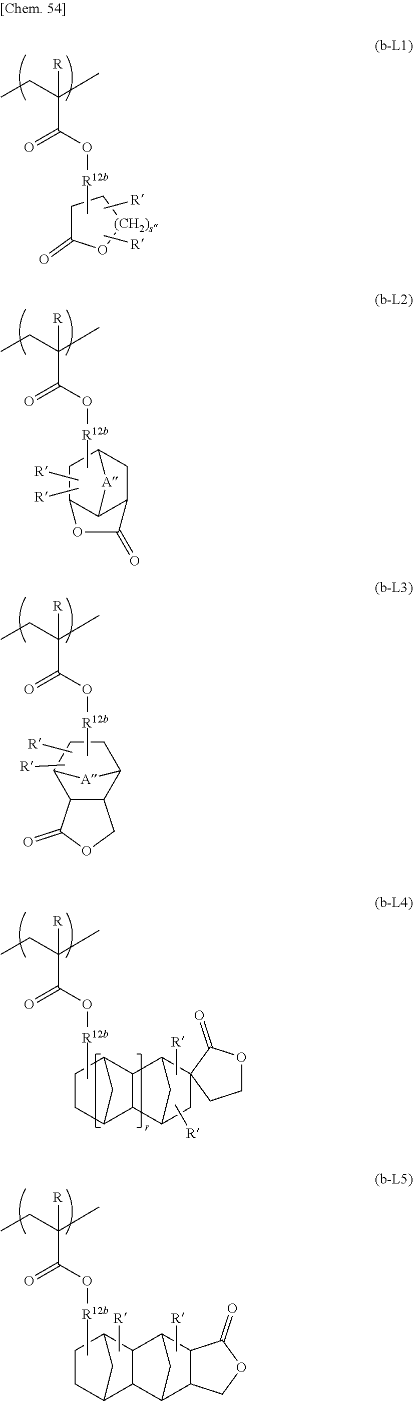

(In the formulae, R represents a hydrogen atom, an alkyl group having 1 or more and 5 or less carbon atoms or a halogenated alkyl group having 1 or more and 5 or less carbon atoms; R′ represents each independently a hydrogen atom, an alkyl group, an alkoxy group, a halogenated alkyl group, a hydroxy group, —COOR″, —OC(═O)R″, a hydroxyalkyl group or a cyano group, and R″ represents a hydrogen atom or an alkyl group; R^{12b} represents a single bond or divalent linking group, and s″ is an integer of 0 or more and 2 or less; A″ represents an alkylene group having 1 or more and 5 or less carbon atoms optionally including an oxygen atom or a sulfur atom, an oxygen atom or a sulfur atom; and r is 0 or 1.)

R in the formulae (b-L1) to (b-L5) is the same as the above. Examples of the alkyl group, the alkoxy group, the halogenated alkyl group, —COOR″, —OC(═O)R″ and the hydroxyalkyl group in R′ include groups similar to those described for the alkyl group, the alkoxy group, the halogenated alkyl group, —COOR″, —OC(═O)R″ and the hydroxyalkyl group recited as a substituent which the —SO₂-containing cyclic group may have, respectively.

R′ is preferably a hydrogen atom in view of easy industrial availability and the like. The alkyl group in R″ may be any of a linear, branched or cyclic chain. In a case where R″ is a linear or branched alkyl group, the number of carbon atoms is preferably 1 or more and 10 or less, and more preferably 1 or more and 5 or less. In a case where R″ is a cyclic alkyl group, the number of carbon atoms is preferably 3 or more and 15 or less, more preferably 4 or more and 12 or less, and most preferably 5 or more and 10 or less. Specific examples include a group in which one or more hydrogen atoms are removed from monocycloalkane and polycycloalkane such as bicycloalkane, tricycloalkane, tetracycloalkane and the like, which may be or not may be substituted with a fluorine atom or a fluorinated alkyl group. Specific examples include a group in which one or more hydrogen atoms are removed from monocycloalkane such as cyclopentane and cyclohexane; and polycycloalkane such as adamantane, norbornane, isobornane, tricyclodecane and tetracyclododecane; and the like. Examples of A″ include groups similar to A′ in the aforementioned formula (3-1). A″ is preferably an alkylene group having 1 to 5 carbon atoms, an oxygen atom (—O—) or a sulfur atom (—S—), more preferably an alkylene group having 1 or more and 5 or less carbon atoms or —O—. As the alkylene group having 1 or more and 5 or less carbon atoms, a methylene group or a dimethylmethylene group is more preferred, and a methylene group is most preferred.

R^{12b} is similar to R^{12b} in the aforementioned formula (b-S1). In the formula (b-L1), s″ is preferably 1 or 2. Below, specific examples of the constituent units represented by the aforementioned formulae (b-L1) to (b-L3) will be illustrated. In each of the following formulae, R^{α} represents a hydrogen atom, a methyl group or a trifluoromethyl group.

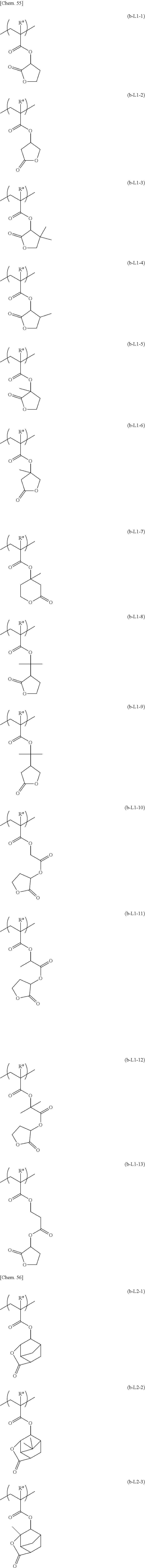

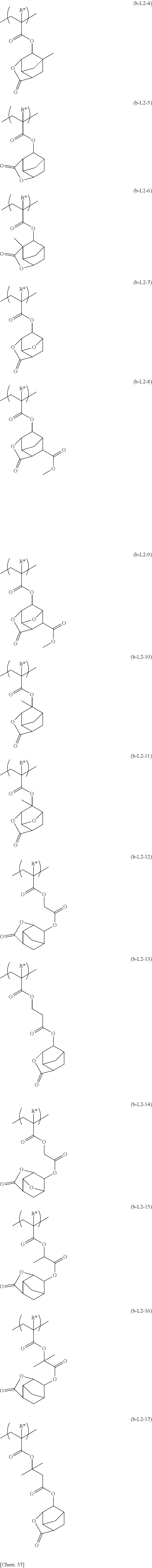

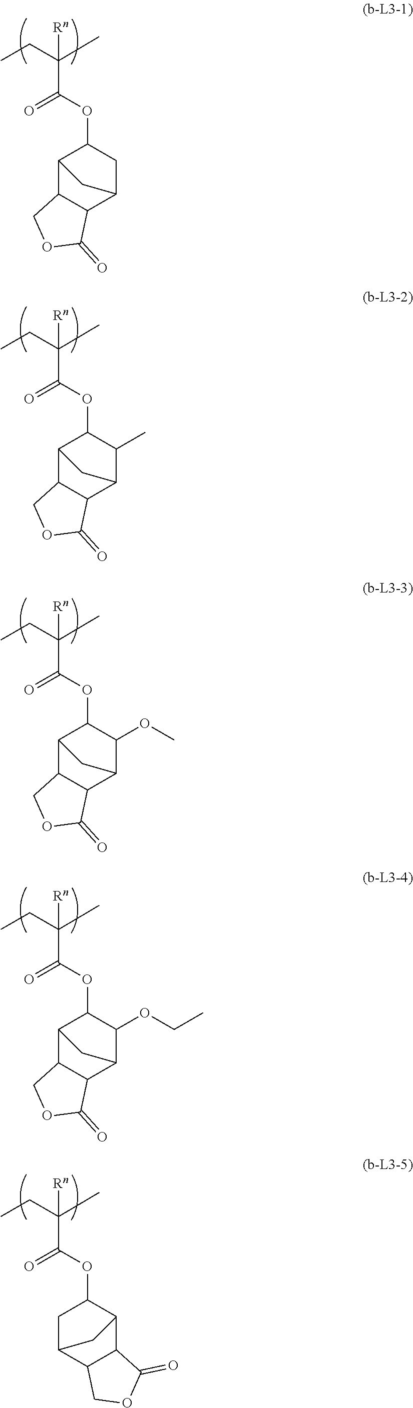

As the constituent unit (b-3-L), at least one selected from the group consisting of the constituent units represented by the aforementioned formulae (b-L1) to (b-L5) is preferred, and at least one selected from the group consisting of the constituent units represented by the formulae (b-L1) to (b-L3) is more preferred, and at least one selected from the group consisting of the constituent units represented by the aforementioned formula (b-L1) or (b-L3) is particularly preferred. Among these, at least one selected from the group consisting of the constituent units represented by the aforementioned formulae (b-L1-1), (b-L1-2), (b-L2-1), (b-L2-7), (b-L2-12), (b-L2-14), (b-L3-1) and (b-L3-5) is preferred.

Further, as the constituent unit (b-3-L), the constituent units represented by following formulae (b-L6) to (b-L7) are also preferred.

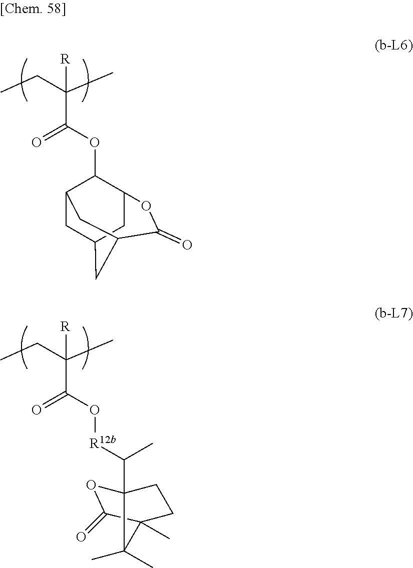

R and R^{12b} in the formulae (b-L6) and (b-L7) are the same as the above.

Further, the acrylic resin (B3) includes constituent units represented by the following formulae (b5) to (b7), having an acid dissociable group, as constituent units that enhance the solubility of the acrylic resin (B3) in alkali under the action of acid.

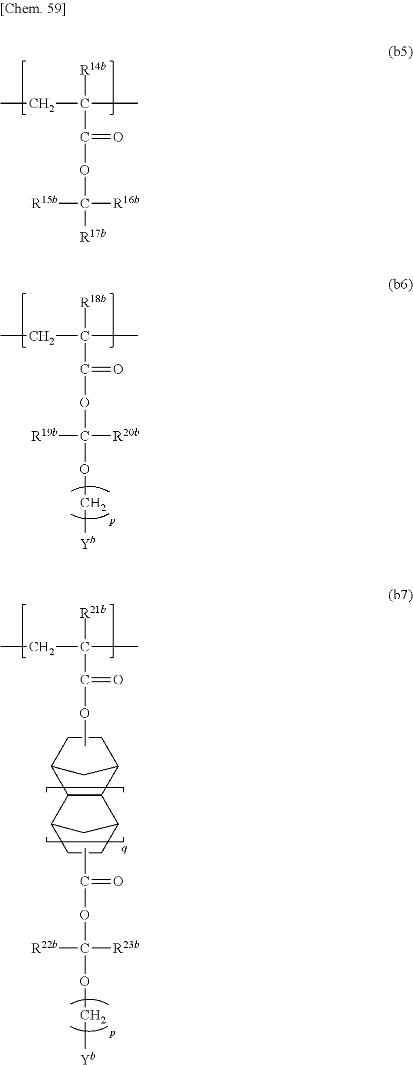

In the above formulae (b5) to (b7), R^{14b} and R^{18b} to R^{23b} each independently represent a hydrogen atom, a linear or branched alkyl group having 1 or more and 6 or less carbon atoms, a fluorine atom, or a linear or branched fluorinated alkyl group having 1 or more and 6 or less carbon atoms; R^{15b} to R^{17b} each independently represent a linear or branched alkyl group having 1 or more and 6 or less carbon atoms, a linear or branched fluorinated alkyl group having 1 or more and 6 or less carbon atoms, or an aliphatic cyclic group having 5 or more and 20 or less carbon atoms, and each independently represent a linear or branched alkyl group having 1 or more and 6 or less carbon atoms, or a linear or branched fluorinated alkyl group having 1 or more and 6 or less carbon atoms; and R^{16b} and R^{17b} may be bonded to each other to form a hydrocarbon ring having 5 or more and 20 or less carbon atoms together with the carbon atom to which both the groups are bonded; Y^{b} represents an optionally substituted aliphatic group or alkyl group; p is an integer of 0 or more and 4 or less; and q is 0 or 1.

Note here that examples of the linear or branched alkyl group include a methyl group, ethyl group, propyl group, isopropyl group, n-butyl group, isobutyl group, tert-butyl group, pentyl group, isopentyl group, neopentyl group, and the like. Furthermore, the fluorinated alkyl group refers to the abovementioned alkyl groups of which the hydrogen atoms are partially or entirely substituted with fluorine atoms. Specific examples of aliphatic cyclic groups include groups obtained by removing one or more hydrogen atoms from monocycloalkanes or polycycloalkanes such as bicycloalkanes, tricycloalkanes, and tetracycloalkanes. Specifically, groups obtained by removing one hydrogen atom from a monocycloalkane such as cyclopentane, cyclohexane, cycloheptane, or cyclooctane, or a polycycloalkane such as adamantane, norbornane, isobornane, tricyclodecane, or tetracyclododecane may be mentioned. In particular, groups obtained by removing one hydrogen atom from cyclohexane or adamantane (which may further be substituted) are preferred.

When R^{16b} and R^{17b} do not combine with each other to form a hydrocarbon ring, the above R^{15b}, R^{16b}, and R^{17b} preferably represent a linear or branched alkyl group having 2 or more and 4 or less carbon atoms, for example, from the viewpoints of a high contrast and favorable resolution and depth of focus. The above R^{19b}, R^{20b}, R^{22b}, and R^{23b} preferably represent a hydrogen atom or a methyl group.

The above R^{16b} and R^{17b} may form an aliphatic cyclic group having 5 or more and 20 or less carbon atoms together with a carbon atom to which the both are attached. Specific examples of such an alicyclic group are the groups of monocycloalkanes and polycycloalkanes such as bicycloalkanes, tricycloalkanes and tetracycloalkanes from which one or more hydrogen atoms are removed. Specific examples thereof are the groups of monocycloalkanes such as cyclopentane, cyclohexane, cycloheptane and cyclooctane and polycycloalkanes such as adamantane, norbornane, isobornane, tricyclodecane and tetracyclododecane from which one or more hydrogen atoms are removed. Particularly preferable are the groups of cyclohexane and adamantane from which one or more hydrogen atoms are removed (that may further have a substituent).

Further, in a case where an aliphatic cyclic group to be formed with the above R^{16b} and R^{17b} has a substituent on the ring skeleton thereof, examples of the substituent include a polar group such as a hydroxy group, a carboxyl group, a cyano group and an oxygen atom (═O), and a linear or branched alkyl group having 1 or more and 4 or less carbon atoms. As the polar group, an oxygen atom (═O) is particularly preferred.

The above Y^{b} is an alicyclic group or an alkyl group; and examples thereof are the groups of monocycloalkanes and polycycloalkanes such as bicycloalkanes, tricycloalkanes and tetracycloalkanes from which one or more hydrogen atoms are removed. Specific examples thereof are the groups of monocycloalkanes such as cyclopentane, cyclohexane, cycloheptane and cyclooctane, and polycycloalkanes such as adamantane, norbornane, isobornane, tricyclodecane and tetracyclododecane from which one or more hydrogen atoms are removed. Particularly preferable is the group of adamantane from which one or more hydrogen atoms are removed (that may further have a substituent).

When the alicyclic group of the above Y^{b} has a substituent on the ring skeleton, the substituent is exemplified by polar groups such as a hydroxy group, carboxyl group, cyano group and oxygen atom (═O), and linear or branched alkyl groups having 1 or more and 4 or less carbon atoms. The polar group is preferably an oxygen atom (═O) in particular.

When Y^{b} is an alkyl group, it is preferably a linear or branched alkyl group having 1 or more and 20 or less carbon atoms, and more preferably 6 or more and 15 or less carbon atoms. The alkyl group is an alkoxyalkyl group particularly preferable. Examples of such an alkoxyalkyl group include a 1-methoxyethyl group, 1-ethoxyethyl group, 1-n-propoxyethyl group, 1-isopropoxyethyl group, 1-n-butoxyethyl group, 1-isobutoxyethyl group, 1-tert-butoxyethyl group, 1-methoxypropyl group, 1-ethoxypropyl group, 1-methoxy-1-methylethyl group, 1-ethoxy-1-methylethyl group, and the like.

Preferable specific examples of the constituent unit represented by the above formula (b5) include constituent units represented by the following formulae (b5-1) to (b5-33).

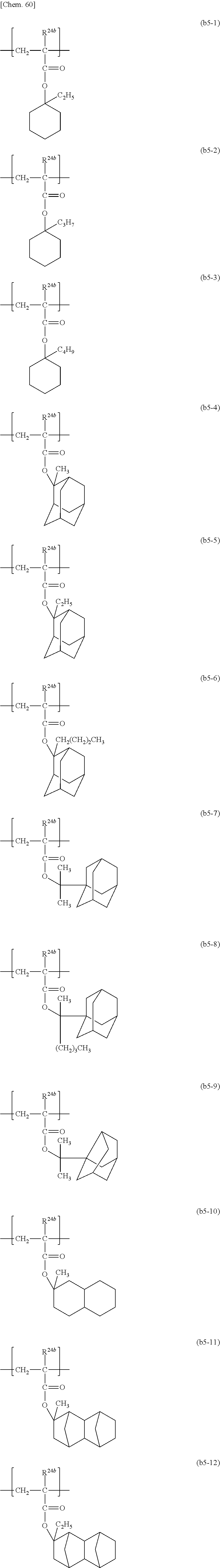

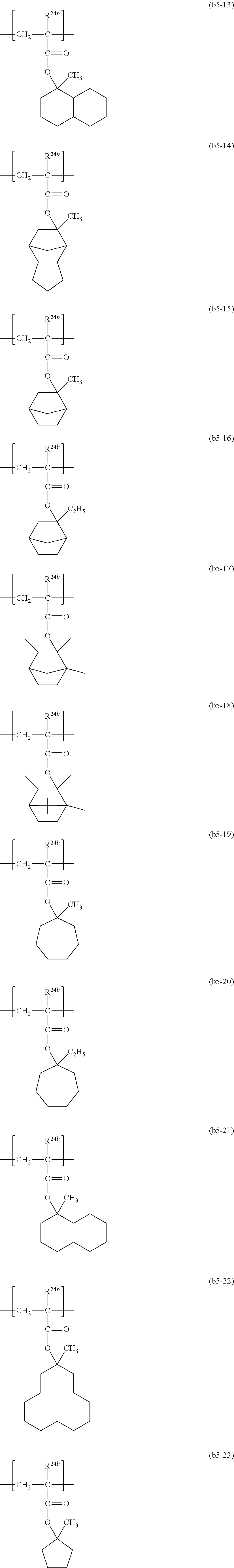

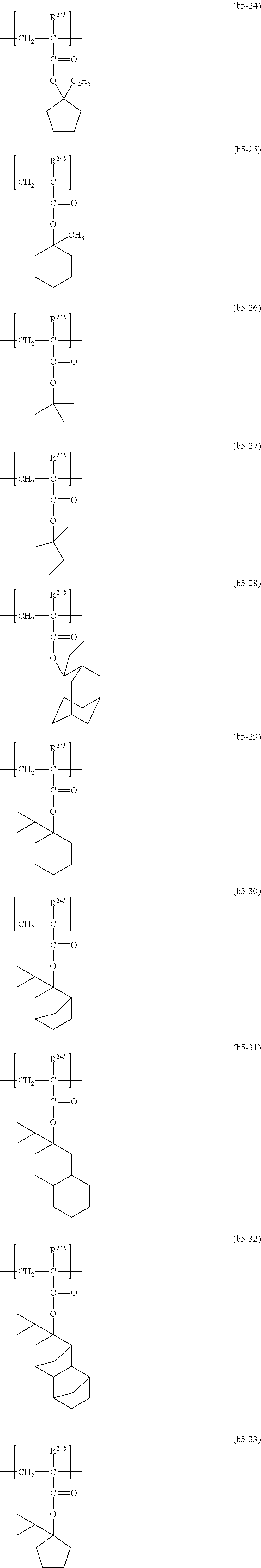

In the above formulae (b5-1) to (b5-33), R^{24b} represents a hydrogen atom or a methyl group.

Preferable specific examples of the constituent unit represented by the above formula (b6) include constituent units represented by the following formulae (b6-1) to (b6-26).

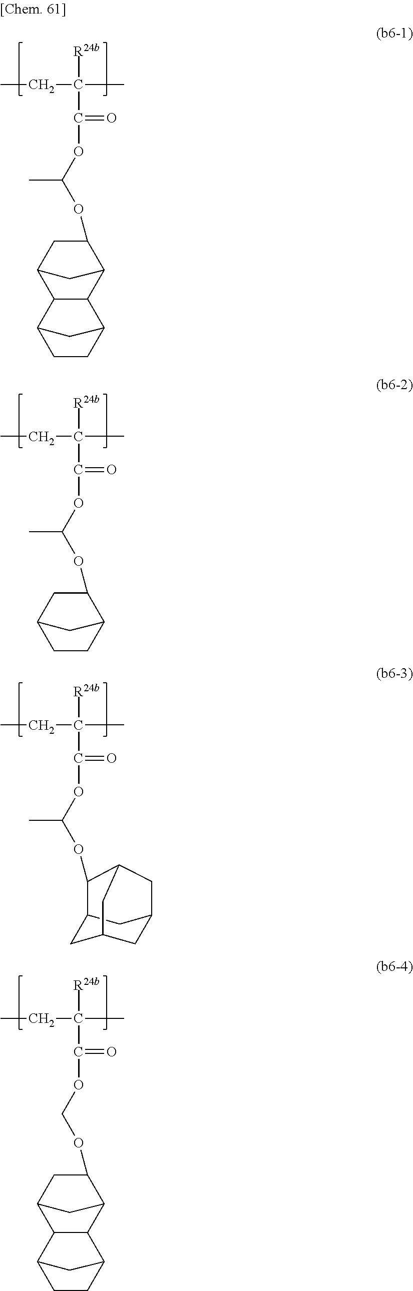

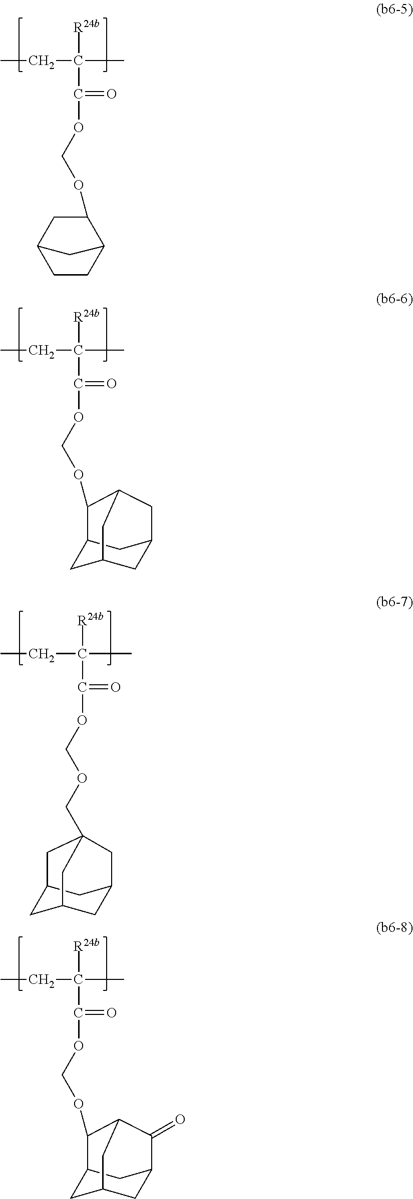

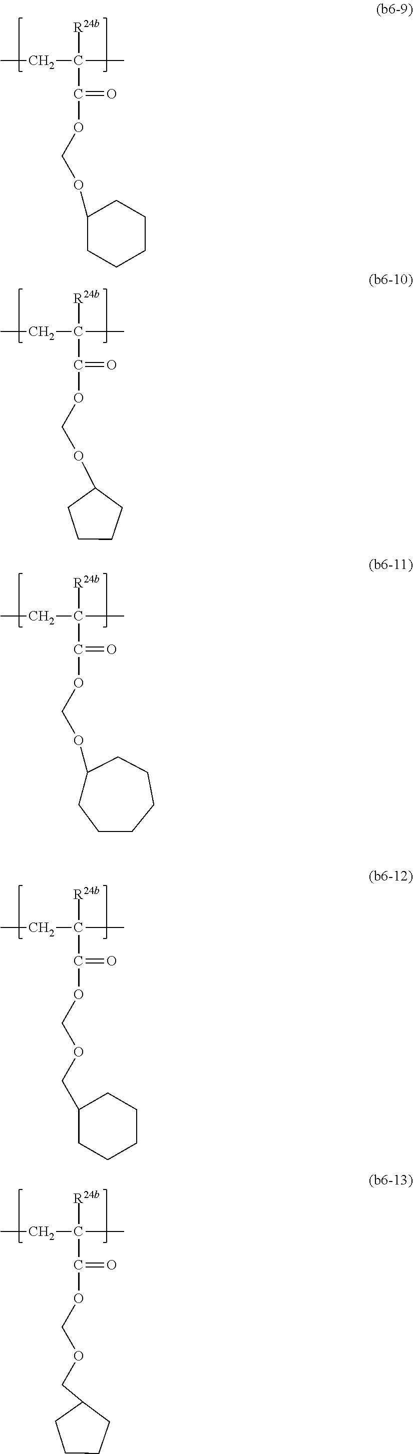

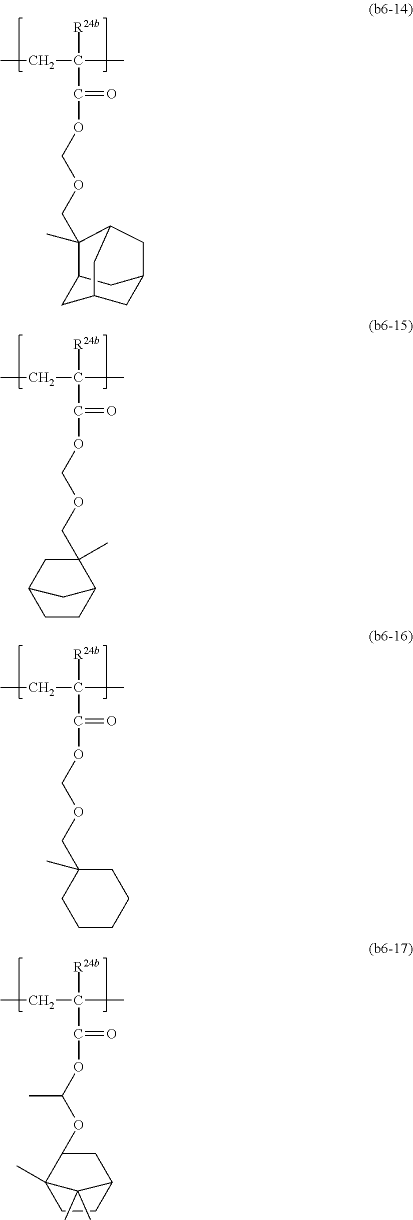

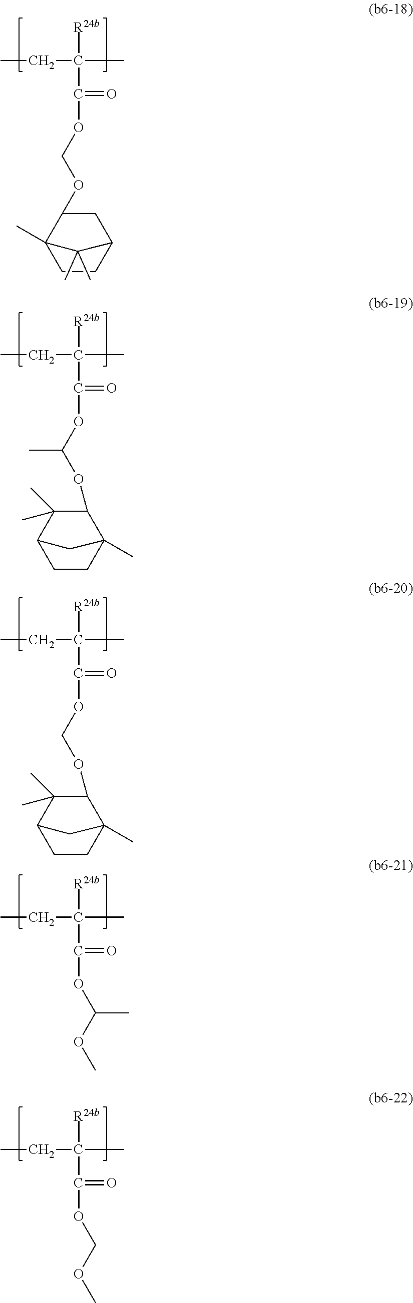

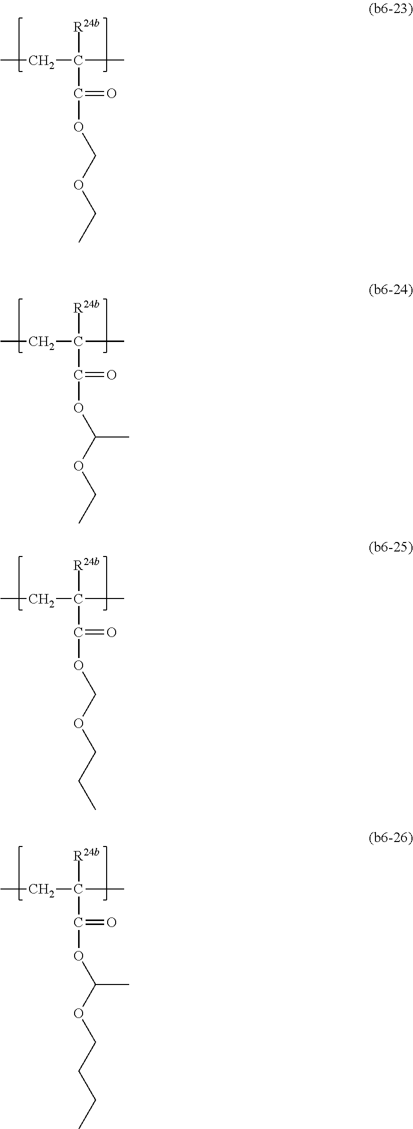

In the above formulae (b6-1) to (b6-26), R^{24b} represents a hydrogen atom or a methyl group.

Preferable specific examples of the constituent unit represented by the above formula (b7) include constituent units represented by the following formulae (b7-1) to (b7-15).

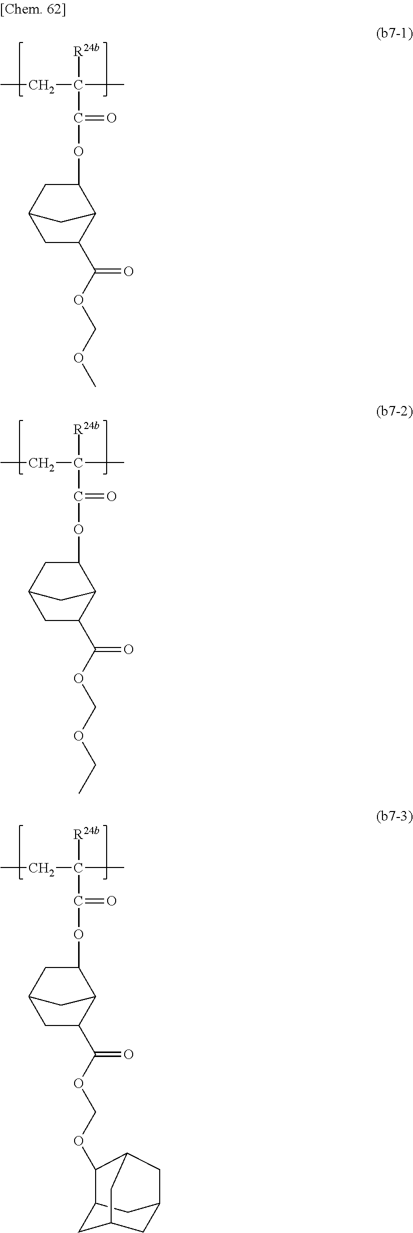

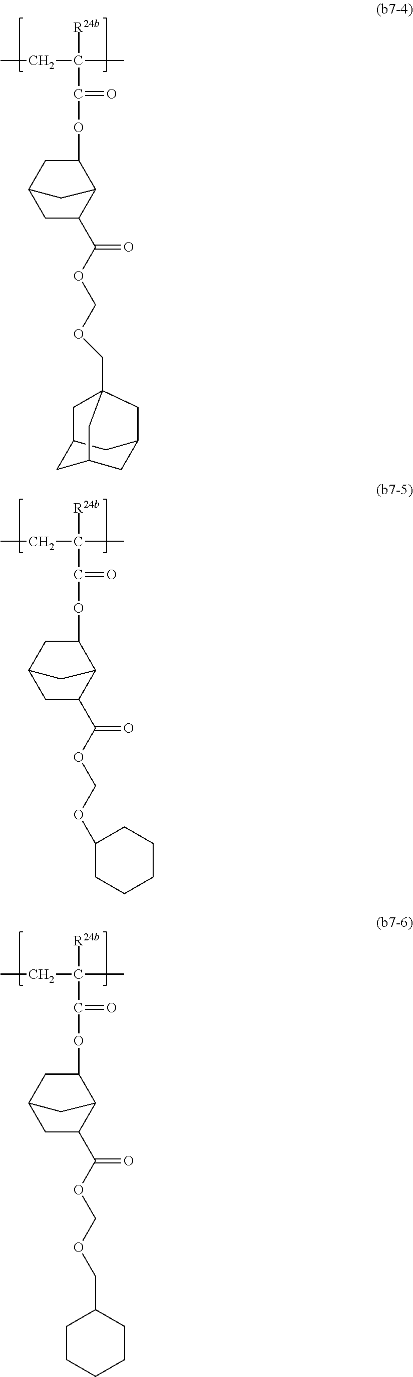

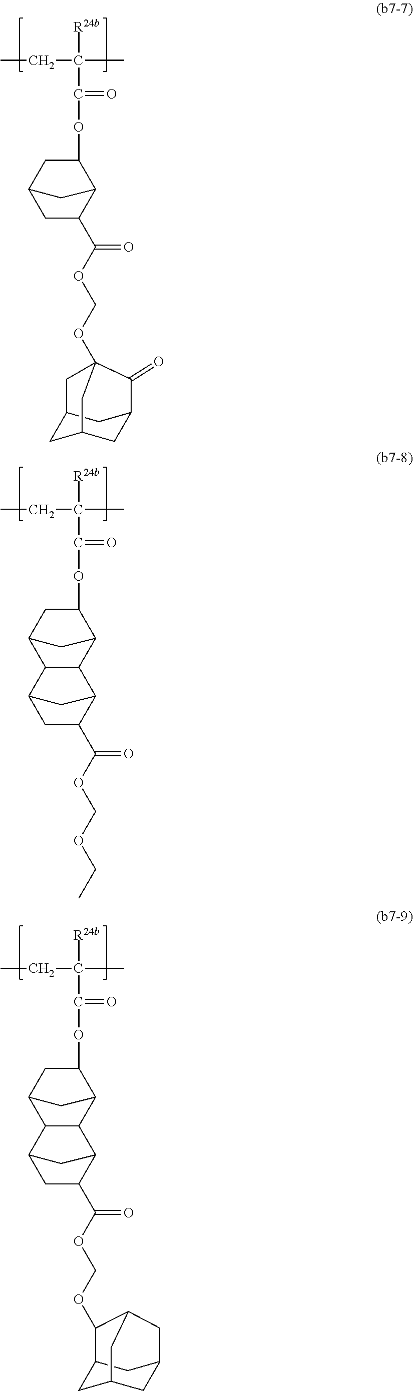

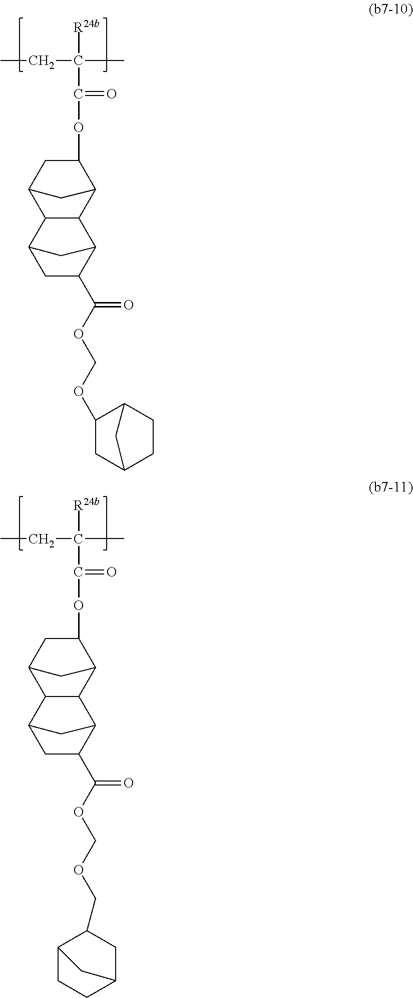

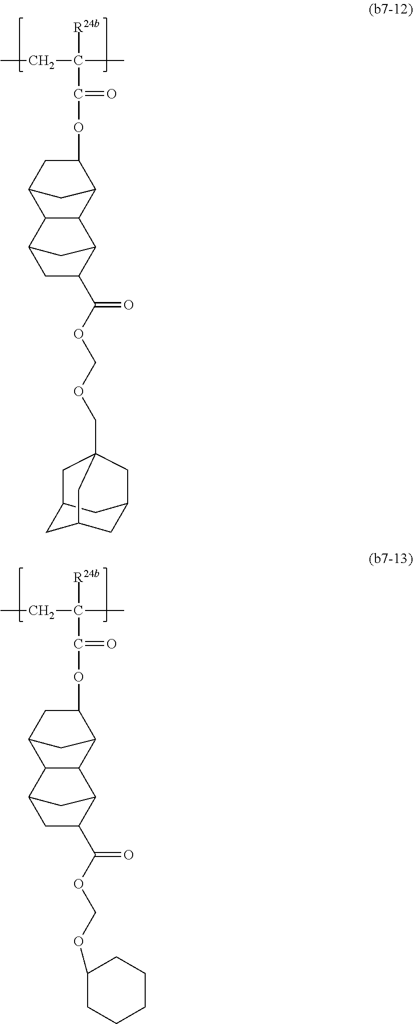

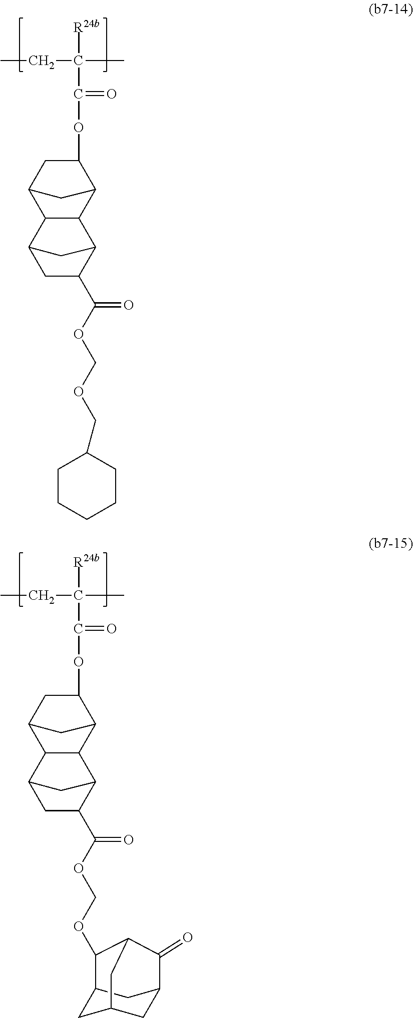

In the above formulae (b7-1) to (b7-15), R^{24b} represents a hydrogen atom or a methyl group.

Among the constituent units represented by the formulae (b5) to (b7) described above, those represented by the formula (b6) are preferred in that they can be easily synthesized and relatively easily sensitized. Further, among the constituent units represented by the formula (b6), those in which Y^{b} is an alkyl group are preferred, and those in which one or both of R^{19b} and R^{20b} are alkyl groups are preferred.

Further, the acrylic resin (B3) is preferably a resin including a copolymer including a constituent unit derived from a polymerizable compound having an ether bond together with a constituent unit represented by the above formulae (b5) to (b7).

Illustrative examples of the polymerizable compound having an ether bond include radical polymerizable compounds such as (meth)acrylic acid derivatives having an ether bond and an ester bond, and specific examples thereof include 2-methoxyethyl (meth)acrylate, 2-ethoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolyethylene glycol (meth)acrylate, methoxypolypropylene glycol (meth)acrylate, tetrahydrofurfuryl (meth)acrylate, and the like. Also, the above polymerizable compound having an ether bond is preferably, 2-methoxyethyl (meth)acrylate, 2-ethoxyethyl (meth)acrylate, or methoxytriethylene glycol (meth)acrylate. These polymerizable compounds may be used alone, or in combinations of two or more thereof.

Furthermore, the acrylic resin (B3) may include another polymerizable compound as a constituent unit in order to moderately control physical or chemical properties. The polymerizable compound is exemplified by conventional radical polymerizable compounds and anion polymerizable compounds.

Examples of the polymerizable compound include monocarboxylic acids such as acrylic acid, methacrylic acid and crotonic acid; dicarboxylic acids such as maleic acid, fumaric acid and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid, and 2-methacryloyloxyethyl hexahydrophthalic acid; (meth)acrylic acid alkyl esters such as methyl(meth)acrylate, ethyl(meth)acrylate, butyl(meth)acrylate and cyclohexyl(meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; amide bond-containing polymerizable compounds such as acrylamide and methacrylamide; and the like.

As described above, the acrylic resin (B3) may include a constituent unit derived from a polymerizable compound having a carboxy group such as the above monocarboxylic acids and dicarboxylic acids. However, it is preferable that the acrylic resin (B3) does not substantially include a constituent unit derived from a polymerizable compound having a carboxyl group, since a resist pattern including a nonresist portion having a favorable rectangular sectional shape can easily be formed. Specifically, the proportion of a constituent unit derived from a polymerizable compound having a carboxyl group in the acrylic resin (B3) is preferably 20% by mass or less, more preferably 15% by mass or less, and particularly preferably 5% by mass or less. In acrylic resin (B3), acrylic resin including a relatively large amount of constituent unit derived from a polymerizable compound having a carboxy group is preferably used in combination with an acrylic resin that includes only a small amount of constituent unit derived from a polymerizable compound having a carboxy group or does not include this constituent unit.

Furthermore, examples of the polymerizable compound include (meth)acrylic acid esters having a non-acid-dissociable aliphatic polycyclic group, and vinyl group-containing aromatic compounds and the like. As the non-acid-dissociable aliphatic polycyclic group, particularly, a tricyclodecanyl group, an adamantyl group, a tetracyclododecanyl group, an isobornyl group, a norbornyl group, and the like are preferred in view of easy industrial availability and the like. These aliphatic polycyclic groups may have a linear or branched alkyl group having 1 or more and 5 or less carbon atoms as a substituent.

Specific examples of the (meth)acrylic acid esters having a non-acid-dissociable aliphatic polycyclic group include those having structures represented by the following formulae (b8-1) to (b8-5).

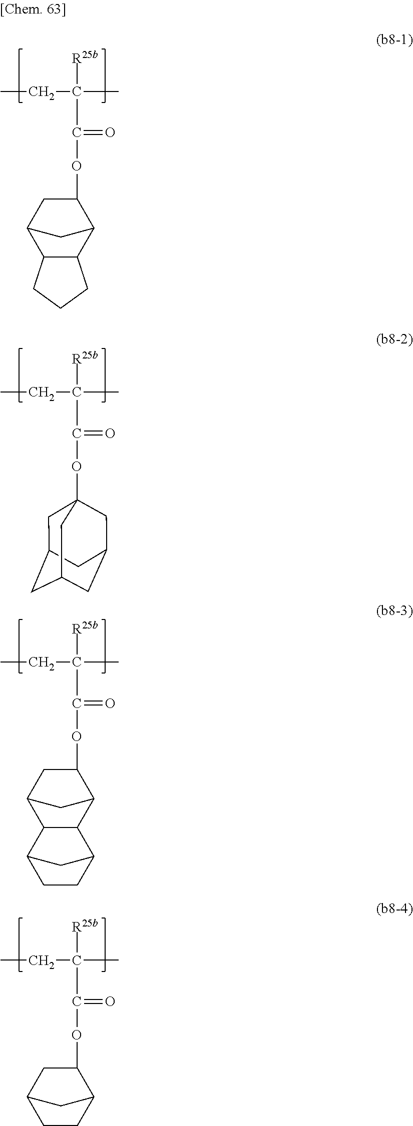

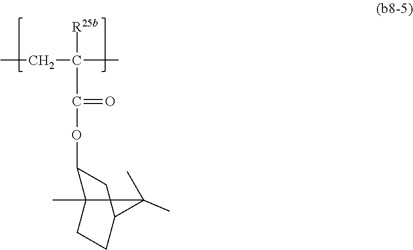

In formulae (b8-1) to (b8-5), R^{25b} represents a hydrogen atom or a methyl group.

When the acrylic resin (B3) includes the constituent unit (b-3) including a —SO₂-containing cyclic group or a lactone-containing cyclic group, the content of the constituent unit (b-3) in the acrylic resin (B3) is preferably 5% by mass or more, more preferably 10% by mass or more, and particularly preferably 10% by mass or more and 50% by mass or less, and most preferably 10% by mass or more and 30% by mass or less. In a case where the photosensitive resin composition includes the constituent unit (b-3) having the above-mentioned range of amount, both good developing property and a good pattern shape can be easily achieved simultaneously.

Further, in the acrylic resin (B3), a constituent unit represented by the aforementioned formulae (b5) to (b7) is preferably included in an amount of 5% by mass or more, more preferably 10% by mass or more, and particularly preferably 10% by mass or more and 50% by mass or less.

The acrylic resin (B3) preferably includes the above constituent unit derived from a polymerizable compound having an ether bond. The content of the constituent unit derived from a polymerizable compound having an ether bond in the acrylic resin (B3) is preferably 0% by mass or more and 50% by mass or less, more preferably 5% by mass or more and 30% by mass or less.

The acrylic resin (B3) preferably includes the above constituent unit derived from (meth)acrylic acid esters having a non-acid-dissociable aliphatic polycyclic group. The content of the constituent unit derived from (meth)acrylic acid esters having a non-acid-dissociable aliphatic polycyclic group in the acrylic resin (B3) is preferably 0% by mass or more and 50% by mass or less, and more preferably 5% by mass or more and 30% by mass or less.

The mass-average molecular weight (hereinafter, also referred to as “mass average molecular weight”) of the resin (B) described above in terms of polystyrene by GPC (gel permeation chromatography) is preferably 10000 or more and 600000 or less, more preferably 20000 or more and 400000 or less, even more preferably 30000 or more and 300000 or less, and particularly preferably 40000 or more and 300000 or less. A mass-average molecular weight within these ranges allows a photosensitive resin layer to maintain sufficient strength without reducing detachability from a substrate, and can further prevent a swelled profile and crack generation when plating.

It is also preferred that the resin (B) has a dispersivity of 1.05 or more. Dispersivity herein indicates a value of a mass average molecular weight divided by a number average molecular weight. A dispersivity in the range described above can further avoid problems with respect to stress resistance on intended plating or possible swelling of metal layers resulting from the plating process.

The content of the resin (B) is preferably 5% by mass or more and 98% by mass or less, and more preferably 5% by mass or more and 85% by mass or less, with respect to the total solid content of the photosensitive resin composition.

### <Phenolic Hydroxyl Group-Containing Low Molecular Weight Compound (C)>

It is preferable that the photosensitive resin composition contains a phenolic hydroxyl group-containing low molecular weight compound (C). The phenolic hydroxyl group means a hydroxyl group (OH) which is directly bonded to a benzene ring. Since the phenolic hydroxyl group-containing low molecular weight compound (C) includes a phenolic hydroxyl group, the compound has alkali-solubility. The alkali-soluble compounds are compounds to be dissolved in 2.38% by mass TMAH solution. The low molecular weight compound is a compound that is not a polymeric substance, and, for example, a compound having a molecular weight of 1500 or less.

The phenolic hydroxyl group-containing low molecular weight compound (C) can increase the dissolution speed of the exposed part, and improve the sensitivity.

Types of the phenolic hydroxyl group-containing low molecular weight compound (C) are not particularly limited within a range where the objects of the present invention are not impaired. As the phenolic hydroxyl group-containing low molecular weight compound (C), a compound including two or more phenolic hydroxyl groups is preferable. Specific examples of the phenolic hydroxyl group-containing low molecular weight compound (C) include the following compounds.

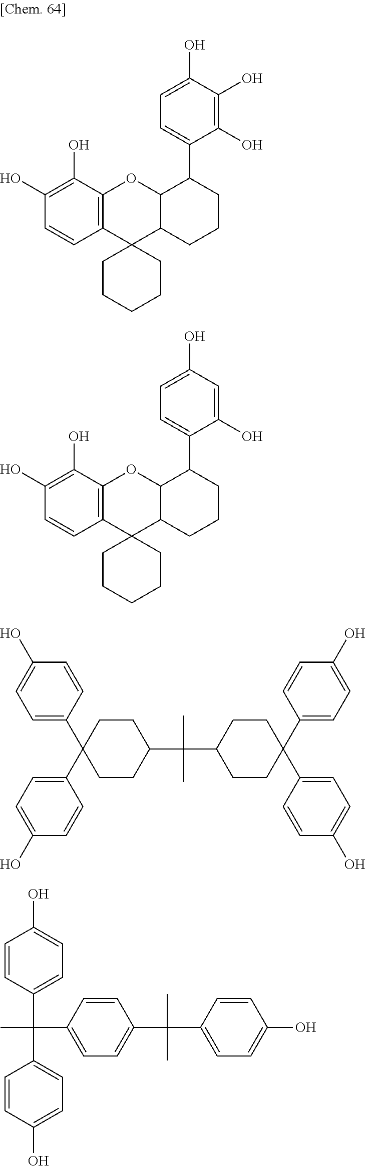

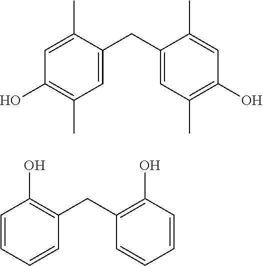 [SMILES: Cc1cc(Cc2cc(C)c(O)cc2C)c(C)cc1O ; Oc1ccccc1Cc1ccccc1O]

Furthermore, examples of the phenolic hydroxyl group-containing low molecular weight compound (C) include polyhydroxybenzophenones such as 2,3,4-trihydroxybenzophenone, and 2,3,4,4′-tetrahydroxybenzophenone; trisphenol-type compounds such as tris(4-hydroxyphenyl)methane, bis(4-hydroxy-3-methylphenyl)-2-hydroxyphenylmethane, bis(4-hydroxy-2,3,5-trimethylphenyl)-2-hydroxyphenylmethane, bis(4-hydroxy-3,5-dimethylphenyl)-4-hydroxyphenylmethane, bis(4-hydroxy-3,5-dimethylphenyl)-3-hydroxyphenylmethane, bis(4-hydroxy-3,5-dimethylphenyl)-2-hydroxyphenylmethane, bis(4-hydroxy-2,5-dimethylphenyl)-4-hydroxyphenylmethane, bis(4-hydroxy-2,5-dimethylphenyl)-3-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-2,5-dimethylphenyl)-2,4-dihydroxyphenylmethane, bis(4-hydroxyphenyl)-3-methoxy-4-hydroxyphenylmethane, bis(5-cyclohexyl-4-hydroxy-2-methylphenyl)-4-hydroxyphenylmethane, bis(5-cyclohexyl-4-hydroxy-2-methylphenyl)-3-hydroxyphenylmethane, bis(5-cyclohexyl-4-hydroxy-2-methylphenyl)-2-hydroxyphenylmethane, bis(5-cyclohexyl-4-hydroxy-2-methylphenyl)-3,4-dihydroxyphenylmethane, and 4,4′-[(3,4-dihydroxy phenyl)methylene]bis(2-cyclohexyl-5-methylphenol); linear trinuclear phenol compounds such as 2,4-bis(3,5-dimethyl-4-hydroxybenzyl)-5-hydroxyphenol, and 2,6-bis(2,5-dimethyl-4-hydroxybenzyl)-4-methylphenol; linear tetranuclear phenol compounds such as 1,1-bis[3-(2-hydroxy-5-methylbenzyl)-4-hydroxy-5-cyclohexylphenyl]isopropane, bis[2,5-dimethyl-3-(4-hydroxy-5-methylbenzyl)-4-hydroxyphenyl]methane, bis[2,5-dimethyl-3-(4-hydroxybenzyl)-4-hydroxyphenyl]methane, bis[3-(3,5-dimethyl-4-hydroxybenzyl)-4-hydroxy-5-methylphenyl]methane, bis[3-(3,5-dimethyl-4-hydroxybenzyl)-4-hydroxy-5-ethylphenyl]methane, bis[3-(3,5-diethyl-4-hydroxybenzyl)-4-hydroxy-5-methylphenyl]methane, bis[3-(3,5-diethyl-4-hydroxybenzyl)-4-hydroxy-5-ethylphenyl]methane, bis[2-hydroxy-3-(3,5-dimethyl-4-hydroxybenzyl)-5-methylphenyl]methane, bis[2-hydroxy-3-(2-hydroxy-5-methylbenzyl)-5-methylphenyl]methane, bis[4-hydroxy-3-(2-hydroxy-5-methylbenzyl)-5-methylphenyl]methane, and bis[2,5-dimethyl-3-(2-hydroxy-5-methylbenzyl)-4-hydroxyphenyl]methane; linear polyphenol compounds such as linear pentanuclear phenol compounds including 2,4-bis[2-hydroxy-3-(4-hydroxybenzyl)-5-methylbenzyl]-6-cyclohexylphenol, 2,4-bis[4-hydroxy-3-(4-hydroxybenzyl)-5-methylbenzyl]-6-cyclohexylphenol, 2,6-bis[2,5-dimethyl-3-(2-hydroxy-5-methylbenzyl)-4-hydroxybenzyl]-4-methylphenol, or the like; bisphenol compounds such as bis(2,3,4-trihydroxyphenyl)methane, bis(2,4-dihydroxyphenyl)methane, 2,3,4-trihydroxyphenyl-4′-hydroxyphenylmethane, 2-(2,3,4-trihydroxyphenyl)-2-(2′,3′,4′-trihydroxyphenyl)propane, 2-(2,4-dihydroxyphenyl)-2-(2′,4′-dihydroxyphenyl)propane, 2-(4-hydroxyphenyl)-2-(4′-hydroxyphenyl)propane, 2-(3-fluoro-4-hydroxyphenyl)-2-(3′-fluoro-4′-hydroxyphenyl)propane, 2-(2,4-dihydroxyphenyl)-2-(4′-hydroxyphenyl)propane, 2-(2,3,4-trihydroxyphenyl)-2-(4′-hydroxyphenyl)propane, and 2-(2,3,4-trihydroxyphenyl)-2-(4′-hydroxy-3′,5′-dimethylphenyl)propane; multinuclear branched compounds such as 1-[1-(3-methyl-4-hydroxyphenyl)isopropyl]-4-[1,1-bis(3-methyl-4-hydroxyphenyl)ethyl]benzene, or the like; and condensed phenol compounds such as 1,1-bis(4-hydroxyphenyl)cyclohexane, and, bisphenol A, pyrogallol monomethyl ether, pyrogallol-1,3-dimethyl ether, and the like. These phenol compounds can be used alone or in combination of two or more.

When the photosensitive resin composition includes the phenolic hydroxyl group-containing low molecular weight compound (C), the content of the phenolic hydroxyl group-containing low molecular weight compound (C) is preferably 1 part by mass or more and 20 parts by mass or less, and more preferably 3 parts by mass or more and 15 parts by mass or less when the total of resins contained in the photosensitive resin composition is 100 parts by mass.

### <Alkali-Soluble Resin (D)>

It is preferable that the photosensitive resin composition further contains an alkali-soluble resin (D) in order to improve alkali-solubility. The alkali-soluble resin as referred to herein may be determined as follows. A resin solution having a resin concentration of 20% by mass (solvent: propylene glycol monomethyl ether acetate) is used to form a resin film having a thickness of 1 μm on a substrate, and immersed in an aqueous 2.38% by mass TMAH (tetramethylammonium hydroxide) solution for 1 minute. When the resin was dissolved in an amount of 0.01 μm or more, the resin is defined as being alkali soluble, wherein the alkali-soluble resin is not the component (B) described above (typically, the resin is defined as resin whose alkali-solubility does not substantially change even under action of acid). As the alkali-soluble resin (D), preferably, for example, at least one selected from the group consisting of novolac resin (D1), polyhydroxystyrene resin (D2), and acrylic resin (D3), can be used.

### [Novolak Resin (D1)]

A novolak resin is obtained by addition condensation of, for example, aromatic compounds having a phenolic hydroxy group (hereinafter, merely referred to as “phenols”) and aldehydes in the presence of an acid catalyst.

Examples of the above phenols include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethyl phenol, 3,4,5-trimethyl phenol, p-phenylphenol, resorcinol, hydroquinone, hydroquinone monomethyl ether, pyrogallol, phloroglycinol, hydroxydiphenyl, bisphenol A, gallic acid, gallic acid ester, α-naphthol, β-naphthol, and the like. Examples of the above aldehydes include formaldehyde, furfural, benzaldehyde, nitrobenzaldehyde, acetaldehyde, and the like. The catalyst used in the addition condensation reaction is not particularly limited, and examples thereof include hydrochloric acid, nitric acid, sulfuric acid, formic acid, oxalic acid, acetic acid, etc., for acid catalyst.

The flexibility of the novolak resins can be enhanced more when o-cresol is used, a hydrogen atom of a hydroxyl group in the resins is substituted with other substituents, or bulky aldehydes are used.

The mass average molecular weight of novolac resin (D1) is not particularly limited as long as the purpose of the present invention is not impaired, but the mass average molecular weight is preferably 1,500 or more and 50,000 or less.

### [Polyhydroxystyrene Resin (D2)]

The hydroxystyrene-based compound (hydroxystyrene and hydroxystyrene derivatives) to constitute the polyhydroxystyrene resin (D2) is exemplified by p-hydroxystyrene, α-methylhydroxystyrene, α-ethylhydroxystyrene, and the like. Furthermore, the polyhydroxystyrene resin (D2) is preferably made to give a copolymer with a styrene resin. Examples of the styrene compound to constitute such a styrene resin include styrene, chlorostyrene, chloromethylstyrene, vinyltoluene, α-methylstyrene, and the like.

The mass average molecular weight of the polyhydroxystyrene resin (D2) is not particularly limited as long as the purpose of the present invention is not impaired, but the mass average molecular weight is preferably 1,500 or more and 50,000 or less.

### [Acrylic Resin (D3)]

It is preferable that the acrylic resin (D3) includes a constituent unit derived from a polymerizable compound having an ether bond and a constituent unit derived from a polymerizable compound having a carboxyl group.

Examples of the above polymerizable compound having an ether bond include (meth)acrylic acid derivatives having an ether bond and an ester bond such as 2-methoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolypropylene glycol (meth)acrylate, tetrahydrofurfuryl (meth)acrylate, and the like. The above polymerizable compound having an ether bond is preferably, 2-methoxyethyl acrylate, and methoxytriethylene glycol acrylate. These polymerizable compounds may be used alone, or in combinations of two or more.

Examples of the above polymerizable compound having a carboxy group include monocarboxylic acids such as acrylic acid, methacrylic acid and crotonic acid; dicarboxylic acids such as maleic acid, fumaric acid and itaconic acid; compounds having a carboxy group and an ester bond such as 2-methacryloyloxyethyl succinic acid, 2-methacryloyloxyethyl maleic acid, 2-methacryloyloxyethyl phthalic acid, 2-methacryloyloxyethyl hexahydrophthalic acid and the like. The above polymerizable compound having a carboxy group is preferably, acrylic acid and methacrylic acid. These polymerizable compounds may be used alone, or in combinations of two or more thereof.

The mass average molecular weight of the acrylic resin (D3) is not particularly limited as long as the purpose of the present invention is not impaired, but the mass average molecular weight is preferably 50,000 or more and 800,000 or less.

The content of the alkali-soluble resin (D) is preferably 3 parts by mass or more and 70 parts by mass or less, and more preferably 5 parts by mass or more and 50 parts by mass or less when the total solid content is 100 parts by mass. By setting the content of the alkali-soluble resin (D) to the range described above, there is a tendency for alkali-solubility.

### <Sulfur-Containing Compound (E)>

Since a photosensitive resin composition is used for pattern formation on a metal substrate, the photosensitive resin composition preferably includes a sulfur-containing compound (E). The sulfur-containing compound (E) is a compound including a sulfur atom that can coordinate with metal. Note here that in a compound that can generate two or more tautomers, at least one tautomer includes a sulfur atom that coordinates with metal constituting a surface of the metal substrate, the compound corresponds to a sulfur-containing compound. When a resist pattern serving as a template for plating is formed on a surface made of metal such as Cu, defectives such as footing having a cross-sectional shape easily occur. However, when the photosensitive resin composition includes a sulfur-containing compound (E), even when a resist pattern is formed on a surface made of metal in a substrate, defectives such as footing having a cross-sectional shape is easily suppressed. Note here that the “footing” is a phenomenon in which the width of the bottom becomes narrower than that of the top in a nonresist section due to protrusion of a resist section toward the nonresist section in the vicinity of the contacting surface between the substrate surface and the resist pattern.

The sulfur atom that can coordinate with metal is included in a sulfur-containing compound as, for example, a mercapto group (—SH), a thiocarboxy group (—CO—SH), a dithiocarboxy group (—CS—SH), a thiocarbonyl group (—CS—), and the like. From the viewpoint of easiness in coordinating with metal and being excellent in suppressing footing, the sulfur-containing compound preferably includes a mercapto group.

Preferable examples of the sulfur-containing compound having a mercapto group include compounds represented by the following formula (e1).

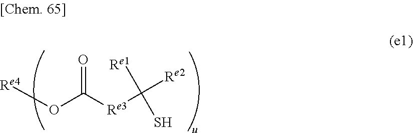

(In the formula, R^{e1} and R^{e2} each independently represent a hydrogen atom or an alkyl group, R^{e3} represents a single bond or an alkylene group, R^{e4} represents a u-valence aliphatic group optionally including an atom other than carbon, and u is an integer of 2 or more and 4 or less.)

R^{e1} and R^{e2} are an alkyl group, the alkyl group may be linear or branched, and is preferably linear. When R^{e1} and R^{e2} are an alkyl group, the number of carbon atoms of the alkyl group is not particularly limited within a range where the objects of the present invention are not impaired. The number of carbon atoms of the alkyl group is preferably 1 or more and 4 or less, particularly preferably 1 or 2, and the most preferably 1. As the combination of R^{e1} and R^{e2}, preferably, one is a hydrogen atom and the other is an alkyl group, and particularly preferably one is a hydrogen atom and the other is a methyl group.

When R^{e3} is an alkylene group, the alkylene group may be linear or branched, and is preferably linear. When R^{e3} is an alkylene group, the number of carbon atoms of the alkylene group is not particularly limited within a range where the objects of the present invention are not impaired. The number of carbon atoms of the alkylene group is preferably 1 or more and 10 or less, more preferably 1 or more and 5 or less, particularly preferably 1 or 2, and the most preferably 1.

R^{e4} is an aliphatic group having two or more and four or less valences and optionally including an atom other than carbon atom. Examples of the atoms which may be included in R^{e4} include a nitrogen atom, an oxygen atom, a sulfur atom, a fluorine atom, a chlorine atom, a bromine atom, an iodine atom, and the like. A structure of the aliphatic group as R^{e4} may be linear or branched, or may be cyclic, and a structure combining these structures.

Among the compounds represented by the formula (e1), a compound represented by the following formula (e2) is more preferable.

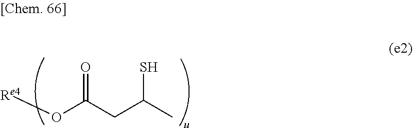

(In the formula (e2), R^{e4} and u are the same as those in the formula (e1).)

Among the compounds represented by the above formula (e2), the following compounds are preferable.

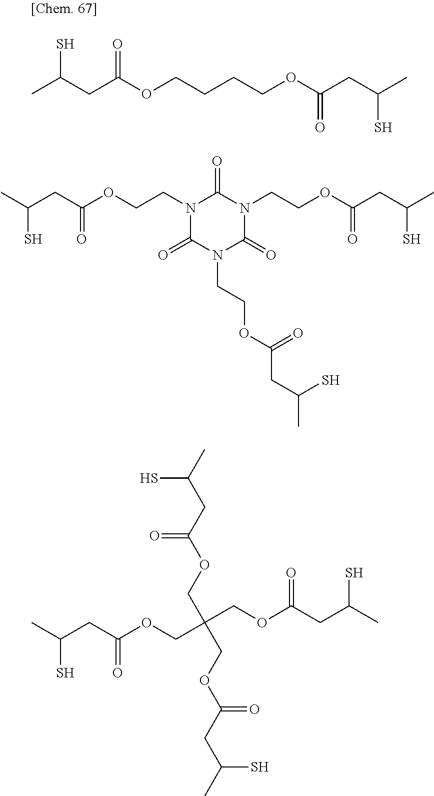

Compounds represented by the following formulae (e3-L1) to (e3-L7) are also preferable examples as the sulfur-containing compound having a mercapto group.

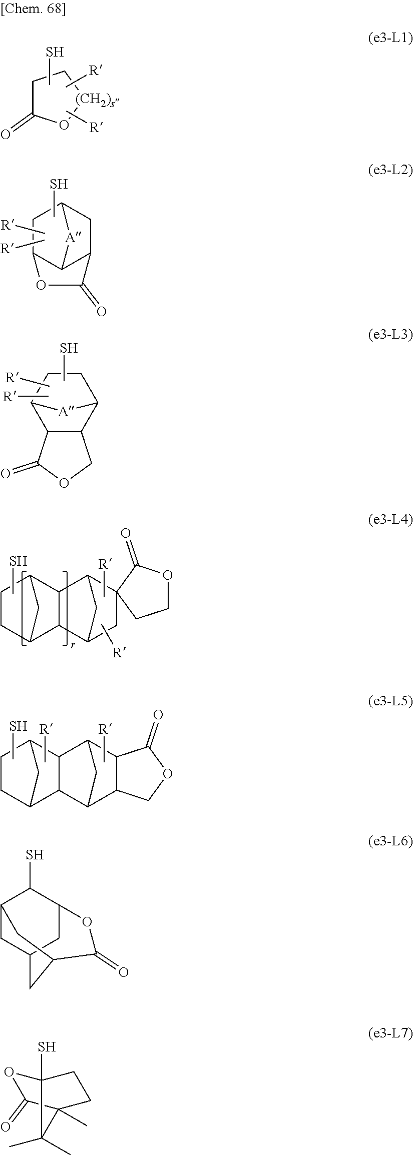

(In the formulae (e3-L1) to (e3-L7), R′, s″, A″, and r are the same as in the formulae (b-L1) to (b-L7) described for the acrylic resin (B3).)

Suitable specific examples of the mercapto compound represented by the above formulae (e3-L1) to (e3-L7) include the following compounds.

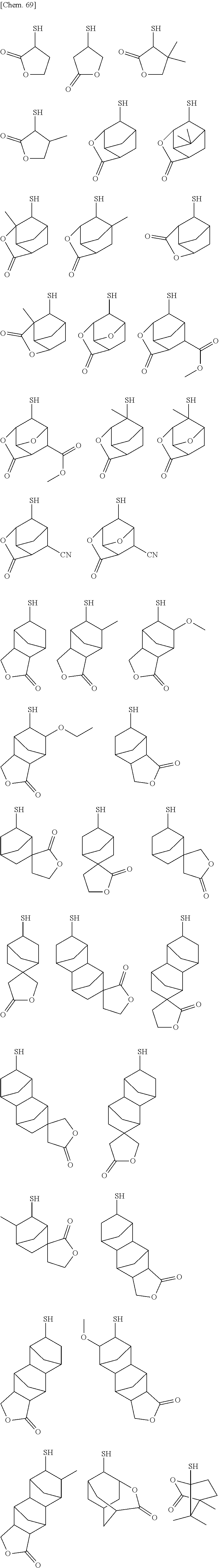

Compounds represented by the following formulae (e3-1) to (e3-4) are also preferable examples as the sulfur-containing compound having a mercapto group.

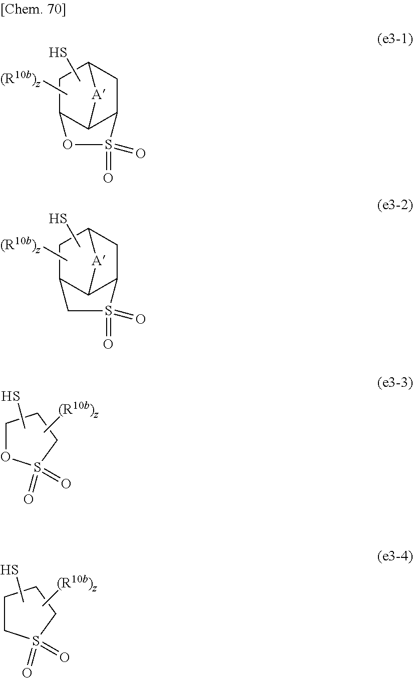

(In the formulae (e3-1) to (e3-4), definitions of abbreviations are the same as mentioned for the formulae (3-1) to (3-4) described for acrylic resin (B3).)

Suitable specific examples of the mercapto compound represented by the above formulae (e3-1) to (e3-4) include the following compounds.

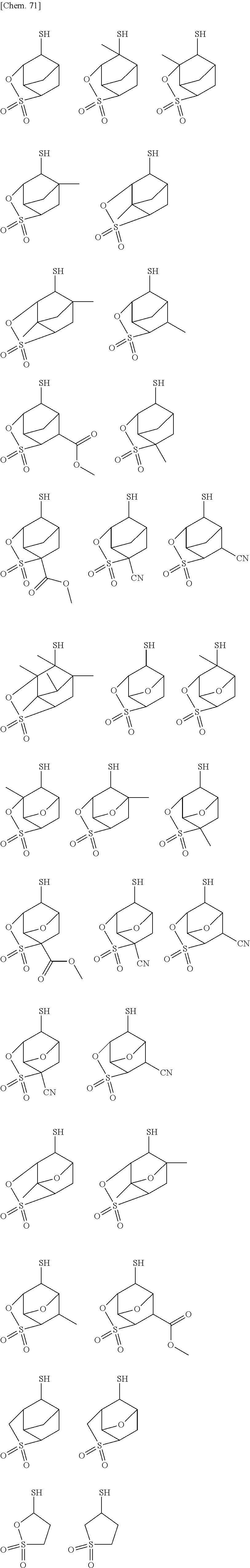

Furthermore, preferable examples of the compound having a mercapto group include compounds represented by the following formula (e4).

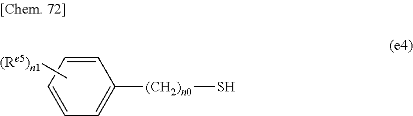

(In the formula (e4), R^{e5} is a group selected from the group consisting of a hydroxyl group, an alkyl group having 1 or more and 4 or less carbon atoms, an alkoxy group having 1 or more and 4 or less carbon atoms, an alkylthio group having 1 or more and 4 or less carbon atoms, a hydroxyalkyl group having 1 or more and 4 or less carbon atoms, a mercapto alkyl group having 1 or more and 4 or less carbon atoms, a halogenated alkyl group having 1 or more and 4 or less carbon atoms, and a halogen atom, n1 is an integer of 0 or more and 3 or less, n0 is an integer of 0 or more and 3 or less, when n1 is 2 or 3, R^{e5} may be the same as or different from each other.)

Specific examples when R^{e5} is an alkyl group which may have a hydroxyl group having 1 or more and 4 or less carbon atoms include a methyl group, an ethyl group, an n-propyl group, an isopropyl group, an n-butyl group, an isobutyl group, a sec-butyl group, and a tert-butyl group. Among these alkyl groups, a methyl group, a hydroxymethyl group, and an ethyl group are preferable.

Specific examples when R^{e5} is an alkoxy group having 1 or more and 4 or less carbon atoms include a methoxy group, an ethoxy group, an n-propyloxy group, an isopropyloxy group, an n-butyloxy group, an isobutyloxy group, a sec-butyloxy group, and a tert-butyloxy group. Among these alkoxy groups, a methoxy group and an ethoxy group are preferable, and a methoxy group is more preferable.

Specific examples when R^{e5} is an alkylthio group having 1 or more and 4 or less carbon atoms include a methylthio group, an ethylthio group, an n-propylthio group, an isopropylthio group, an n-butylthio group, an isobutylthio, a sec-butylthio group, and a tert-butylthio group. Among these alkylthio groups, a methylthio group, and an ethylthio group are preferable, and a methylthio group is more preferable.

Specific examples when R^{e5} is a hydroxyalkyl group having 1 or more and 4 or less carbon atoms include a hydroxymethyl group, a 2-hydroxyethyl group, a 1-hydroxyethyl group, a 3-hydroxy-n-propyl group, and a 4-hydroxy-n-butyl group, and the like. Among these hydroxyalkyl groups, a hydroxymethyl group, a 2-hydroxyethyl group, and a 1-hydroxyethyl group are preferable, and a hydroxymethyl group is more preferable.

Specific examples when R^{e5} is a mercapto alkyl group having 1 or more and 4 or less carbon atoms include a mercapto methyl group, a 2-mercapto ethyl group, a 1-mercapto ethyl group, a 3-mercapto-n-propyl group, a 4-mercapto-n-butyl group, and the like. Among these mercapto alkyl groups, a mercapto methyl group, a 2-mercapto ethyl group, and 1-mercapto ethyl group are preferable, and a mercapto methyl group is more preferable.

When R^{e5} is an alkyl halide group having 1 or more and 4 or less carbon atoms, examples of the halogen atom included in the alkyl halide group include fluorine, chlorine, bromine, iodine, and the like. Specific examples when R^{e5} is an alkyl halide group having 1 or more and 4 or less carbon atoms include a chloromethyl group, a bromomethyl group, an iodomethyl group, a fluoromethyl group, a dichloromethyl group, a dibromomethyl group, a difluoromethyl group, a trichloromethyl group, a tribromomethyl group, a trifluoromethyl group, a 2-chloroethyl group, a 2-bromoethyl group, a 2-fluoroethyl group, a 1,2-dichloroethyl group, a 2,2-difluoroethyl group, a 1-chloro-2-fluoroethyl group, 3-chloro-n-propyl group, a 3-bromon-propyl group, a 3-fluoro-n-propyl group, 4-chloro-n-butyl group, and the like. Among these alkyl halide groups, a chloromethyl group, a bromomethyl group, an iodomethyl group, a fluoromethyl group, a dichloromethyl group, a dibromomethyl group, a difluoromethyl group, a trichloromethyl group, a tribromomethyl group, and a trifluoromethyl group are preferable, and a chloromethyl group, a dichloromethyl group, a trichloromethyl group, and a trifluoromethyl group are more preferable.

Specific examples when R^{e5} is a halogen atom include fluorine, chlorine, bromine, or iodine.

In the formula (e4), n1 is an integer of 0 or more and 3 or less, and 1 is more preferable. When n1 is 2 or 3, a plurality of R^{e5}s may be the same as or different from each other.

In the compound represented by the formula (e4), a substituted position of R^{e5} on a benzene ring is not particularly limited. The substituted position of R^{e5} on a benzene ring is preferably a meta position or a para position with respect to the bond position of —(CH₂)ₙ₀—SH.

The compound represented by the formula (e4) is preferably a compound having at least one group selected from the group consisting of an alkyl group, a hydroxyalkyl group, and a mercapto alkyl group as R^{e5}, and more preferably a compound having one group selected from the group consisting of an alkyl group, a hydroxyalkyl group, and a mercapto alkyl group as R^{e5}. When the compound represented by the formula (e4) has one group selected from the group consisting of an alkyl group, a hydroxyalkyl group, and a mercapto alkyl group as R^{e5}, the substituted position on the benzene ring of the alkyl group, the hydroxyalkyl group, or the mercapto alkyl group is preferably a meta position or a para position with respect to the bond position of —(CH₂)ₙ₀—SH, and more preferably a para position.

In the formula (e4), n0 is an integer of 0 or more and 3 or less. From the viewpoint that preparation or availability of a compound is easy, n0 is preferably 0 or 1, and more preferably 0.

Specific examples of the compound represented by the formula (e4) include p-mercaptophenol, p-thiocresol, m-thiocresol, 4-(methylthio)benzenethiol, 4-methoxybenzenethiol, 3-methoxybenzenethiol, 4-ethoxybenzenethiol, 4-isopropyloxy benzenethiol, 4-tert-butoxybenzenethiol, 3,4-dimethoxy benzenethiol, 3,4,5-trimethoxybenzenethiol, 4-ethylbenzenethiol, 4-isopropyl benzenethiol, 4-n-butylbenzenethiol, 4-tert-butylbenzenethiol, 3-ethylbenzenethiol, 3-isopropyl benzenethiol, 3-n-butylbenzenethiol, 3-tert-butylbenzenethiol, 3,5-dimethyl benzenethiol, 3,4-dimethyl benzenethiol, 3-tert-butyl-4-methylbenzenethiol, 3-tert-4-methylbenzenethiol, 3-tert-butyl-5-methylbenzenethiol, 4-tert-butyl-3-methylbenzenethiol, 4-mercaptobenzyl alcohol, 3-mercaptobenzyl alcohol, 4-(mercaptomethyl)phenol, 3-(mercaptomethyl)phenol, 1,4-di(mercaptomethyl)phenol, 1,3-di(mercaptomethyl)phenol, 4-fluorobenzenethiol, 3-fluorobenzenethiol, 4-chlorobenzenethiol, 3-chlorobenzenethiol, 4-bromobenzenethiol, 4-iodobenzenethiol, 3-bromobenzenethiol, 3,4-dichlorobenzenethiol, 3,5-dichlorobenzenethiol, 3,4-difluorobenzenethiol, 3,5-difluorobenzenethiol, 4-mercaptocatechol, 2,6-di-tert-butyl-4-mercaptophenol, 3,5-di-tert-butyl-4-methoxybenzenethiol, 4-bromo-3-methylbenzenethiol, 4-(trifluoromethyl)benzenethiol, 3-(trifluoromethyl)benzenethiol, 3,5-bis(trifluoromethyl)benzenethiol, 4-methylthiobenzenethiol, 4-ethylthiobenzenethiol, 4-n-butylthiobenzenethiol, and 4-tert-butylthiobenzenethiol, and the like.

Furthermore, examples of the sulfur-containing compound having a mercapto group include a compound including nitrogen-containing aromatic heterocycle substituted with a mercapto group, and a tautomer of a compound including nitrogen-containing aromatic heterocycle substituted with a mercapto group. Preferable specific examples of the nitrogen-containing aromatic heterocycle include imidazole, pyrazole, 1,2,3-triazol, 1,2,4-triazol, oxazole, thiazole, pyridine, pyrimidine, pyridazine, pyrazine, 1,2,3-triazine, 1,2,4-triazine, 1,3,5-triazine, indole, indazole, benzimidazole, benzoxazole, benzothiazole, 1H-benzotriazole, quinoline, isoquinoline, cinnoline, phthalazine, quinazoline, quinoxaline, and 1,8-naphthyridine.

Suitable specific examples of a nitrogen-containing heterocyclic compound suitable as a sulfur-containing compound, and suitable tautomer of the nitrogen-containing heterocyclic compound include the following compounds.

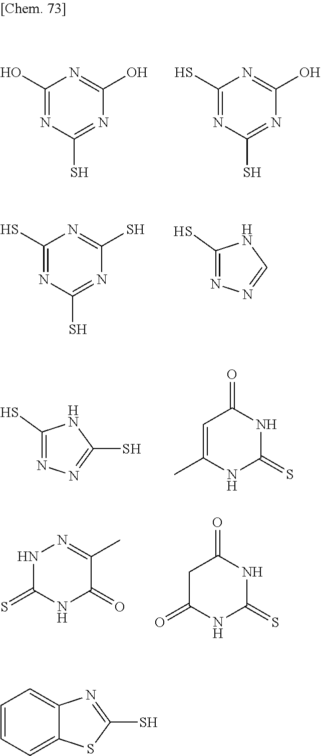

When the photosensitive resin composition includes a sulfur-containing compound (E), the use amount thereof is preferably 0.01 parts by mass or more and 5 parts by mass or less, more preferably 0.02 parts by mass or more and 3 parts by mass or less, and particularly preferably 0.05 parts by mass or more and 2 parts by mass or less with respect to 100 parts by mass that is the total mass of the above resin (B) and the alkali-soluble resin (D).

### <Acid Diffusion Suppressing Agent (F)>

In order to improve the shape of resist pattern used as a template, the post-exposure delay stability of photosensitive resin film and the like, it is preferable that the photosensitive resin composition further contains an acid diffusion suppressing agent (F). The acid diffusion suppressing agent (F) is preferably a nitrogen-containing compound (F1), and an organic carboxylic acid, or an oxo acid of phosphorus or a derivative thereof (F2) may be further included as needed.

### [Nitrogen-Containing Compound (F1)]

Examples of the nitrogen-containing compound (F1) include trimethylamine, diethylamine, triethylamine, di-n-propylamine, tri-n-propylamine, tri-n-pentylamine, tribenzylamine, diethanolamine, triethanolamine, n-hexylamine, n-heptyl amine, n-octyl amine, n-nonyl amine, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, formamide, N-methylformamide, N,N-dimethylformamide, acetamide, N-methylacetamide, N,N-dimethylacetamide, propionamide, benzamide, pyrrolidone, N-methylpyrrolidone, methylurea, 1,1-dimethylurea, 1,3-dimethylurea, 1,1,3,3-tetramethylurea, 1,3-diphenylurea, imidazole, benzimidazole, 4-methylimidazole, 8-oxyquinoline, acridine, purine, pyrrolidine, piperidine, 2,4,6-tri(2-pyridyl)-S-triazine, morpholine, 4-methylmorpholine, piperazine, 1,4-dimethylpiperazine, 1,4-diazabicyclo[2.2.2]octane, pyridine, and the like. These may be used alone, or in combinations of two or more thereof.

Furthermore, commercially available hindered amine compounds such as Adeka Stab LA-52, Adeka Stab LA-57, Adeka Stab LA-63P, Adeka Stab LA-68, Adeka Stab LA-72, Adeka Stab LA-77Y, Adeka Stab LA-77G, Adeka Stab LA-81, Adeka Stab LA-82, Adeka Stab LA-87 (all manufactured by ADEKA), 4-hydroxy-1,2,2,6,6-pentamethylpiperidine derivative, and the like, and pyridine whose 2,6-position has been substituted with a substituent a hydrocarbon group such as 2,6-diphenyl pyridine and 2,6-di-tert-butyl pyridine can be used as the nitrogen-containing compound (F1).

The nitrogen-containing compound (F1) may be used in an amount typically in the range of 0 parts by mass or more and 5 parts by mass or less, and particularly preferably in the range of 0 parts by mass or more and 3 parts by mass or less, with respect to 100 parts by mass of total mass of the above resin (B) and the above alkali-soluble resin (D).

### [Organic Carboxylic Acid or Oxo Acid of Phosphorus or Derivative Thereof (F2)]

Among the organic carboxylic acid, or the oxo acid of phosphorus or the derivative thereof (F2), specific preferred examples of the organic carboxylic acid include malonic acid, citric acid, malic acid, succinic acid, benzoic acid, salicylic acid and the like, and salicylic acid is particularly preferred.

Examples of the oxo acid of phosphorus or derivatives thereof include phosphoric acid and derivatives such as esters thereof such as phosphoric acid, phosphoric acid di-n-butyl ester, and phosphoric acid diphenyl ester; phosphonic acid and derivatives such as esters thereof such as phosphonic acid, phosphonic acid dimethyl ester, phosphonic acid di-n-butyl ester, phenylphosphonic acid, phosphonic acid diphenyl ester, and phosphonic acid dibenzyl ester; and phosphinic acid and derivatives such as esters thereof such as phosphinic acid and phenylphosphinic acid; and the like. Among these, phosphonic acid is particularly preferred. These may be used alone, or in combinations of two or more thereof.

The organic carboxylic acid or oxo acid of phosphorus or derivative thereof (F2) may be used in an amount usually in the range of 0 parts by mass or more and 5 parts by mass or less, and particularly preferably in the range of 0 parts by mass and 3 parts by mass or less, with respect to 100 parts by mass of total mass of the above resin (B) and the above alkali-soluble resin (D).

Moreover, in order to form a salt to allow for stabilization, the organic carboxylic acid, or the oxo acid of phosphorous or the derivative thereof (F2) is preferably used in an amount equivalent to that of the above nitrogen-containing compound (F1).

### <Organic Solvent (S)>

It is preferable that the photosensitive resin composition contains an organic solvent (S). There is no particular limitation on the types of the organic solvent (S) as long as the objects of the present invention are not impaired, and an organic solvent appropriately selected from those conventionally used for positive-type photosensitive resin compositions can be used.

Specific examples of the organic solvent (S) include ketones such as acetone, methyl ethyl ketone, cyclohexanone, methyl isoamyl ketone, and 2-heptanone; polyhydric alcohols and derivatives thereof such as glycols such as ethylene glycol, ethylene glycol monoacetate, diethylene glycol, diethylene glycol monoacetate, propylene glycol, propylene glycol monoacetate, dipropylene glycol, and a monomethyl ether, a monoethyl ether, a monopropyl ether, a monobutyl ether, and a monophenyl ether of dipropylene glycol monoacetate; cyclic ethers such as dioxane; esters such as ethyl formate, methyl lactate, ethyl lactate, methyl acetate, ethyl acetate, butyl acetate, methyl pyruvate, methyl acetoacetate, ethyl acetoacetate, ethyl pyruvate, ethylmethoxy acetate, methyl methoxypropionate, ethyl ethoxypropionate, methyl 2-hydroxypropionate, ethyl 2-hydroxypropionate, ethyl 2-hydroxy-2-methylpropionate, methyl 2-hydroxy-3-methylbutanoate, 3-methoxybutyl acetate, and 3-methyl-3-methoxybutyl acetate; aromatic hydrocarbons such as toluene and xylene; and the like. These may be used alone, or as a mixture of two or more thereof.

There is no particular limitation on the all content of the organic solvent (S) as long as the objects of the present invention are not impaired. In a case where a photosensitive resin composition is used for a thick-film application such that a photosensitive resin layer obtained by the spin coating method and the like has a film thickness of 5 μm or more, the organic solvent (S) is preferably used in a range where the solid content concentration of the photosensitive resin composition is 30% by mass or more and 70% by mass or less.

### <Other Components>

The photosensitive resin composition may further contain a polyvinyl resin for improving plasticity. Specific examples of the polyvinyl resin include polyvinyl chloride, polystyrene, polyhydroxystyrene, polyvinyl acetate, polyvinylbenzoic acid, polyvinyl methyl ether, polyvinyl ethyl ether, polyvinyl alcohol, polyvinyl pyrrolidone, polyvinyl phenol, and copolymers thereof, and the like. The polyvinyl resin is preferably polyvinyl methyl ether in view of lower glass transition temperatures.

Further, the photosensitive resin composition may also contain an adhesive auxiliary agent in order to improve the adhesiveness between a template formed with the photosensitive resin composition and a metal substrate.

Also, the photosensitive resin composition may further contain a surfactant for improving coating characteristics, defoaming characteristics, leveling characteristics, and the like. As the surfactant, for example, a fluorine-based surfactant or a silicone-based surfactant is preferably used. Specific examples of the fluorine-based surfactant include commercially available fluorine-based surfactants such as BM-1000 and BM-1100 (both manufactured by B.M-Chemie Co., Ltd.), Megafac F142D, Megafac F172, Megafac F173 and Megafac F183 (all manufactured by Dainippon Ink And Chemicals, Incorporated), Flolade FC-135, Flolade FC-170C, Flolade FC-430 and Flolade FC-431 (all manufactured by Sumitomo 3M Ltd.), Surflon S-112, Surflon S-113, Surflon S-131, Surflon S-141 and Surflon S-145 (all manufactured by Asahi Glass Co., Ltd.), SH-28PA, SH-190, SH-193, SZ-6032 and SF-8428 (all manufactured by Toray Silicone Co., Ltd.) and the like, but not limited thereto. As the silicone-based surfactant, an unmodified silicone-based surfactant, a polyether modified silicone-based surfactant, a polyester modified silicone-based surfactant, an alkyl modified silicone-based surfactant, an aralkyl modified silicone-based surfactant, a reactive silicone-based surfactant, and the like, can be preferably used. As the silicone-based surfactant, commercially available silicone-based surfactant can be used. Specific examples of the commercially available silicone-based surfactant include Paintad M (manufactured by Dow Corning Toray Co., Ltd.), Topica K1000, Topica K2000, and Topica K5000 (all manufactured by Takachiho Industry Co., Ltd.), XL-121 (polyether modified silicone-based surfactant, manufactured by Clariant Co.), BYK-310 (polyester modified silicone-based surfactant, manufactured by BYK), and the like.

Additionally, in order to finely adjust the solubility in a developing solution, the photosensitive resin composition may further contain an acid, an acid anhydride, or a solvent having a high boiling point.

Specific examples of the acid and acid anhydride include monocarboxylic acids such as acetic acid, propionic acid, n-butyric acid, isobutyric acid, n-valeric acid, isovaleric acid, benzoic acid, and cinnamic acid; hydroxymonocarboxylic acids such as lactic acid, 2-hydroxybutyric acid, 3-hydroxybutyric acid, salicylic acid, m-hydroxybenzoic acid, p-hydroxybenzoic acid, 2-hydroxycinnamic acid, 3-hydroxycinnamic acid, 4-hydroxycinnamic acid, 5-hydroxyisophthalic acid, and syringic acid; polyvalent carboxylic acids such as oxalic acid, succinic acid, glutaric acid, adipic acid, maleic acid, itaconic acid, hexahydrophthalic acid, phthalic acid, isophthalic acid, terephthalic acid, 1,2-cyclohexanedicarboxylic acid, 1,2,4-cyclohexanetricarboxylic acid, butanetetracarboxylic acid, trimellitic acid, pyromellitic acid, cyclopentanetetracarboxylic acid, butanetetracarboxylic acid, and 1,2,5,8-naphthalenetetracarboxylic acid; acid anhydrides such as itaconic anhydride, succinic anhydride, citraconic anhydride, dodecenylsuccinic anhydride, tricarbanilic anhydride, maleic anhydride, hexahydrophthalic anhydride, methyltetrahydrophthalic anhydride, Himic anhydride, 1,2,3,4-butanetetracarboxylic anhydride, cyclopentanetetracarboxylic dianhydride, phthalic anhydride, pyromellitic anhydride, trimellitic anhydride, benzophenonetetracarboxylic anhydride, ethylene glycol bis anhydrous trimellitate, and glycerin tris anhydrous trimellitate; and the like.

Furthermore, specific examples of the solvent having a high boiling point include N-methylformamide, N,N-dimethylformamide, N-methylformanilide, N-methylacetamide, N,N-dimethlyacetamide, N-methylpyrrolidone, dimethyl sulfoxide, benzyl ethyl ether, dihexyl ether, acetonyl acetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and the like.

Moreover, the photosensitive resin composition may further contain a sensitizer for improving the sensitivity. In this specification, the sensitizer is defined as a compound other than the phenolic hydroxyl group-containing low molecular weight compound (C).

As a resin, the photosensitive resin composition contains the resin (B) as an essential component, and a resin other than the resin (B) such as an alkali-soluble resin (D), as required. Note that, in the specification and claims of the present application, the “resin” is a high molecular weight compound having a mass average molecular weight of more than 1,500 and a polymer obtained by polymerization of a monomer compound. The mass average molecular weight is a mass average molecular weight in terms of polystyrene by GPC (gel permeation chromatography). In the photosensitive resin composition, the ratio of the acrylic resin to the total of the resin (B) and a resin other than the resin (B) is 70% by mass or more. The ratio of the acrylic resin to the total of the resin (B) and a resin other than the resin (B) is preferably 80% by mass or more, and more preferably 90% by mass or more. The acrylic resin may be either the resin (B) or the resin other than the resin (B), but it is preferable that the resin (B) contains an acrylic resin. The ratio of the acrylic resin contained in the resin (B) to the resin (B) is preferably 70% by mass or more.

The “resin other than the resin (B)” refers to a resin that is contained in the photosensitive resin and that is a resin other than the resin (B), and for example, the aforementioned alkali-soluble resin (D), a polyvinyl resin as a plasticizer, or the like falls under the “resin other than the resin (B)”. “The total of the resin (B) and a resin other than the resin (B)” refers to a sum of resins contained in the photosensitive resin composition. For example, when the resin contained in the photosensitive resin composition is only the resin (B), “the total of the resin (B) and a resin other than the resin (B)” is only “resin (B)”. In addition, when the resin contained in the photosensitive resin composition is the resin (B) and the above-mentioned alkali-soluble resin (D), “the total of the resin (B) and a resin other than the resin (B)” is a “total of the resin (B) and the alkali-soluble resin (D)”. In addition, when the resin contained in the photosensitive resin composition is the resin (B), the alkali-soluble resin (D) described above, and a resin other than the resin (B) or the alkali-soluble resin (D), “the total of the resin (B) and a resin other than the resin (B)” is a “total of the resin (B), the alkali-soluble resin (D), and the resin other than the resin (B) or the alkali-soluble resin (D)”.

As described above, in the chemically amplified positive-type photosensitive resin composition including an acid generator (A) which generates acid upon exposure to an irradiated active ray or radiation, and a resin (B), whose solubility in alkali increases under an action of acid, when a specific acid generator is included and a ratio of a content of the acrylic resin to a total of the resin (B) and a resin other than the resin (B) is set to a specific range, the photosensitive resin composition is applicable to exposure to h-line, and a resist pattern having excellent plating solution resistance and crack resistance is easily formed using the photosensitive resin composition, as shown in the Examples described below. In addition, the cross-sectional shape of the resist pattern is also good. In this way, the photosensitive resin composition of the present invention is applicable to exposure to h-line and a resist pattern having excellent plating solution resistance and crack resistance can be easily formed using the photosensitive resin composition. Thus, the photosensitive resin composition can be used for manufacturing a template for forming a plated article by embedding a metal on a substrate having a metal surface by a plating treatment.

Since the photosensitive resin composition has the specific composition described above, it is applicable to exposure to h-line. Therefore, the photosensitive resin composition can be preferably applied to the fabrication of a template for forming a plated article on a substrate of a panel level, which is generally larger in area than, for example, a wafer. When the area of a substrate is large, the plating conditions are severe in some cases, as compared with a case where the area of the substrate is small. When the area of a substrate is large, stresses applied to the substrate, template, plated article, etc. tend to increase. Substrates of a panel level often have rectangular main surfaces, to which the photosensitive resin composition is applied. When the panel has a rectangular shape, the stress is more likely to vary than when it is circular. Therefore, when a substrate having a large area or a rectangular shape is used, the photosensitive resin composition is further required to have excellent plating solution resistance and crack resistance. Since the photosensitive resin composition is applicable to exposure to h-line and has excellent plating solution resistance and crack resistance, it can be particularly preferably used as a chemically amplified positive-type photosensitive resin composition which is used for manufacturing a template for forming a plated article by embedding a metal by a plating treatment on a substrate which has a large area or a rectangular shape and which has a metal surface.

### <Method of Preparing Chemically Amplified Positive-Type Photosensitive Resin Composition>

A chemically amplified positive-type photosensitive resin composition is prepared by mixing and stirring the above components by the common method. Machines which can be used for mixing and stirring the above components include dissolvers, homogenizers, 3-roll mills and the like. After uniformly mixing the above components, the resulting mixture may be filtered through a mesh, a membrane filter and the like.

### <<Photosensitive Dry Film>>

A photosensitive dry film includes a substrate film, and a photosensitive resin layer formed on the surface of the substrate film.

As the substrate film, a film having optical transparency is preferable. Specifically, a polyethylene terephthalate (PET) film, a polypropylene (PP) film, a polyethylene (PE) film, and the like. In view of excellent balance between the optical transparency and the breaking strength, a polyethylene terephthalate (PET) film is preferable.

The aforementioned photosensitive resin composition is applied on the substrate film to form a photosensitive resin layer, and thereby a photosensitive dry film is manufactured. When the photosensitive resin layer is formed on the substrate film, a photosensitive resin composition is applied and dried on the substrate film using an applicator, a bar coater, a wire bar coater, a roller coater, a curtain flow coater, and the like, so that a film thickness after drying is preferably 0.5 μm or more and 300 μm or less, more preferably 1 μm or more and 300 μm or less, and particularly preferably 3 μm or more and 100 μm or less.

The photosensitive dry film may have a protective film on the photosensitive resin layer. Examples of the protective film include a polyethylene terephthalate (PET) film, a polypropylene (PP) film, a polyethylene (PE) film, and the like.

### <<Method of Producing Patterned Resist Film, and Substrate With Template>>

There is no particular limitation on a method of forming a patterned resist film on a substrate using the photosensitive resin composition described above. Such a patterned resist film is used as a template for forming a plated article.

A suitable method includes a manufacturing method of a patterned resist film, the method including:
laminating a photosensitive resin layer on a substrate, the layer being formed from a photosensitive resin composition;
exposing the photosensitive resin layer through irradiation with an active ray or radiation in a position-selective manner; and
developing the exposed photosensitive resin layer.
A method of manufacturing a substrate with a template for forming a plated article is the same method as the method of manufacturing a patterned resist film except that the method includes laminating a photosensitive resin layer on a metal surface of the substrate having a metal surface, and a template for forming a plated article is produced by developing in the developing step.

As the substrate on which the photosensitive resin layer is laminated, a substrate having a metal surface is used. As metal species constituting the metal surface, copper and aluminum are preferred, and copper is more preferred.

The photosensitive resin layer is laminated on the substrate, for example, as follows. In other words, a liquid photosensitive resin composition is coated onto a substrate, and the coating is heated to remove the solvent and thus to form a photosensitive resin layer having a desired thickness. The thickness of the photosensitive resin layer is not particularly limited as long as it is possible to form a resist pattern serving as a template which has a desired thickness. The thickness of the photosensitive resin layer is not particularly limited, but is preferably 0.5 μm or more, more preferably 0.5 μm or more and 300 μm or less, and particularly preferably 1 μm or more and 150 μm or less, and most preferably 3 μm or more and 100 μm or less.

As a method of applying a photosensitive resin composition onto a substrate, methods such as the spin coating method, the slit coat method, the roll coat method, the screen printing method and the applicator method can be employed. Pre-baking is preferably performed on a photosensitive resin layer. The conditions of pre-baking may differ depending on the components in a photosensitive resin composition, the blending ratio, the thickness of a coating film and the like. They are usually about 2 minutes or more and 120 minutes or less at 70° C. or more and 200° C. or less, and preferably 80° C. or more and 150° C. or less.

The photosensitive resin layer formed as described above is selectively irradiated (exposed) with an active ray or radiation, for example, an ultraviolet radiation or visible light with a wavelength of 300 nm or more and 500 nm or less through a mask having a predetermined pattern. The active ray or radiation to be irradiated preferably includes light with a wavelength of 405 nm (h-line), and examples thereof include broadband light of a mercury lamp including an h-line or a band passed h-line single light, and a gh-line. By using the above-mentioned chemically amplified positive-type photosensitive resin composition including at least one selected from the compounds represented by the formula (a1-i) or (a1-ii), the compounds represented by the formula (a2-i) or (a2-ii), and the compounds represented by the formula (a3-i) or (a3-ii) as acid generator (A), and a resin (B) whose solubility in alkali increases under an action of acid, and including an acrylic resin in a content of 70% by mass or more with respect to the total of the resin (B) and a resin other than the resin (B), it is possible to apply h-line that is applicable to a panel level package having a large area, thereby making it possible to form a resist pattern having excellent plating solution resistance and crack resistance.

Low pressure mercury lamps, high pressure mercury lamps, super high pressure mercury lamps, metal halide lamps, argon gas lasers, etc. can be used for the light source of the radiation. The radiation may include microwaves, infrared rays, visible lights, ultraviolet rays, X-rays, γ-rays, electron beams, proton beams, neutron beams, ion beams, etc. The irradiation dose of the radiation may vary depending on the constituent of the photosensitive resin composition, the film thickness of the photosensitive resin layer, and the like. For example, when an ultra-high-pressure mercury lamp is used, the dose may be 100 mJ/cm² or more and 10,000 mJ/cm² or less. The radiation includes a light ray to activate the acid generator (A) in order to generate an acid.

After the exposure, the diffusion of acid is promoted by heating the photosensitive resin layer using a known method to change the alkali solubility of the photosensitive resin layer at an exposed portion in the photosensitive resin film.

Subsequently, the exposed photosensitive resin layer is developed in accordance with a conventionally known method, and an unnecessary portion is dissolved and removed to form a predetermined resist pattern or a template for forming a plated article. At this time, as the developing solution, an alkaline aqueous solution is used.

As the developing solution, an aqueous solution of an alkali such as, for example, sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5,4,0]-7-undecene or 1,5-diazabicyclo[4,3,0]-5-nonane can be used. Also, an aqueous solution obtained by adding an adequate amount of a water-soluble organic solvent such as methanol or ethanol, or a surfactant to the above aqueous solution of the alkali can be used as the developing solution.

The developing time may vary depending on the constituent of the photosensitive resin composition, the film thickness of the photosensitive resin layer, and the like. Usually, the developing time is 1 minute or more and 30 minutes or less. The method of the development may be any one of a liquid-filling method, a dipping method, a paddle method, a spray developing method, and the like.

After development, it is washed with running water for 30 seconds or more and 90 seconds or less, and then dried with an air gun, an oven, and the like. In this manner, a resist pattern, which has been patterned in a predetermined pattern, is formed on a metal surface of a substrate having a metal surface. Also, in this manner, it is possible to manufacture a substrate with a template having a resist pattern serving as a template, on a metal surface of a substrate having a metal surface.

The film thickness of the resist pattern (patterned resist film) formed using the photosensitive resin composition is not particularly limited, and the photosensitive resin composition can be applied to both a thick film and a thin film. The photosensitive resin composition is preferably used for forming a resist pattern of a thick film. Specifically, the film thickness of the resist pattern formed using the photosensitive resin composition is preferably 0.5 μm or more, more preferably 0.5 μm or more and 300 μm or less, more preferably 0.5 μm or more and 200 μm or less, and particularly preferably 0.5 μm or more and 150 μm or less. The upper limit value of the film thickness may be, for example, 100 μm or less. The lower limit value of the film thickness may be, for example, 1 μm or more and may be 3 μm or more.

### <<Method of Manufacturing Plated Article>>

A conductor such as a metal may be embedded, by plating, into a nonresist portion (a portion removed with a developing solution) in the template in the substrate with a template formed by the above method to form a plated article, for example, like a contacting terminal such as a bump and a metal post, or Cu rewiring. Note here that there is no particular limitation on the method of plate processing, and various conventionally known methods can be used. As a plating liquid, in particular, a solder plating liquid, a copper plating liquid, a gold plating liquid, and a nickel plating liquid are suitably used. Finally, the remaining template is removed with a stripping liquid and the like in accordance with a conventional method. The resist pattern obtained by the above-mentioned method has excellent plating solution resistance, and therefore, change of the resist pattern before and after the plating process can be suppressed. Therefore, a plated article having a desired shape can be obtained.

When the plated article is manufactured, it may be preferable that an exposed metal surface in a non-patterned portion of a resist pattern serving as a template for forming plated article is subjected to ashing treatment. Specific examples include case where a pattern formed of a photosensitive resin composition including a sulfur-containing compound (E) is used as a template to form a plated article. In this case, adhesiveness of the plated article to a metal surface may be easily damaged. This problem is remarkable in a case where sulfur-containing compound (E) represented by the above-mentioned formula (e1), and the sulfur-containing compound (E) represented by the formula (e4). However, the above-mentioned ashing treatment is carried out, even when a pattern formed using a photosensitive resin composition including a sulfur-containing compound (E) is used as a template, a plated article favorably adhering to the metal surface is easily formed. Note here that in a case where a compound including a nitrogen-containing aromatic heterocycle substituted with a mercapto group is used as a sulfur-containing compound (E), the problem of adhesiveness of a plated article hardly occurs or occurs slightly. Therefore, in a case where a compound including a nitrogen-containing aromatic heterocycle substituted with a mercapto group is used as a sulfur-containing compound (E), a plated article having excellent adhesiveness with respect to the metal surface is easily formed without carrying out ashing treatment.

The ashing treatment is not particularly limited as long as long as it does not damage a resist pattern serving as a template for forming the plated article to such an extent that the plated article having a desired shape cannot be formed. Preferable ashing treatment methods include a method using oxygen plasma. For ashing with respect to the metal surface of the substrate using oxygen plasma, an oxygen plasma is generated using a known oxygen plasma generator, and the metal surface on the substrate is irradiated with the oxygen plasma.

Various gases which have conventionally been used for plasma treatment together with oxygen can be mixed into gas to be used for generating oxygen plasma within a range where the objects of the present invention are not impaired. Examples of such gas include nitrogen gas, hydrogen gas, CF₄ gas, and the like. Conditions of ashing using oxygen plasma are not particularly limited within a range where the objects of the present invention are not impaired, but treatment time is, for example, in a range of 10 seconds or more and 20 minutes or less, preferably in a range of 20 seconds or more and 18 minutes or less, and more preferably in a range of 30 seconds or more and 15 minutes or less. By setting the treatment time by oxygen plasma to the above range, an effect of improving the adhesiveness of the plated article can be easily achieved without changing a shape of the resist pattern.

According to the above method, since h-line applicable to a panel level package having a large area is applied, and a resist pattern having excellent plating solution resistance and crack resistance can be used for a template for forming a plated article, a plated article can be manufactured not only in a wafer level but also in a panel level having a large area. Further, not only when a substrate having a circular shape is used but also when a substrate in which a main surface has a shape other than the circular shape, such as a rectangular shape, is used, it is possible to manufacture a plated article having a desired shape.

### EXAMPLES

The present invention will be described in more detail below by way of Examples, but the present invention is not limited to these Examples.

### Preparation Example 1

### (Synthesis of Mercapto Compound E1)

In Preparation Example 1, a mercapto compound T2 having the following structure was synthesized as sulfur-containing compound (E).

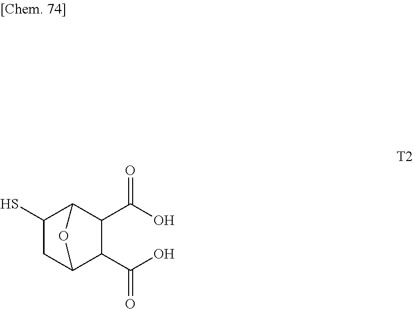 [SMILES: O=C(O)C1C2CC(S)C(O2)C1C(=O)O]

In a flask, 15.00 g of 7-oxanorborna-5-ene-2,3-dicarboxylic anhydride and 150.00 g of tetrahydrofuran were added, followed by stirring. Subsequently, 7.64 g of thioacetic acid (AcSH) was added in a flask, followed by stirring at room temperature for 3.5 hours. Then, the reaction solution was concentrated to obtain 22.11 g of 5-acetyl thio-7-oxanorbornane-2,3-dicarboxylic anhydride. In a flask, 22.11 g of 5-acetylthio-7-oxanorbornane-2,3-dicarboxylic anhydride and 30.11 g of an aqueous sodium hydroxide solution having the concentration of 10% by mass were added, and then contents in the flask were stirred at room temperature for 2 hours. Subsequently, hydrochloric acid (80.00 g) having the concentration of 20% by mass was added in the flask to acidify the reaction solution. Then, extraction with 200 g of ethyl acetate was performed four times to obtain an extraction liquid including a mercapto compound T2. The extraction liquid was concentrated and the collected residue was dissolved by adding 25.11 g of tetrahydrofuran (THF). Heptane was added dropwise to the obtained THF solution to precipitate the mercapto compound T2, and the precipitated mercapto compound T2 was collected by filtration. The measurement results of ¹H-NMR of the mercapto compound T2 are shown below.

¹H-NMR (DMSO-d6): δ12.10 (s, 2H), 4.72 (d, 1H), 4.43 (s, 1H), 3.10 (t, 1H), 3.01 (d, 1H), 2.85 (d, 1H), 2.75 (d, 1H), 2.10 (t, 1H), 1.40 (m, 1H)

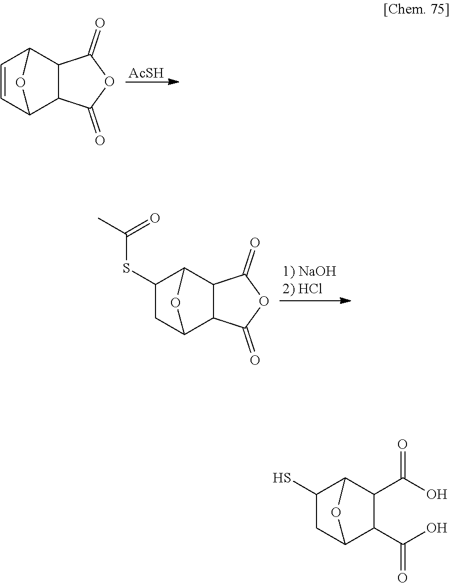 [SMILES: "AcSH" ; O=C1OC(=O)C2C3C=CC(O3)C12 ; CC(=O)SC1CC2OC1C1C(=O)OC(=O)C21 ; O=C(O)C1C2CC(S)C(O2)C1C(=O)O]

### Examples 1 to 19, and Comparative Examples 1 to 5

In Examples 1 to 19, and Comparative Examples 1 to 5, compounds PAG1 and PAG2 of the following formula were used as the acid generator (A).

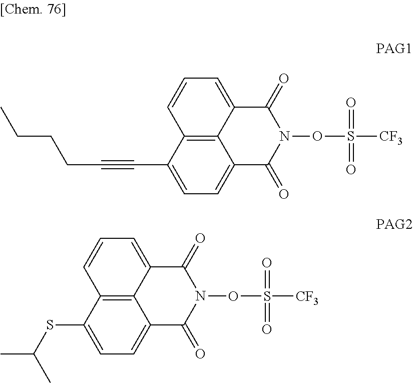 [SMILES: CCCCC#Cc1ccc2c3c(cccc13)C(=O)N(OS(=O)(=O)C(F)(F)F)C2=O ; CC(C)Sc1ccc2c3c(cccc13)C(=O)N(OS(=O)(=O)C(F)(F)F)C2=O]

In Examples 1 to 19 and Comparative Examples 1 to 5, the following Acryl-1 to Acryl-11, PHS-1, and PHS-2 were used as the resin (resin (B)) whose solubility in alkali increases under an action of acid. The number at the lower right of the parentheses in each constituent unit in the following structural formulae represents the content (mol %) of the constituent unit in each resin. Since Acryl-1 to Acryl-11 contain 70 mol % or more of the acrylic constituent unit which is a constituent unit derived from (meth)acrylic acid or (meth)acrylic acid derivative, they are acrylic resins (B3). Further, PHS-1 and PHS-2 are polyhydroxystyrene resins (B2). The mass average molecular weight Mw of each of Acryl-1 to Acryl-7 is 40,000. Each of Acryl-8 to Acryl-11 is a resin having the same constituent unit and composition ratio as Acryl-1 but being different in mass average molecular weight: the mass average molecular weight of Acryl-8 is 10,000, the mass average molecular weight of Acryl-9 is 20,000, the mass average molecular weight of Acryl-10 is 80,000, and the mass average molecular weight of Acryl-11 is 120,000. Note that the dispersivity (Mw/Mn) was 2.6 in all of Acryl-1 to Acryl-11. Further, the mass average molecular weight Mw of PHS-1 was 10,000, and the dispersivity (Mw/Mn) was 2.1. The mass-average molecular weight Mw of PHS-2 was 11,500, and the dispersivity (Mw/Mn) was 1.08.

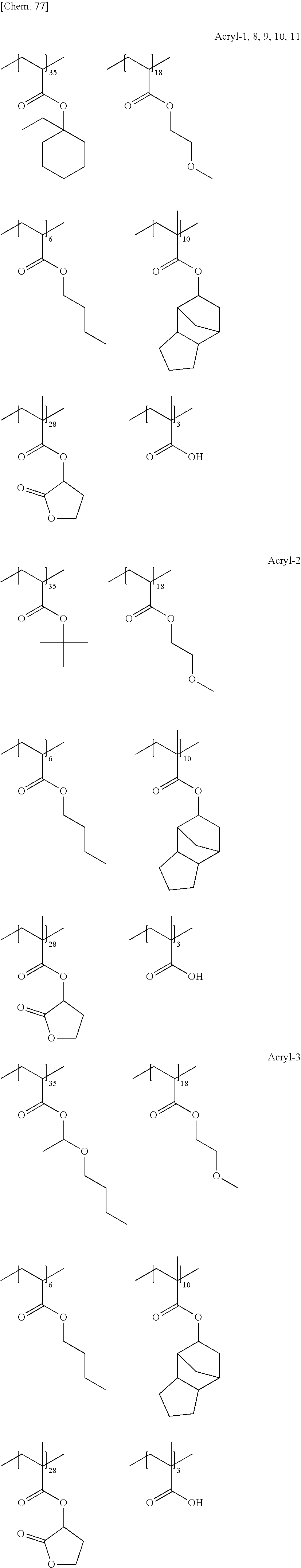

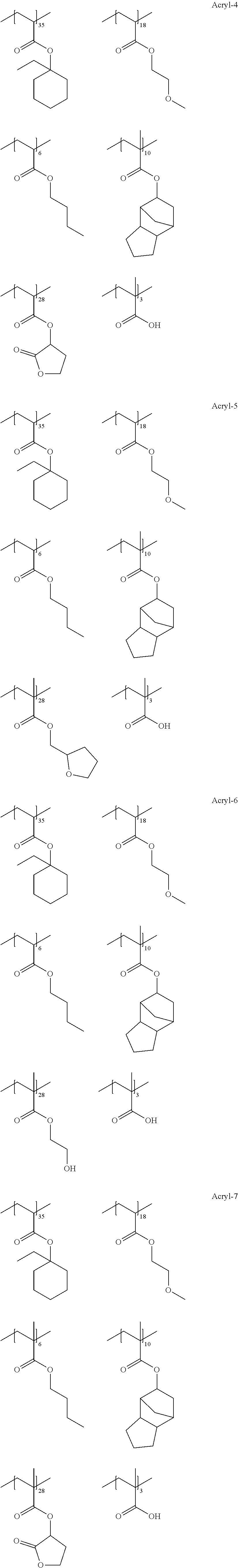

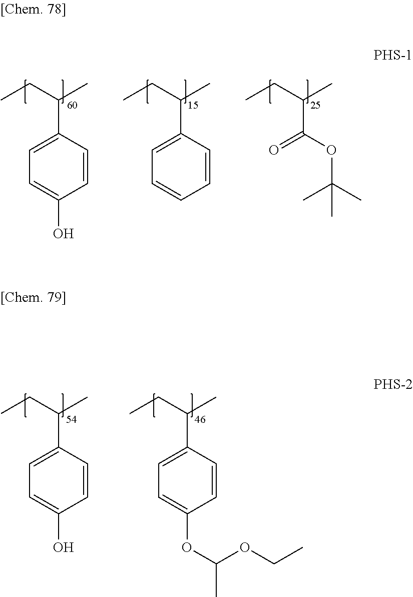

As the phenolic hydroxyl group-containing low molecular weight compound (C), the following compound C1 was used.

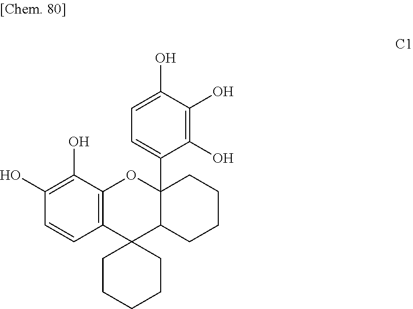 [SMILES: Oc1ccc(C23CCCCC2C2(CCCCC2)c2ccc(O)c(O)c2O3)c(O)c1O]

As the alkali-soluble resin (D), the following PHS-3 (polyhydroxystyrene resin) and Novolak-1 (novolac resin (homo-condensate of m-cresol)) were used. The number at the lower right of the parentheses in each constituent unit in the following structural formulae represents the content (mol %) of the constituent unit in each resin. PHS-3 has a mass average molecular weight (Mw) of 2,500, and the dispersivity (Mw/Mn) of 2.4. The resin Novolak-1 has a mass average molecular weight (Mw) of 8000.

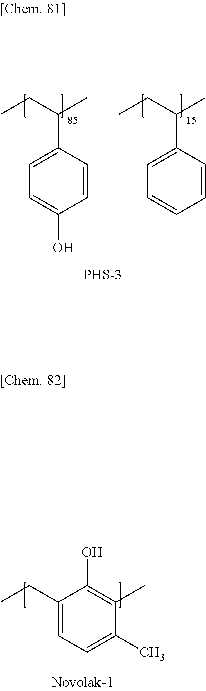

As the sulfur-containing compound (E), the following sulfur-containing compounds T1 to T3 were used.

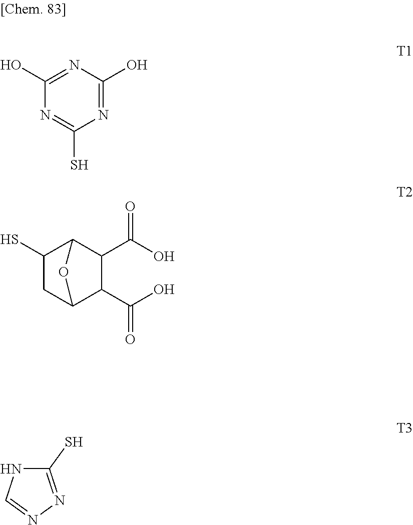 [SMILES: Oc1nc(O)nc(S)n1 ; O=C(O)C1C2CC(S)C(O2)C1C(=O)O ; Sc1nnc[nH]1]

As the acid diffusion suppressing agent (F), the following Amine-1 to Amine-3 were used.

Amine-1: Adeka Stab LA-63P (manufactured by ADEKA Corporation)
Amine-2: diphenylpyridine
Amine-3: triphenylpyridine

The acid generator (A), the resin (B), the phenolic hydroxyl group-containing low molecular weight compound (C), the alkali-soluble resin (D), the sulfur-containing compound (E), and the acid diffusion suppressing agent (F) in types and amounts shown in each of Tables 1 and 2, and a surfactant (BYK310, manufactured by BYK) were dissolved in 3-methoxybutyl acetate (MA) to obtain photosensitive resin compositions of the Examples and the Comparative Examples. Note here that the surfactant (BYK310, manufactured by BYK) was added such that the amount thereof was 0.05 parts by mass with respect to the total amount of the resin (B) and the alkali-soluble resin (D). Each of the photosensitive resin compositions of Examples 1 to 18 and Comparative Examples 1 to 5 was prepared such that the solid concentration was 40% by mass. The photosensitive resin composition of Example 19 was prepared such that the solid concentration was 53% by mass. The ratio of the acrylic resin to the total of the resin (B) and a resin other than the resin (B) was described in the column of “ratio of the acrylic resin (% by mass)” in Tables 1 and 2.

Using the obtained photosensitive resin compositions, resist patterns were formed according to the following method, and the shapes of the resist patterns, the crack resistance, and the shapes after immersion in a copper sulfate plating solution were evaluated. Note here that in Examples 1 to 18 and Comparative Examples 1 to 5, evaluation at a film thickness of 7 μm was carried out. On the other hand, in Example 19, evaluation at a film thickness of 55 μm was carried out. These evaluation results are described in Tables 1 and 2.

### (Formation of Resist Pattern for Evaluation at a Film Thickness of 7 μm)

A substrate provided with a copper layer by sputtering on a surface of a glass substrate having a diameter of 500 mm was prepared, and the photosensitive resin compositions of Examples 1 to 18 and Comparative Examples 1 to 5 were each applied on the copper layer of the substrate to form photosensitive resin layers each having a thickness of 7 μm. Then, the photosensitive resin layers were pre-baked at 130° C. for 5 minutes. After pre-baking, using a mask having a line-and-space pattern having a line-width of 2 μm and a space-width of 2 μm, and an exposure device Prisma GHI5452 (manufactured by Ultratech Inc.) equipped with an i-line cut filter, pattern exposure was performed with a gh line at an exposure dose greater by 1.2 times than the minimum exposure dose capable of forming a pattern having a predetermined size until a 2.5 μm space was formed. Subsequently, the substrate was placed on a hot plate and post-exposure baking (PEB) was performed at 90° C. for 1.5 minutes. Then, an aqueous 2.38% by weight solution of tetramethylammonium hydroxide (developing solution, NMD-3, manufactured by Tokyo Ohka Kogyo Co., Ltd.) was added dropwise to the exposed photosensitive resin layer, which was allowed to stand at 23° C. for 30 seconds. This operation was repeated twice in total. Subsequently, the surface of the resist pattern was washed (rinsed) with running water, and blown with nitrogen to obtain a resist pattern.

### (Formation of a Resist Pattern for Evaluation at a Film Thickness of 55 μm)

A substrate provided with a copper layer by sputtering on a surface of a glass substrate having a diameter of 500 mm was prepared, and the photosensitive resin composition of Example 19 was applied on the copper layer of the substrate to form a photosensitive resin layer having a thickness of 55 μm. Then, the photosensitive resin layer was pre-baked at 100° C. for 5 minutes. After the pre-baking, using a mask having a square pattern capable of forming rectangular openings having a size of 30 μm×30 μm, and an exposure device Prisma GHI5452 (manufactured by Ultratech Inc.) equipped with an i-line cut filter, pattern exposure was performed with gh-line at an exposure dose greater by 1.2 times than the minimum exposure dose capable of forming a pattern having a predetermined size until rectangular openings having a size of 35 μm×35 μm was formed. Subsequently, the substrate was placed on a hot plate and post-exposure baking (PEB) was performed at 100° C. for 3 minutes. Then, an aqueous 2.38% by weight solution of tetramethylammonium hydroxide (developing solution, NMD-3, manufactured by Tokyo Ohka Kogyo Co., Ltd.) was added dropwise to the exposed photosensitive resin layer, which was allowed to stand at 23° C. for 60 seconds. This operation was repeated four times in total. Subsequently, the surface of the resist pattern was washed (rinsed) with running water, and blown with nitrogen to obtain a resist pattern.

### [Evaluation for Shape of Resist Pattern]

A cross-sectional shape of the resist pattern was observed under scanning electron microscope, and the cross-sectional shape of the pattern was evaluated. Specifically, assuming that a width of the resist pattern on a surface (top) opposite to the surface of the resist pattern in contact with the substrate is Wt, and a pattern width in the intermediate portion in the thickness direction of a cross section of the resist pattern is Wm, when Wm is within ±10% of Wt, the shape of the resist pattern was evaluated as O, and when Wm was outside the range of ±10% of Wt, the shape of the resist pattern was evaluated as X. In all of the Examples, the pattern width in the intermediate portion in the thickness direction of a cross section of the resist pattern was substantially the same as the width of the face (bottom) in contact with the substrate of the resist pattern cross section.

### [Evaluation for Crack Resistance of Resist Pattern]

A substrate on which a resist pattern was formed was subjected to a heat shock testing using a thermal shock chamber (Espec Corporation TSA-103EL), based on one cycle including at 60° C. for 5 minutes and at −5° C. for 5 minutes. The resist pattern was observed at 10 locations at 10 times by an optical microscope. A resist pattern in which a crack was observed in the first cycle was evaluated as X, a resist pattern in which a crack was observed for the first time in the second cycle was evaluated as Δ, a resist pattern in which a crack was observed for the first time in the third cycle was evaluated as O, and a resist pattern in which no cracks were observed until the fourth cycle was evaluated as ⊚.

### [Evaluation of Plating Solution Resistance of Resist Pattern]

A resist pattern was immersed in a copper sulfate plating solution (UTB-W30 manufactured by Ishihara Chemical Co., Ltd.) at 28° C., with the resist pattern adhering to the substrate. The cross-sectional shape of the resist pattern after immersing was observed by a scanning electron microscope to evaluate the cross-sectional shape of the pattern. Specifically, a resist pattern in which no shape change was observed, when comparing before and after immersion for 30 minutes, was evaluated as ⊚; a resist pattern in which no shape change was observed, when comparing before and after immersion for 15 minutes, but the resist pattern was dissolved in the plating solution after immersion for 30 minutes was evaluated as O; and a resist pattern which was dissolved in the plating solution after immersion for 15 minutes was evaluated as X.

TABLE 1

| | | | Phenolic hydroxyl | | | | | | |
|---|---|---|---|---|---|---|---|---|---|
| | Acid | Resin (B) and | group-containing | Sulfur- | Acid diffusion | Ratio of | | | |
| | generator | alkali-soluble | low molecular weight | containing | suppressing | acrylic | Evaluation | | |
| | (A) | resin (D) | compound (C) | compound (E) | agent (F) | resin | Cross- | | Plating |
| | Types/part | Types/part | Types/part | Types/part | Types/part | (% by | sectional | Crack | solution |
| | by mass | by mass | by mass | by mass | by mass | mass) | shape | resistance | resistance |
| Example 1 | PAG1/0.3 | Acryl-1/100 | C1/5 | T1/0.05 | Amine-1/0.05 | 100 | ◯ | ⊚ | ⊚ |
| Example 2 | PAG2/0.3 | | C1/5 | | | 100 | ◯ | ⊚ | ⊚ |
| Example 3 | | | C1/5 | | Amine-2/0.05 | 100 | ◯ | ⊚ | ⊚ |
| Example 4 | | | C1/5 | T2/0.05 | Amine-3/0.05 | 100 | ◯ | ⊚ | ⊚ |
| Example 5 | | | C1/5 | T3/0.05 | | 100 | ◯ | ⊚ | ⊚ |
| Example 6 | | Acryl-2/100 | C1/5 | | | 100 | ◯ | ⊚ | ⊚ |
| Example 7 | | Acryl-3/100 | C1/0 | | | 100 | ◯ | ⊚ | ⊚ |
| Example 8 | | Acryl-4/100 | C1/5 | | | 100 | ◯ | ⊚ | ⊚ |
| Example 9 | | Acryl-5/100 | C1/5 | | | 100 | ◯ | ⊚ | ⊚ |
| Example 10 | | Acryl-6/100 | C1/5 | | | 100 | ◯ | ⊚ | ⊚ |
| Example 11 | | Acryl-7/100 | C1/5 | | | 100 | ◯ | ⊚ | ⊚ |
| Example 12 | | Acryl-8/100 | C1/5 | | | 100 | ◯ | Δ | ⊚ |
| Example 13 | | Acryl-9/100 | C1/5 | | | 100 | ◯ | ◯ | ⊚ |
| Example 14 | | Acryl-10/100 | C1/5 | | | 100 | ◯ | ⊚ | ⊚ |
| Example 15 | | Acryl-11/100 | C1/5 | | | 100 | ◯ | ⊚ | ⊚ |

TABLE 2

| | | | Phenolic hydroxyl | | | | | | |
|---|---|---|---|---|---|---|---|---|---|
| | Acid | Resin (B) and | group-containing | Sulfur- | Acid diffusion | Ratio of | | | |
| | generator | alkali-soluble | low molecular weight | containing | suppressing | acrylic | Evaluation | | |
| | (A) | resin (D) | compound (C) | compound (E) | agent (F) | resin | Cross- | | Plating |
| | Types/part | Types/part | Types/part | Types/part | Types/part | (& by | sectional | Crack | solution |
| | by mass | by mass | by mass | by mass | by mass | mass) | shape | resistance | resistance |
| Example 16 | PAG2/0.3 | Acryl-1/80 | C1/0 | T3/0.05 | Amine-2/0.05 | 80 | ◯ | ◯ | ◯ |
| | | PHS-1/20 | | | Amine-3/0.05 | | | | |
| Example 17 | | Acryl-1/80 | C1/0 | | | 80 | ◯ | ◯ | ◯ |
| | | PHS-3/20 | | | | | | | |
| Example 18 | | Acryl-1/80 | C1/0 | | | 80 | ◯ | ◯ | ◯ |
| | | Novolak-1/20 | | | | | | | |
| Example 19 | PAG1/0.3 | Acryl-1/100 | C1/5 | T1/0.05 | Amine-1/0.05 | 100 | ◯ | ⊚ | ⊚ |
| Comparative | PAG2/0.3 | Acryl-1/60 | C1/0 | T3/0.05 | Amine-2/0.05 | 60 | ◯ | Δ | X |
| Example 1 | | PHS-3/40 | | | Amine-3/0.05 | | | | |
| Comparative | | Acryl-1/40 | C1/0 | | | 40 | ◯ | X | X |
| Example 2 | | PHS-1/20 | | | | | | | |
| | | Novolak-1/40 | | | | | | | |
| Comparative | | Acryl-1/60 | C1/0 | | | 60 | ◯ | Δ | X |
| Example 3 | | PHS-1/40 | | | | | | | |
| Comparative | | Acryl-1/50 | C1/0 | | | 50 | ◯ | X | X |
| Example 6 | | Novolak-1/50 | | | | | | | |
| Comparative | | PHS-2/100 | C1/0 | | | 0 | ◯ | X | X |
| Example 5 | | | | | | | | | |

According to Examples 1 to 19, it can be seen that a positive-type photosensitive resin composition including: at least one selected from the compounds represented by the formula (a1-i) or (a1-ii), the compounds represented by the formula (a2-i) or (a2-ii), and the compounds represented by the formula (a3-i) or (a3-ii) as the acid generator (A), which generates acid upon exposure to an irradiated active ray or radiation, and a resin (B), whose solubility in alkali increases under action of acid, in which the ratio of the acrylic resin to the total of the resin (B) and a resin other than the resin (B) is 70% by mass or more, can form a resist pattern by exposure to h-line, and the formed resist pattern has excellent plating liquid resistance and crack resistance. Further, it can be seen that the cross-sectional shape of the resist pattern is good.

On the other hand, according to Comparative Examples 1 to 5, it can be understood that when the positive photosensitive resin composition contains the acid generator (A) represented by formula (a1-i) or (a2-i), but the ratio of the acrylic resin is less than 70% by mass, the plating solution resistance and the crack resistance of the resist pattern were inferior to those of Examples 1 to 19.

### Reference Examples

### Examples

In Reference Examples 1 to 21, Compound PAG1 and PAG2 of the following formula were used as the acid generator (A).

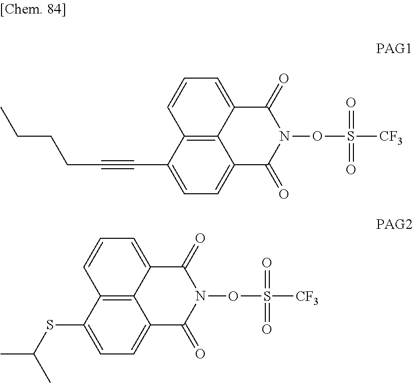 [SMILES: CCCCC#Cc1ccc2c3c(cccc13)C(=O)N(OS(=O)(=O)C(F)(F)F)C2=O ; CC(C)Sc1ccc2c3c(cccc13)C(=O)N(OS(=O)(=O)C(F)(F)F)C2=O]

In Reference Examples 1 to 21, the following Resin-A1 to Resin-A4 were used as a resin whose solubility in alkali increases under an action of acid (the resin (B)). The number at the lower right of the parentheses in each constituent unit in the following structural formula represents the content (% by mass) of the constituent unit in each resin. The resin Resin-A1 has a mass average molecular weight Mw of 80,000, and dispersivity (Mw/Mn) of 2.6. The resin Resin-A2 has a mass average molecular weight Mw of 80,000, and dispersivity (Mw/Mn) of 2.6. The resin Resin-A3 has a mass average molecular weight Mw of 98,000. The resin Resin-A4 has a mass average molecular weight Mw of 11,500, and dispersivity (Mw/Mn) of 1.08.

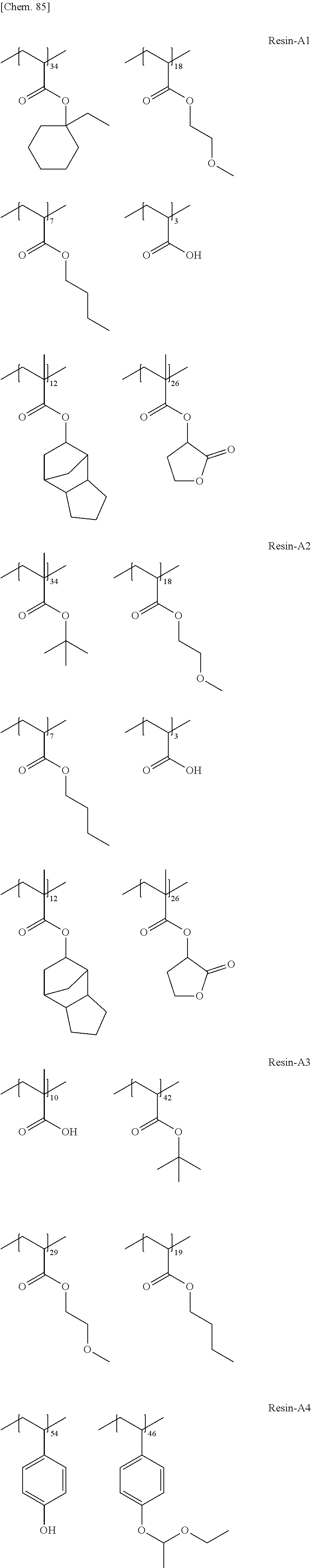

As the phenolic hydroxyl group-containing low molecular weight compound (C), the following compound C1 was used.

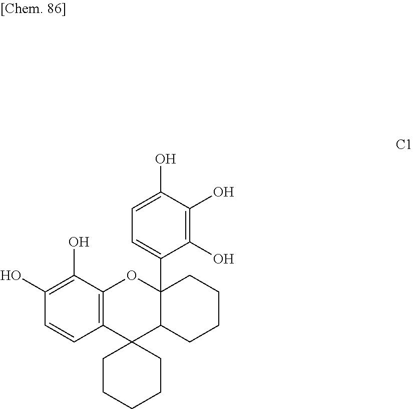 [SMILES: Oc1ccc(C23CCCCC2C2(CCCCC2)c2ccc(O)c(O)c2O3)c(O)c1O]

As the alkali-soluble resin (D), the following Resin-B (polyhydroxystyrene resin), and Resin-C (novolac resin (homo-condensate of m-cresol) were used. The number at the lower right of the parentheses in each constituent unit in the following structural formulae represents the content (% by mass) of the constituent unit in each resin. The resin Resin-B has a mass average molecular weight (Mw) of 2,500, and the dispersivity (Mw/Mn) of 2.4. The resin Resin-C has a mass average molecular weight (Mw) of 8000.

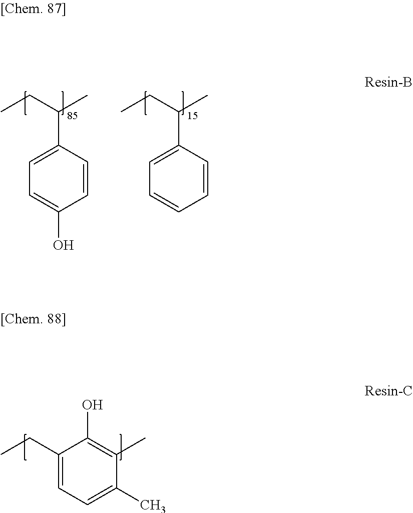

As the sulfur-containing compound (E), the following sulfur-containing compounds T1 to T3 were used.

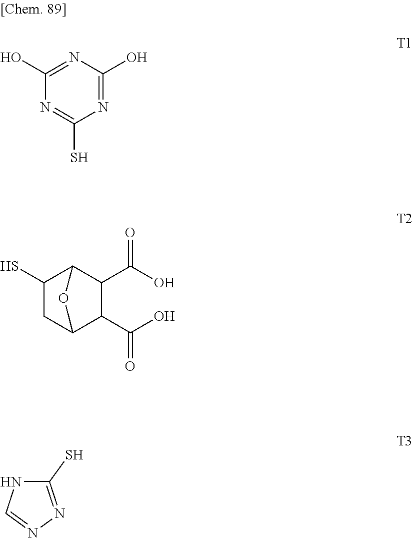 [SMILES: Oc1nc(O)nc(S)n1 ; O=C(O)C1C2CC(S)C(O2)C1C(=O)O ; Sc1nnc[nH]1]

As the acid diffusion suppressing agent (F), the following Amine-1 to Amine-3 were used.

Amine-1: Adeka Stab LA-63P (manufactured by ADEKA Corporation)
Amine-2: diphenylpyridine
Amine-3: triphenylpyridine

The acid generator (A), the resin (B), the phenolic hydroxyl group-containing low molecular weight compound (C), the alkali-soluble resin (D), the sulfur-containing compound (E), and the acid diffusion suppressing agent (F) in types and amounts shown in each of Tables 3 and 4, and a surfactant (BYK310, manufactured by BYK) were dissolved in a mixed solvent of 3-methoxybutyl acetate (MA) and propylene glycol monomethyl ether acetate (PM) (MA/PM=6/4 (mass ratio)) to obtain photosensitive resin compositions of the Reference Examples. Note here that the surfactant (BYK310, manufactured by BYK) was added such that the amount thereof was 0.05 parts by mass with respect to the total amount of the resin (B) and the phenolic hydroxyl group-containing low molecular weight compound (C). Photosensitive resin compositions of Reference Examples 1 to 9 used in evaluation at a film thickness of 55 μm mentioned below were prepared such that the solid content concentration was 50% by mass. Photosensitive resin compositions of Reference Examples 10 to 21 used in evaluation at a film thickness of 7 μm were prepared such that the solid content concentration was 40% by mass.

Using the obtained photosensitive resin composition, according to the following methods, shapes after the composition had been immersed in a copper sulfate plating liquid was evaluated. Note here that in Reference Examples 1 to 9, evaluation at a film thickness of 55 μm was carried out. On the other hand, in Reference Examples 10 to 21, evaluation at a film thickness of 7 μm was carried out. These evaluation results are shown in Tables 3 and 4.

### [Shape Evaluation]

### (Evaluation at Film Thickness of 55 μm)

A substrate provided with a copper layer by sputtering on a surface of a glass substrate having a diameter of 500 mm was prepared, and the photosensitive resin compositions of the Reference Examples were each applied on the copper layer of the substrate to form photosensitive resin layers each having a thickness of 55 μm. Then, the photosensitive resin layers were pre-baked at 100° C. for 5 minutes. After the pre-baking, using a mask having a square pattern capable of forming rectangular opening having a size of 30 μm×30 μm, and an exposure device Prisma GHI5452 (manufactured by Ultratech Inc.) equipped with an i-line cut filter, pattern exposure was performed with gh-line at an exposure dose greater by 1.2 times than the minimum exposure dose capable of forming a pattern having a predetermined size until rectangular opening having a size of 35 μm×35 μm was formed. Subsequently, the substrate was placed on a hot plate and post-exposure baking (PEB) was performed at 100° C. for 3 minutes. Then, an aqueous 2.38% by weight solution of tetramethylammonium hydroxide (developing solution, NMD-3, manufactured by Tokyo Ohka Kogyo Co., Ltd.) was added dropwise to the exposed photosensitive resin layer, and allowed to stand at 23° C. for 60 seconds. This operation was repeated four times in total. Subsequently, the surface of the resist pattern was washed (rinsed) with running water, and blown with nitrogen to obtain a resist pattern. The obtained resist pattern including the substrate was immersed in a copper sulfate plating solution (UTB-W30 manufactured by ISHIHARA CHEMICAL CO., LTD) at 28° C. for 10 minutes. A cross-sectional shape of the resist pattern after immersion was observed under scanning electron microscope, and the cross-sectional shape of the pattern was evaluated. Specifically, a case where the resist pattern before and after the immersion was not changed was evaluated as O, a case where resist pattern was dissolved in a plating liquid and erosion of the resist pattern was observed was evaluated as X.

### (Evaluation at Film Thickness of 7 μm)

A substrate provided with a copper layer by sputtering on a surface of a glass substrate having a diameter of 500 mm was prepared, and the photosensitive resin compositions of the Reference Examples were each applied on the copper layer of the substrate to form photosensitive resin layers each having a thickness of 7 μm. Then, the photosensitive resin layers were pre-baked at 130° C. for 5 minutes. After the pre-baking, using a mask having a line-and-space pattern having a line-width of 2 μm and a space-width of 2 μm, and an exposure device Prisma GHI5452 (manufactured by Ultratech Inc.) equipped with an i-line cut filter, pattern exposure was performed with gh line at an exposure dose greater by 1.2 times than the minimum exposure dose capable of forming a pattern having a predetermined size until a 2.2 μm space was formed. Subsequently, the substrate was placed on a hot plate and post-exposure baking (PEB) was performed at 90° C. for 1.5 minutes. Then, an aqueous 2.38% by weight solution of tetramethylammonium hydroxide (developing solution, NMD-3, manufactured by Tokyo Ohka Kogyo Co., Ltd.) was added dropwise to the exposed photosensitive resin layer, and allowed to stand at 23° C. for 30 seconds. This operation was repeated twice in total. Subsequently, the surface of the resist pattern was washed (rinsed) with running water, and blown with nitrogen to obtain a resist pattern. The obtained resist pattern including the substrate was immersed in a copper sulfate plating solution (UTB-W30 manufactured by ISHIHARA CHEMICAL CO., LTD) at 28° C. for 10 minutes. A cross-sectional shape of the resist pattern after immersion was observed under scanning electron microscope, and the cross-sectional shape of the pattern was evaluated. Specifically, a case where the resist pattern before and after the immersion was not changed was evaluated as O, a case where resist pattern was dissolved in a plating liquid and erosion of the resist pattern was observed was evaluated as X.

TABLE 3

| | | | Phenolic hydroxyl | | | |
|---|---|---|---|---|---|---|
| | Acid | Resin (B) and | group-containing | Sulfur- | Acid diffusion | |
| | generator | alkali-soluble | low molecular weight | containing | suppressing | Evaluation |
| | (A) | resin (D) | compound (C) | compound (E) | agent (F) | of thickness |
| | Types/part | Types/part | Types/part | Types/part | Types/part | of 55 μm |
| | by mass | by mass | by mass | by mass | by mass | Shape |
| Reference | PAG1/0.3 | A1/90 | C1/10 | T2/0.1 | Amine-3/0.75 | ◯ |
| Example 1 | | | | | Amine-2/0.75 | |
| Reference | | A2/90 | | | | ◯ |
| Example 2 | | | | | | |
| Reference | PAG2/0.3 | A1/90 | | | | ◯ |
| Example 3 | | | | | | |
| Reference | | A2/90 | | | | ◯ |
| Example 4 | | | | | | |
| Reference | PAG1/0.3 | A1/90 | | | | ◯ |
| Example 5 | | | | | | |
| Reference | | A2/90 | | | | ◯ |
| Example 6 | | | | | | |
| Reference | PAG2/0.3 | A1/90 | | | | ◯ |
| Example 7 | | | | | | |
| Reference | | A2/90 | | | | ◯ |
| Example 3 | | | | | | |
| Reference | PAG1/0.3 | A1/70 | None | T2/0.1 | | ◯ |
| Example 9 | | B/15 | | | | |
| | | C/15 | | | | |

TABLE 4

| | | | Phenolic hydroxyl | | | |
|---|---|---|---|---|---|---|
| | Acid | Resin (B) and | group-containing | Sulfur- | Acid diffusion | |
| | generator | alkali-soluble | low molecular weight | containing | suppressing | Evaluation |
| | (A) | resin (D) | compound (C) | compound (E) | agent (F) | at thickness |
| | Types/part | Types/part | Types/part | Types/part | Types/part | of 7 μm |
| | by mass | by mass | by mass | by mass | by mass | Shape |
| Reference | PAG1/1.0 | A1/75 | C1/10 | T2/0.1 | Amine-3/0.75 | ◯ |
| Example 10 | | C/15 | | | Amine-2/0.75 | |
| Reference | | A1/65 | | | | ◯ |
| Example 11 | | A3/10 | | | | |
| | | C/15 | | | | |
| Reference | | A1/75 | None | | | ◯ |
| Example 12 | | B/10 | | | | |
| | | C/15 | | | | |
| Reference | PAG2/1.0 | A1/75 | C1/10 | | | ◯ |
| Example 13 | | C/15 | | | | |
| Reference | | A1/65 | C1/10 | | | ◯ |
| Example 14 | | A3/10 | | | | |
| | | C/15 | | | | |
| Reference | | A1/75 | None | | | ◯ |
| Example 15 | | B/10 | | | | |
| | | C/15 | | | | |
| Reference | PAG1/1.0 | A1/75 | C1/10 | T1/0.05 | Amine-1/1.5 | ◯ |
| Example 16 | | C/IS | | T2/0.05 | | |
| Reference | | A1/65 | C1/10 | | | ◯ |
| Example 17 | | A3/10 | | | | |
| | | C/15 | | | | |
| Reference | | A1/75 | None | | | ◯ |
| Example 18 | | B/10 | | | | |
| | | C/15 | | | | |
| Reference | PAG2/1.0 | A1/75 | C1/10 | | | ◯ |
| Example 19 | | C/15 | | | | |
| Reference | | A1/65 | C1/10 | | | ◯ |
| Example 20 | | A3/10 | | | | |
| | | C/15 | | | | |
| Reference | | A1/75 | C1/10 | | | ◯ |
| Example 21 | | B/10 | | | | |
| | | C/15 | | | | |

According to Reference Examples 1 to 21, it is shown that a positive-type photosensitive resin composition including at least one selected from the compounds represented by the formula (a1-i) or (a1-ii), the compounds represented by the formula (a2-i) or (a2-ii), and the compounds represented by the formula (a3-i) or (a3-ii) as the acid generator (A) which generates acid upon exposure to an irradiated active ray or radiation, and an acrylic resin as the resin (B) whose solubility in alkali increases under an action of acid can form a resist pattern by exposure to h-line, and the formed resist pattern has excellent plating solution resistance. Additionally, as in the above-described Examples, it is predicted that the crack resistance is excellent. Moreover, as in the above-described Examples, it is predicted that the cross-sectional shape of the resist pattern is good.

1. A chemically amplified positive-type photosensitive resin composition for use in manufacturing a template for forming a plated article by embedding a metal by a plating treatment on a substrate having a metal surface, the chemically amplified positive-type photosensitive resin composition comprising:
an acid generator (A) which generates acid upon exposure to an irradiated active ray or radiation, and a resin (B) whose solubility in alkali increases under an action of acid,
wherein the acid generator (A) comprises at least one compound selected from:
a compound represented by the following formula (a1-i) or (a1-ii): 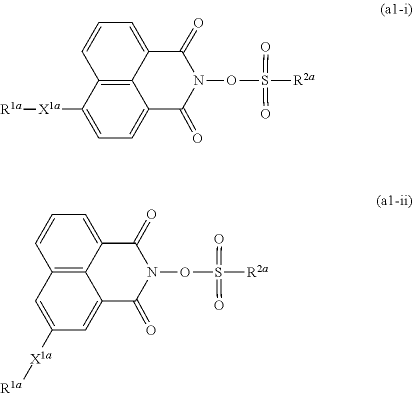
wherein in the formulae (a1-i) and (a1-ii),
X^{1a} is an oxygen atom or a sulfur atom;
R^{1a} is selected from the group consisting of an aliphatic group having 1 or more and 18 or less carbon atoms, optionally substituted with one or more halogen atoms;
an aliphatic group having 2 or more and 18 or less carbon atoms, including at least one moiety selected from the group consisting of —S—, —C(═O)—S—, —O—S(═O)₂—, —O—C(═O)—O—, —C(═O)—NH—, —C(═O)—NR^{10a}—, and —C(═O)—NR^{10a}R^{11a}, and optionally substituted with one or more halogen atoms;
a group represented by the following formula (a11):
—R^{3a}—Ar (a11)
a group represented by the following formula (a12): 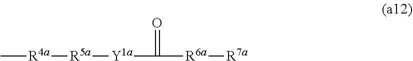
and
a group represented by the following formula (a13): 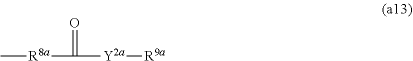
wherein in the formula (a11), R^{3a} is a single bond, or an aliphatic group having 1 or more and 20 or less carbon atoms, optionally including at least one moiety selected from the group consisting of —O—, —S—, —C(═O)—O—, —C(═O)—S—, —O—S(═O)₂—, —O—C(═O)—O—, —C(═O)—NH—, —O—C(═O)—NH—, —C(═O)—NR^{10a}—, and —C(═O)—NR^{10a}—,
Ar is an aromatic group which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group,
in the formula (a12), R^{4a} and R^{5a} are each independently an aliphatic group having 1 or more and 5 or less carbon atoms;
Y^{1a} is an oxygen atom;
R^{6a} is an aliphatic group having 1 or more and 10 or less carbon atoms, and
R^{7a} is an aliphatic group having 1 or more and 18 or less carbon atoms, including at least one moiety selected from the group consisting of —O—, —S—, —C(═O)—S—, —O—S(═O)₂—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a},
in the formula (a13), R^{8a} is an aliphatic group having 2 or more and 18 or less carbon atoms, optionally including at least one moiety selected from the group consisting of —O—, —S—, —C(═O)—S—, —O—S(═O)₂—, —O—C(═O)—O—, —C(═O)—NH—, —O—C(═O)—NH—, —C(═O)—NR^{10a}—, and —O—C(═O)—NR^{10a}—,
Y^{2a} is an oxygen atom;
R^{9a} is an aliphatic group having 1 or more and 18 or less carbon atoms, including at least one moiety selected from the group consisting of —O—, —S—, —C(═O)—O—, —C(═O)—S—, —O—S(═O)₂—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a},
R^{10a} and R^{11a} are each an aliphatic group having 1 or more and 10 or less carbon atoms, and in —C(═O)—NR^{10a}R^{11a}, R^{10a} and R^{11a} may be the same as or different from each other, and bonded to each other to form an alicyclic group, and
R^{2a} is selected from the group consisting of an aliphatic group having 1 or more and 18 or less carbon atoms, optionally substituted with one or more halogen atoms;
an aliphatic group having 3 or more and 18 or less carbon atoms, including at least one moiety selected from the group consisting of —O—, —S—, —C(═O)—O—, —C(═O)—S—, —O—S(═O)₂—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms;
an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxy carbonyl group, an alkylsulfonyl group, an alkylsulfinyl group, an aryl group, an alkyl aryl group, a cyano group, and a nitro group; and
an alkyl group substituted with an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxy carbonyl group, an alkylsulfonyl group, an alkylsulfinyl group, an aryl group, an alkyl aryl group, a cyano group, and a nitro group,
a compound represented by the following formula (a2-i) or (a2-ii): 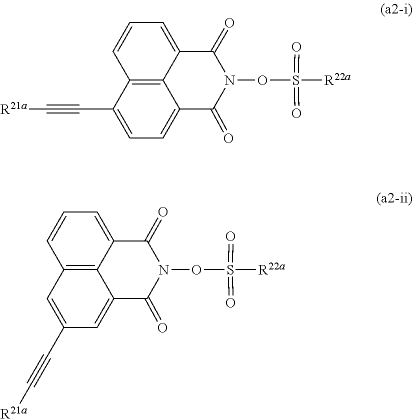
wherein in the formulae (a2-i) to (a2-ii),
R^{21a} is a hydrogen atom;
an aliphatic group having 1 or more and 18 or less carbon atoms, optionally substituted with one or more halogen atoms; or
an aliphatic group having 2 or more and 18 or less carbon atoms, optionally including at least one moiety selected from the group consisting of —O—, —S—, —C(═O)—, —C(═O)—O—, —C(═O)—S—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms,
R^{22a} is selected from the group consisting of —CH₃, —CH₂F, —CHF₂, —CF₃, or an aliphatic group having 2 or more and 18 or less carbon atoms, optionally substituted with one or more halogen atoms;
an aliphatic group having 2 or more and 18 or less carbon atoms, including at least one moiety selected from the group consisting of —O—, —S—, —C(═O)—, —C(═O)—O—, —C(═O)—S—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms;
an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group; and
an alkyl group substituted with an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group,
wherein when R^{22a} is —CF₃, R^{21a} is a group selected from the group consisting of a hydrogen atom;
an aliphatic group having 2 or more and 18 or less carbon atoms, optionally including at least one moiety selected from the group consisting of —O—, —S—, —C(═O)—, —C(═O)—O—, —C(═O)—S—, —O—C(═O)—O—, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms;
—CH₂CH(CH₃)₂, —CH₂CH═CHCH₃, or —CH₂CH₂CH═CH₂;
a group represented by the following formula (a21):
—CH₂—R^{23a} (a21)
and
a group represented by the following formula (a22): 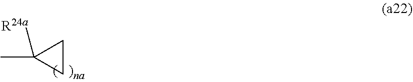
R^{10a} and R^{11a} are each an aliphatic group having 1 or more and 10 or less carbon atoms, and in —C(═O)—NR^{10a}R^{11a}, R^{10a} and R^{11a} may be the same as or different from each other, and bonded to each other to form an alicyclic group,
in the formula (a21), R^{23a} is an aliphatic group having 4 or more and 18 or less carbon atoms,
in the formula (a22), R^{24a} is a hydrogen atom, or an alkyl group having 1 or more and 10 or less carbon atoms, and na is an integer of 1 to 5
and
a compound represented by the following formulae (a3-i) or (a3-ii): 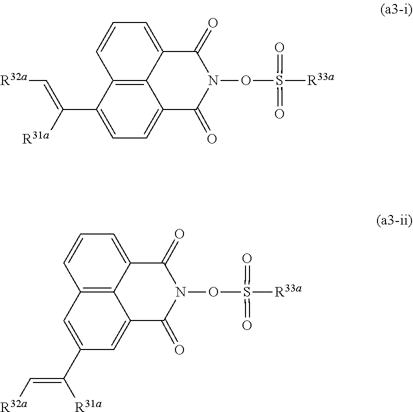
wherein in the formulae (a3-i) to (a3-ii), R^{31a} and R^{32a} are each independently a group selected from the group consisting of a hydrogen atom;
a cyano group;
an aliphatic group having 1 or more and 18 or less carbon atoms, optionally substituted with one or more halogen atoms;
an aliphatic group having 1 or more and 18 or less carbon atoms, including at least one moiety selected from the group consisting of —O—, —S—, —C(═O)—, —C(═O)—O—, —C(═O)—S—, —OC(═O)—O—, —CN, —C(═O)—NH—, —C(═O)—NR^{10a}—, and —C(═O)—NR^{10a}R^{11a}, and optionally substituted with one or more halogen atoms; and
an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group;
R^{31a} and R^{32a} may be the same as or different from each other, and bonded to each other to form an alicyclic group or a heterocyclic group, R^{33a} is selected from the group consisting of an aliphatic group having 1 or more and 18 or less carbon atoms, optionally substituted with one or more halogen atoms;
an aliphatic group having 1 or more and 18 or less carbon atoms, including at least one moiety selected from the group consisting of —O—, —S—, —C(═O)—, —C(═O)—O—, —C(═O)—S—, —O—C(═O)—O—, —CN, —C(═O)—NH—, —O—C(═O)—NH—, —C(═O)—NR^{10a}—, —O—C(═O)—NR^{10a}—, and —C(═O)—NR^{10a}R^{11a}, and optionally substituted with one or more halogen atoms; and
an aromatic group having 4 or more and 18 or less carbon atoms, which may have one or more substituents selected from the group consisting of a halogen atom, an aliphatic group, a haloalkyl group, an alkoxy group, a haloalkoxy group, an alkylthio group, a dialkylamino group, an acyloxy group, an acylthio group, an acylamino group, an alkoxycarbonyl group, an alkylsulfonyl group, an alkylsulfinyl group, an aryl group, an alkyl aryl group, a cyano group, and a nitro group,
R^{10a} and R^{11a} are each an aliphatic group having 1 or more and 10 or less carbon atoms, and in —C(═O)—NR^{10a}R^{11a}, R^{10a} and R^{11a} may be the same as or different from each other, and bonded to each other to form an alicyclic group,
wherein the chemically amplified positive-type photosensitive resin composition comprises an acrylic resin that is a resin comprising an acrylic constituent unit that is a constituent unit derived from (meth)acrylic acid or (meth)acrylic acid derivative in a content of 70 mol % or more, and
a ratio of the acrylic resin to a total of the resin (B) and a resin other than the resin (B) is 70% by mass or more.

2. The chemically amplified positive-type photosensitive resin composition according to claim 1, wherein the acid generator (A) comprises a compound represented by the formula (a1-i), (a1-ii), (a2-i) or (a2-ii).

3. The chemically amplified positive-type photosensitive resin composition according to claim 1, wherein the resin (B) comprises the acrylic resin.

4. The chemically amplified positive-type photosensitive resin composition according to claim 3, wherein a ratio of the acrylic resin contained in the resin (B) with respect to the resin (B) is 70% by mass or more.

5. The chemically amplified positive-type photosensitive resin composition according to claim 1, further comprising an alkali-soluble resin (D).

6. The chemically amplified positive-type photosensitive resin composition according to claim 5, wherein the alkali-soluble resin (D) comprises a novolac resin (D1).

7. The chemically amplified positive-type photosensitive resin composition according to claim 5, wherein the alkali-soluble resin (D) comprises a hydroxystyrene resin (D2).

8. The chemically amplified positive-type photosensitive resin composition according to claim 1, further comprising a phenolic hydroxyl group-containing low molecular weight compound (C).

9. The chemically amplified positive-type photosensitive resin composition according to claim 1, further comprising a sulfur-containing compound (E) capable of coordinating with the metal.

10. (canceled)

11. The chemically amplified positive-type photosensitive resin composition according to claim 1, wherein a main surface of the substrate having a metal surface has a rectangular shape.

12. A photosensitive dry film comprising a substrate film, and a photosensitive resin layer formed on a surface of the substrate film, wherein the photosensitive resin layer comprises the chemically amplified positive-type photosensitive resin composition according to claim 1.

13. A method of manufacturing a photosensitive dry film, the method comprising applying the chemically amplified positive-type photosensitive resin composition according to claim 1 to a substrate film to form a photosensitive resin layer.

14. A method of manufacturing a patterned resist film, the method comprising:
laminating a photosensitive resin layer on a substrate, the layer comprising the chemically amplified positive-type photosensitive resin composition according to claim 1;
exposing the photosensitive resin layer through irradiation with an active ray or radiation in a position-selective manner; and
developing the exposed photosensitive resin layer.

15. The method of manufacturing a patterned resist film according to claim 14, wherein the active ray or radiation is h-line.

16. The method of manufacturing a patterned resist film according to claim 14, wherein the patterned resist film has a thickness of 1 μm or more.

17. A method of manufacturing a substrate with a template, the method comprising:
laminating a photosensitive resin layer on a substrate having a metal surface, the layer comprising the chemically amplified positive-type photosensitive resin composition according to claim 1;
exposing the photosensitive resin layer through irradiation with an active ray or radiation in a position-selective manner; and
developing the exposed photosensitive resin layer to form a template for forming a plated article.

18. The method of manufacturing a substrate with a template according to claim 17, wherein the active ray or the radiation is h-line.

19. The method of manufacturing a substrate with a template according to claim 17, wherein the template has a thickness of 1 μm or more.

20. The method of manufacturing a substrate with a template according to claim 17, wherein a main surface of the substrate having a metal surface has a rectangular shape.

21. A method of manufacturing a plated article, the method comprising plating a substrate with a template to form the plated article in the template, the substrate with a template being manufactured by the method of manufacturing a substrate with a template according to claim 17.
